(19) United States
(12) Patent Application Publication
(10) Pub. No.: US 2025/0024685 A1
(43) Pub. Date: Jan. 16, 2025

(54) MEMORY STRUCTURE OF THREE-DIMENSIONAL NOR MEMORY STRINGS OF CHANNEL-ALL-AROUND FERROELECTRIC MEMORY TRANSISTORS AND METHOD OF FABRICATION

(71) Applicant: SUNRISE MEMORY CORPORATION, San Jose, CA (US)

(72) Inventors: Jie Zhou, San Jose, CA (US); Christopher J. Petti, Mountain View, CA (US); Eli Harari, Saratoga, CA (US); Kavita Shah, Mountain View, CA (US)

(21) Appl. No.: 18/755,360

(22) Filed: Jun. 26, 2024

Related U.S. Application Data
(60) Provisional application No. 63/598,050, filed on Nov. 10, 2023.
(60) Provisional application No. 63/512,894, filed on Jul. 10, 2023.

(51) Int. Cl. H10B 51/20; G11C 5/06; G11C 16/04; G11C 16/14; H01L 29/49; H01L 29/78; H01L 29/786; H10B 43/10; H10B 43/27; H10B 51/10

(52) U.S. Cl. CPC H10B 51/20; G11C 5/063; G11C 16/0483; G11C 16/14; H01L 29/4908; H01L 29/78391; H01L 29/7869; H10B 43/10; H10B 43/27; H10B 51/10

(57) ABSTRACT

A memory structure includes randomly accessible, channel-all-around ferroelectric memory transistors organized as horizontal NOR memory strings. The NOR memory strings are formed over a semiconductor substrate in multiple scalable memory stacks of thin-film ferroelectric memory transistors. The three-dimensional memory stacks are manufactured in a process that includes forming holes in a multi-layer film stack for forming local word line structures and slit trenches to divide the film stack into memory stacks including local word line structures formed therein. The memory structure of channel-all-around ferroelectric memory transistors enables a scalable construction for realizing a high density, high capacity memory device.

### CROSS REFERENCE TO RELATED APPLICATIONS

This application claims priority to U.S. Provisional Patent Application No. 63/598,050, entitled MEMORY STRUCTURE OF THREE-DIMENSIONAL NOR MEMORY STRINGS OF CHANNEL-ALL-AROUND FERROELECTRIC MEMORY TRANSISTORS AND METHOD OF FABRICATION, filed Nov. 10, 2023, and U.S. Provisional Patent Application No. 63/512,894, entitled MEMORY STRUCTURE OF THREE-DIMENSIONAL NOR MEMORY STRINGS OF CHANNEL-ALL-AROUND FERROELECTRIC MEMORY TRANSISTORS AND METHOD OF FABRICATION, filed Jul. 10, 2023, which are incorporated herein by reference in their entireties.

### FIELD OF THE INVENTION

The present invention relates to high-density memory structures and fabrication methods thereof. In particular, the present invention relates to a memory structure of three dimensional NOR memory strings formed using channel-all-around ferroelectric memory transistors. Furthermore, the present invention relates to a vertical channel-all-around ferroelectric field effect transistor formed on a semiconductor substrate.

### BACKGROUND OF THE INVENTION

A NOR-type memory string includes storage transistors that share a common source region and a common drain region, where each storage transistor can be individually addressed and accessed. U.S. Pat. No. 10,121,553 (the '553 Patent), entitled “Capacitive-Coupled Non-Volatile Thin-film Transistor NOR Strings in Three-Dimensional Arrays,” issued on Nov. 6, 2018, discloses storage transistors (or memory transistors) organized as 3-dimensional arrays of NOR memory strings formed above a planar surface of a semiconductor substrate. The '553 Patent is hereby incorporated by reference in its entirety for all purposes. In the '553 Patent, a NOR memory string includes numerous thin-film storage transistors that share a common bit line and a common source line. In particular, the '553 Patent discloses a NOR memory string that includes (i) a common source region and a common drain region both running lengthwise along a horizontal direction and (ii) gate electrodes for the storage transistors each running along a vertical direction. In the present description, the term “vertical” refers to the direction normal to the surface of a semiconductor substrate, and the term “horizontal” refers to any direction that is parallel to the surface of that semiconductor substrate. In a 3-dimensional array, the NOR memory strings are provided on multiple planes (e.g., 8 or 16 planes) above the semiconductor substrate, with the NOR memory strings on each plane arranged in rows. For a charge-trap type storage transistor, data is stored in each storage transistor using a charge storage film as the gate dielectric material. For example, the charge storage film may include a tunneling dielectric layer, a charge trapping layer and a blocking layer, which can be implemented as a multilayer including silicon oxide or oxynitride, silicon-rich nitride, and silicon oxide, arranged in this order and referred to as an ONO layer. An applied electrical field across the charge storage film adds or removes charge from charge traps in the charge trapping layer, thus altering the threshold voltage of the storage transistor to encode a given logical state in the storage transistor.

Advances in electrically polarizable materials (“ferroelectric materials”), especially those that are being used in semiconductor manufacturing processes, suggest new potential applications in ferroelectric memory circuits. For example, the article “Ferroelectricity in Hafnium Oxide: CMOS compatible Ferroelectric Field Effect Transistors,” by T. S. Böscke et al., published in 2011 International Electron Devices Meeting (IEDM), pp. 24.5.1-24.5.4, discloses a ferroelectric field effect transistor (“FeFET”) that uses hafnium oxide as a gate dielectric material. By controlling the polarization direction in a ferroelectric gate dielectric layer, the FeFET may be programmed to have either one of two threshold voltages. Each threshold voltage of the FeFET constitutes a state, for example, a “programmed” state or an “erased” state, that represents a designated logical value. Such an FeFET has application in high-density memory circuits. In another example, U.S. Pat. No. 9,281,044, entitled “Apparatuses having a ferroelectric field-effect transistor memory array and related method,” by D. V. Nirmal Ramaswamy et al., issued Mar. 8, 2016, discloses a 3-dimensional array of FeFETs.

### SUMMARY OF THE INVENTION

The present disclosure discloses a memory structure including three-dimensional NOR memory strings of junctionless ferroelectric memory transistors and method of fabrication, substantially as shown in and/or described below, for example in connection with at least one of the figures, as set forth more completely in the claims.

In some embodiments, a three-dimensional memory structure formed above a planar surface of a semiconductor substrate includes multiple memory stacks arranged along a first direction, each memory stack being separated from each of its immediate neighboring memory stacks along the first direction by a trench, each memory stack and each trench extending in a second direction, the first and second directions being orthogonal to each other and both being substantially parallel to the planar surface of the semiconductor substrate, wherein each memory stack includes multiple active layers arranged in a third direction substantially normal to the planar surface of the semiconductor substrate, each active layer including a first conductive layer and a second conductive layer arranged one on top of another in the third direction and spaced apart by a first isolation layer and each active layer is separated from its immediate neighboring active layers along the third direction by a second isolation layer; and multiple local word line structures provided as pillars formed in each memory stack and extending in the third direction, each local word line structure being encircled by the first and second conductive layers, each local word line structure including concentric layers of an oxide semiconductor layer, a ferroelectric dielectric layer and a gate conductor layer, wherein the oxide semiconductor layer is provided around the outer circumference of each pillar and is provided between and in contact with the first and second conductive layers. Each active layer in the memory stack forms an array of thin-film ferroelectric memory transistors organized as a NOR memory string, each memory transistor being formed at an intersection of an active layer and a local word line structure.

In another embodiment, a process suitable for use in fabricating a memory structure including memory transistors of a NOR memory string above a planar surface of a semiconductor substrate includes above the planar surface, repeatedly depositing, alternately and one over another, a multilayer and an inter-layer sacrificial layer to form a multi-layer film stack, each multilayer including first and second sacrificial layers and a first isolation layer between the first and second sacrificial layers, the multi-layer film stack extending in a first direction and a second direction, the first and second directions being orthogonal to each other and both being substantially parallel to the planar surface of the semiconductor substrate, and the multilayer and the inter-layer sacrificial layer are stacked in a third direction substantially normal to the planar surface of the semiconductor substrate; forming an array of holes in the multi-layer film stack, the array of holes extending in the third direction through the multilayers and the inter-layer sacrificial layers, the array of holes including a first array of holes formed in a memory array area; forming a local word line structure in each of the first array of holes, including forming concentric layers of an oxide semiconductor layer, a ferroelectric dielectric layer and a gate conductor layer in each of the first plurality of holes; forming trenches in the multi-layer film stack to divide the multi-layer film stack into multiple memory stacks, each memory stack having a subset of the local word line structures formed therein, each memory stack being separated from each of its immediate neighboring memory stacks along the first direction by one of the trenches, each memory stack and each trench extending in the second direction, each memory stack including the multilayer and the inter-layer sacrificial layers arranged in the third direction; using access through the trenches, replacing the first and second sacrificial layers with first and second conductive layers, the first and second conductive layers being in contact with the oxide semiconductor layer of each local word line structure in each memory stack; using access through the trenches, removing the inter-layer sacrificial layer to expose portions of the oxide semiconductor layer formed on the outer circumference of the local word line structures formed in the first array of holes; and using access through the trenches, removing at least a portion of the exposed portions of the oxide semiconductor layer.

In some embodiments, an integrated circuit includes a vertical ferroelectric field effect transistor formed above a planar surface of a semiconductor substrate where the ferroelectric field effect transistor includes: a gate conductor layer provided as a pillar extending in a first direction substantially normal to the planar surface of the semiconductor substrate; an annular ferroelectric dielectric layer formed adjacent to the pillar of the gate conductor layer; an annular oxide semiconductor layer formed adjacent to the annular ferroelectric dielectric layer; and a first conductive layer and a second conductive layer each provided as a plane parallel to the planar surface of the semiconductor substrate. The first and second conductive layers are arranged one on top of another along the first direction and spaced apart by a first isolation layer. The first and second conductive layers encircle an outer circumference of and are in contact with the annular oxide semiconductor layer. The ferroelectric field effect transistor is formed at an intersection of the first and second conductive layers and the annular oxide semiconductor layer, the first conductive layer forming a drain region and the second conductive layer forming a source region, the oxide semiconductor layer forming a junctionless channel region, the annular ferroelectric dielectric layer forming the gate dielectric layer, and the gate conductor layer forming the gate electrode of the ferroelectric field effect transistor.

In another embodiment, an array of memory strings where each memory string includes multiple vertical ferroelectric field effect transistors formed above a planar surface of a semiconductor substrate. Each ferroelectric field effect transistor includes: a gate conductor layer provided as a pillar extending in a first direction substantially normal to the planar surface of the semiconductor substrate; an annular ferroelectric dielectric layer formed adjacent to the pillar of the gate conductor layer; an annular oxide semiconductor layer formed adjacent to the annular ferroelectric dielectric layer; and a first conductive layer and a second conductive layer each provided as a plane parallel to the planar surface of the semiconductor substrate, the first and second conductive layers being arranged one on top of another along the first direction and spaced apart by a first isolation layer, the first and second conductive layers encircling an outer circumference of and being in contact with the annular oxide semiconductor layer. The ferroelectric field effect transistor is formed at an intersection of the first and second conductive layers and the annular oxide semiconductor layer, the first conductive layer forming a drain region and the second conductive layer forming a source region, the oxide semiconductor layer forming a junctionless channel region, the annular ferroelectric dielectric layer forming the gate dielectric layer, and the gate conductor layer forming the gate electrode of the ferroelectric field effect transistor.

These and other advantages, aspects and novel features of the present invention, as well as details of an illustrated embodiment thereof, will be more fully understood from the following description and drawings.

### BRIEF DESCRIPTION OF THE DRAWINGS

Various embodiments of the invention are disclosed in the following detailed description and the accompanying drawings. Although the drawings depict various examples of the invention, the invention is not limited by the depicted examples. It is to be understood that, in the drawings, like reference numerals designate like structural elements. Also, it is understood that the depictions in the figures are not necessarily to scale.

FIGS. 1(a), 1(b) and 1(c) are perspective views of a memory structure including a three-dimensional array of NOR memory strings of channel-all-around ferroelectric memory transistors in embodiments of the present invention.

FIGS. 1(d) and 1(e) are cross-sectional views of a respective part of the memory structure of FIGS. 1(a) and 1(c) illustrating the ferroelectric memory transistors in some embodiments.

FIG. 2 is a transistor-level schematic diagram of a memory device including a three-dimensional array of NOR memory strings in embodiments of the present invention.

FIGS. 3(a) and 3(b) include cross-sectional views of the memory structures of FIGS. 1(a) and 1(c) in two different planes in embodiments of the present invention.

FIGS. 4(a) and 4(b) are expanded perspective views of the memory structure of FIGS. 1(a) to 1(c) in embodiments of the present invention.

FIG. 5 is a top view of a memory structure including precharge transistors and staircase structures in embodiments of the present invention.

FIG. 6 is a cross-sectional view of the memory structure of FIG. 5 including precharge transistors and staircase structures in embodiments of the present invention.

FIG. 7 is an expanded cross-sectional view of a memory stack including local word line structures in embodiments of the present invention.

FIG. 8 is an expanded cross-sectional view of a memory stack including local word line structures in an alternate embodiment of the present invention.

FIGS. 9(a) and 9(b) are expanded cross-sectional views of memory stacks including local word line structures in an alternate embodiments of the present invention.

FIG. 10 is a top view of a memory structure including staircase structures connecting to common bit lines and common source lines in embodiments of the present invention.

FIG. 11 is a cross-sectional view of the memory structure of FIG. 10 including staircase structures connecting to common bit lines and common source lines in embodiments of the present invention.

FIG. 12 is flowchart of a fabrication process for forming a memory structure including channel-all-around ferroelectric memory transistors in embodiments of the present invention.

FIGS. 13(a) to 13(n), including FIG. 13(j1), illustrate the memory structure during intermediate process steps in the fabrication process of FIG. 12 in some embodiments.

FIG. 14 includes cross-sectional views of a memory structure of channel-all-around ferroelectric memory transistors in alternate embodiments of the present invention.

FIG. 15 is a top view of a memory structure including staircase structures connecting to common bit lines and common source lines in alternate embodiments of the present invention.

FIG. 16 is a cross-sectional view of the memory structure of FIG. 15 including staircase structures connecting to common bit lines and common source lines in embodiments of the present invention.

FIGS. 17(a) and 17(b) are top view and cross-sectional view, respectively, of a memory structure including a single layer of global word lines in some embodiments.

FIGS. 18(a) and 18(b) are top view and cross-sectional view, respectively, of a memory structure including a double layer of global word lines in some embodiments.

FIGS. 19(a), 19(b) and 19(c) are top view, cross-sectional view and expanded cross-sectional view, respectively, of a memory structure including a top-bottom layer of global word lines in some embodiments.

FIGS. 19(d)-19(k) are cross-sectional views of the memory structure of FIGS. 19(a)-19(c) illustrating the fabrication process for forming the top-bottom layer of global word lines in some embodiments.

FIGS. 20(a) and 20(b) illustrate the patterning of pillar hole openings in a hard mask layer using a single-mask, single-exposure photolithography technique in some embodiments.

FIGS. 21(a) and 21(b) illustrate the patterning of pillar hole openings in a hard mask layer using a two-mask, two-exposure photolithography technique in some embodiments.

FIG. 22 illustrates an application of a memory device of the present invention as an embedded memory device in some embodiments.

FIG. 23 illustrates the detail construction of a memory transistor formed in a memory structure in alternate embodiments of the present invention.

### DETAILED DESCRIPTION OF THE INVENTION

In embodiments of the present invention, a memory structure includes randomly accessible, channel-all-around ferroelectric memory transistors organized as horizontal NOR memory strings. The NOR memory strings are formed over a semiconductor substrate in multiple scalable memory stacks of thin-film ferroelectric memory transistors. The three-dimensional memory stacks are manufactured in a process that includes forming holes in a multi-layer film stack for forming local word line structures and slit trenches to divide the film stack into memory stacks including local word line structures formed therein. The memory structure of channel-all-around ferroelectric memory transistors enables a scalable construction for realizing a high density, high capacity memory device.

In some embodiments, the ferroelectric memory transistors are thin-film ferroelectric field-effect transistors (FeFETs) having a ferroelectric polarization layer as a gate dielectric layer. The ferroelectric polarization layer, also referred to as a “ferroelectric gate dielectric layer” or “ferroelectric dielectric layer”, is formed adjacent an oxide semiconductor layer as a channel region. The ferroelectric memory transistors include source and drain regions-both formed of a metallic conductive material—in electrical contact with the oxide semiconductor channel region. The ferroelectric memory transistors thus formed are each a junctionless transistor without a p/n junction in the channel and in which the threshold voltage is modulated by the polarization of the mobile carriers in the ferroelectric polarization layer. In the memory structure of the present invention, the ferroelectric memory transistors in each NOR memory string are controlled by individual control gate electrodes to allow each memory transistor to be individually addressed and accessed. In some embodiments, the ferroelectric polarization layer is formed of a doped hafnium oxide material and the oxide semiconductor channel region is formed of an amorphous metal oxide semiconductor material.

In the present description, the term “storage transistor” is used interchangeably with “memory transistor” to refer to the transistor device formed in the memory structure described herein. In some examples, the memory structure of the present disclosure including NOR memory strings of randomly accessible memory transistors (or storage transistors) can have applications in computing systems as the main memory where the memory locations are directly accessible by the processors of the computer systems, for instance, in a role served in the prior art by conventional random-access memories (RAMs), such as dynamic RAMs (DRAMS) and static RAMs (SRAMs). For example, the memory structure of the present invention can be applied in computing systems to function as a random-access memory to support the operations of microprocessors, graphical processors and artificial intelligence processors. In other examples, the memory structure of the present disclosure is also applicable to form a storage system, such as a solid-state drive or replacing a hard drive, for providing long term data storage in computing systems.

In the present description, the term “oxide semiconductor layer” (sometimes also referred to as a “semiconductor oxide layer” or “metal oxide semiconductor layer”) as used herein refers to thin film semiconducting materials made from a conductive metal oxide, such as zinc oxide and indium oxide, or any suitable conductive metal oxides with charge-carriers having mobilities that can be modified or modulated using suitable preparation or inclusion of suitable impurities.

In the present description, to facilitate reference to the figures, a Cartesian coordinate reference frame is used, in which the Z-direction is normal to the planar surface of the semiconductor substrate and the X-direction and the Y-direction are orthogonal to the Z-direction and to each other, as indicated in the figures. Moreover, the drawings provided herein are idealized representations to illustrate embodiments of the present invention and are not meant to be actual views of any particular component, structure, or device. The drawings are not to scale, and the thickness and dimensions of some layers may be exaggerated for clarity. Variations from the shapes of the illustrations are to be expected. For example, a region illustrated as a box shape may typically have rough and/or nonlinear features. Sharp angles that are illustrated may be rounded. Like numerals refer to like components or elements throughout.

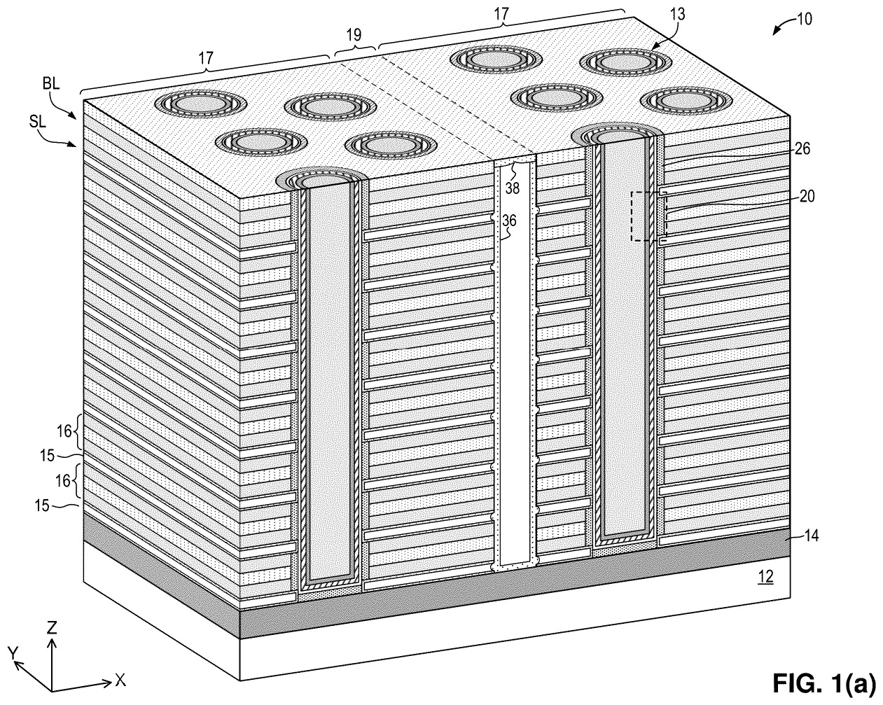

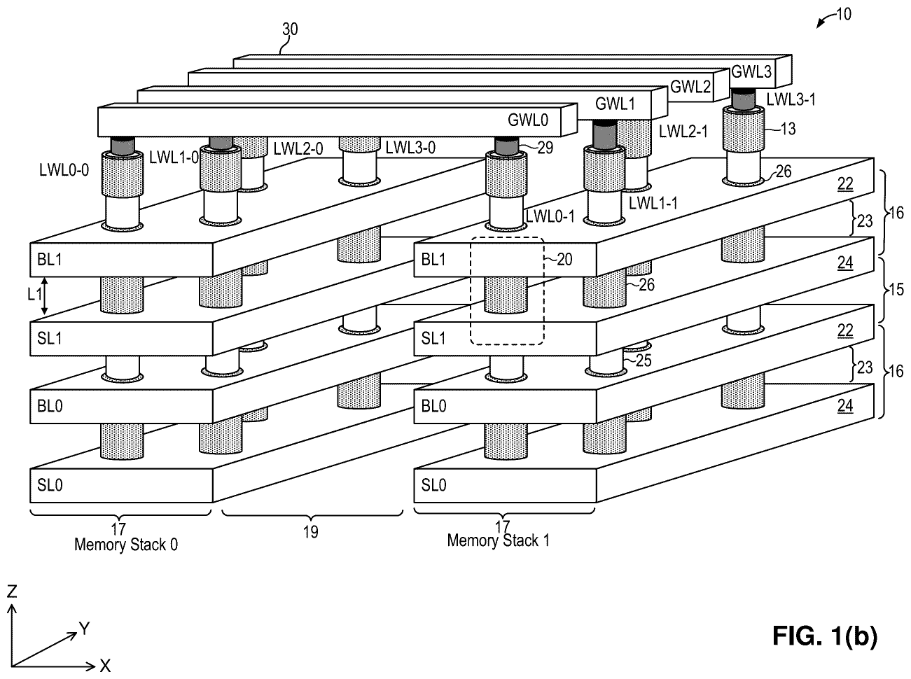

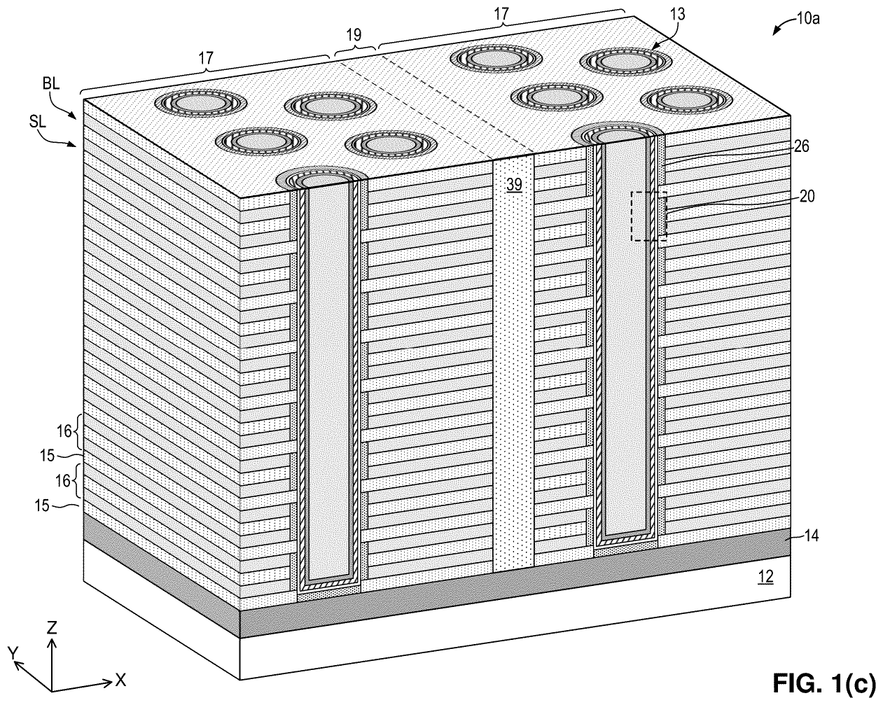

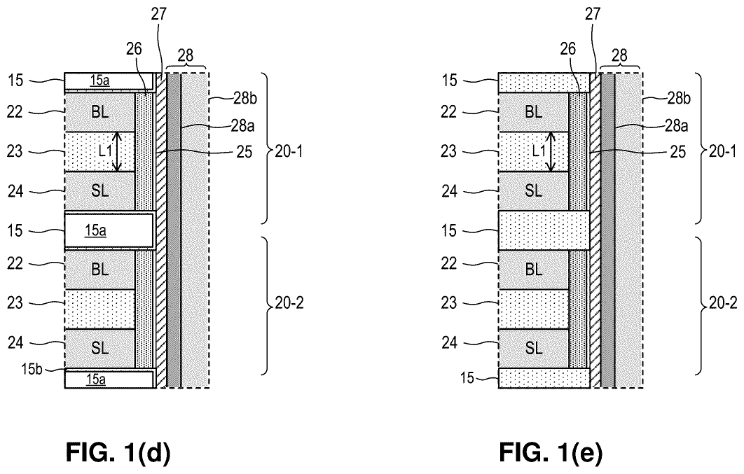

FIGS. 1(a), 1(b) and 1(c) are perspective views of a memory structure including a three-dimensional array of NOR memory strings of channel-all-around ferroelectric memory transistors in embodiments of the present invention. FIGS. 1(d) and 1(e) are cross-sectional views of a respective part of the memory structure of FIGS. 1(a) and 1(c) illustrating the ferroelectric memory transistors in some embodiments. The memory structure in FIG. 1(b) is shown with the dielectric layers omitted for simplicity in order to illustrate the elements of the ferroelectric memory transistors in the three-dimensional structure.

Referring to FIGS. 1(a) and 1(b), a memory structure 10 includes memory stacks 17 formed on a semiconductor layer 12 (sometimes referred to as a semiconductor substrate) where each memory stack includes multiple NOR memory strings formed one on top of another in the vertical direction. An insulating layer 14 may be provided between the semiconductor substrate 12 and the memory stacks. Each memory stack 17 is separated form its immediate neighboring memory stack in the X-direction by a trench 19, also referred herein as a “slit trench”. The slit trench 19 is a narrow trench having a width in the X-direction much smaller than the width of the memory stack 17. In some embodiments, the memory stacks of NOR memory strings are formed by groups of thin films successively deposited over the planar surface of the semiconductor substrate 12, each group of thin films being referred to as an active layer 16 in the present description. The active layers 16 in each memory stack of NOR memory strings are provided one on top of another and each active layer 16 is separated from the neighboring active layers by an inter-layer isolation layer 15. The inter-layer isolation layer 15 can be a dielectric layer or can be implemented as an air gap isolation. In some embodiments, the inter-layer isolation layer 15 is an oxygen-containing dielectric layer. Each active layer 16 includes a common drain line (or bit line) 22 and a common source line (or source line) 24 that are arranged spaced apart in the vertical direction (Z-direction) by a channel spacer isolation layer 23. The common drain line 22 and the common source line 24 in each active layer 16 extend along the horizontal Y-direction to form a NOR memory string of memory transistors. The memory transistors in each NOR memory string share the bit line 22 (the common drain line) and the source line 24 (the common source line).

In embodiments of the present invention, local word line structures 13 in the form of pillars are formed in each memory stack and extend through the memory stack in the Z-direction. As thus configured, each local word line structure 13 is encircled by the bit line 22 and the source line 24. Each pillar-shaped local word line structure 13 includes concentric layers of a channel layer, a ferroelectric gate dielectric layer and a gate conductor layer, formed from the outer circumference to the inner center of the pillar. In some embodiments, an optional interfacial layer is formed as a concentric layer between the channel layer and the ferroelectric gate dielectric layer. In the present embodiment, the channel layer is an oxide semiconductor layer.

In embodiments of the present invention, the annular channel layer 26 is separated between adjacent active layers 16. That is, the channel layer 26 is provided along each local word line structure 13 in each active layer 16, between and in contact with the bit line 22 and the source line 24 of each active layer 16. The channel layer 26 is absent or is removed, at least partially, in the regions of the inter-layer isolation layer 15 to separate the channel layer between adjacent active layers 16. In the regions of the inter-layer isolation layer 15, the exposed layer of the local word line structure 13 may be the interfacial layer 25, if used, as shown in Figures (a) and 1(b). Alternately, the exposed layer of the local word line structure 13 in the inter-layer isolation layer 15 is the ferroelectric gate dielectric layer, in the case no interfacial layer is included in the local word line structures 13 or the optional interfacial layer is removed completely or partially during the channel layer removal process. The presence or absence of the interfacial layer 25 in the inter-layer isolation region is not critical to the practice of the present invention. In alternate embodiments, the ferroelectric gate dielectric layer is also at least partially removed between adjacent active layers 16. Removing at least partially the ferroelectric gate dielectric layer in the regions of the inter-layer isolation layer 15 has the effect of limiting the sideway migration of the polarization areas between the memory transistors on adjacent planes in the memory stack or limiting the migration of oxygen atoms between adjacent active layers.

As thus configured, the channel layer 26 of the memory transistors is an annular layer formed on the outer circumference of the local word line pillar to realize a channel-all-around transistor structure. The bit line 22 (common drain line) and the source line 24 (common source line) encircle and are in contact with the annular channel layer 26. The annular channel layer is formed adjacent to the ferroelectric gate dielectric layer, also formed as an annular layer. The inner center portion of the local word line pillar is the gate conductor layer. In the case an interfacial layer is provided, the interfacial layer is another annular layer formed between the annular channel layer and the annular ferroelectric gate dielectric layer. A ferroelectric memory transistor is formed at each intersection of the active layer 16 and the local word line structure 13. Accordingly, in each memory stack 17, memory transistors are formed in a vertical direction in multiple parallel planes of the memory stack. In each active layer 16 of a memory stack 17, memory transistors 20 are formed at each intersection of the common source line and the common drain line and the local word line structures to form a memory string. As mentioned above, the term “vertical” refers to the direction normal to the surface of a semiconductor substrate, and the term “horizontal” refers to any direction that is parallel to the surface of that semiconductor substrate.

FIG. 1(d) illustrates the detail construction of the memory transistor 20 formed in the memory structure 10 of FIGS. 1(a) and 1(b) in some embodiments. In particular, FIG. 1(d) illustrates a pair of memory transistors 20-1 and 20-2 in two adjacent planes of a memory stack 17. Referring to FIG. 1(d), the memory transistor 20 includes a first conductive layer 22 forming the bit line (or the common drain line) and a second conductive layer 24 forming the source line (or the common source line), the conductive layers being spaced apart by the channel spacer isolation layer 23. The memory transistor 20 further includes the annular channel layer 26 formed vertically along the sidewall of the local word line pillar and in contact with both the first conductive layer 22 and the second conductive layer 24. The annular ferroelectric gate dielectric layer 27 and the gate conductor layer 28 are formed adjacent the annular channel layer 26. In particular, a portion of the annular channel layer 26 is provided between the bit line 22 and the annular ferroelectric gate dielectric layer 27 in the X-Y plane; and a portion of the annular channel layer 26 is provided between the source line 24 and the annular ferroelectric gate dielectric layer 27 in the X-Y plane. In the present embodiment, an annular interfacial layer 25 is provided between the channel layer 26 and the ferroelectric gate dielectric layer 27. The memory transistor 20 is isolated from adjacent memory transistors in the stack by the inter-layer isolation layer 15. As thus configured, along each active strip (in the Y-direction), the memory transistors that share the common source line and the common bit line form a NOR memory string (referred herein as a “Horizontal NOR memory string” or “HNOR memory string”).

In the embodiment shown in FIGS. 1(a), 1(b) and 1(d), the inter-layer isolation layer 15 is implemented as an air gap isolation. For instance, the air gap isolation is implemented by forming an air gap liner layer 15b on the exposed surface of the inter-layer isolation area between active layers, with the remaining cavity 15a left unfilled to form the air gap isolation. The air gap liner layer 15b can be a silicon oxide layer, or a silicon nitride layer, or other suitable dielectric layer. Furthermore, in the embodiment shown in FIG. 1(a), air gap isolation is also formed in the slit trench 19 between adjacent memory stacks 17. In the embodiment shown in FIG. 1(a), the air gap isolation between adjacent memory stacks 17 includes a dielectric liner layer 36 lining the sidewalls of the slit trench 19 and capping the openings of the air gap isolation layer 15. A dielectric layer 38 is then deposited nonconformally to form a cap on the top end of the slit trench 19, thereby enclosing the cavity of each slit trench to form the air gap isolation. In some embodiments, the dielectric layer 38 is a silicon dioxide (SiO₂) layer that is nonconformally deposited.

In alternate embodiments, the memory structure can be formed using dielectric-filled isolation layers, instead of air gap isolation. FIG. 1(c) illustrates a memory structure 10a constructed in a similar manner as the memory structure 10 of FIG. 1(a) but with the use of dielectric-filled isolation layers. Referring to FIG. 1(c), in the memory structure 10a, the inter-layer isolation layer 15 is formed as a dielectric layer. In some embodiments, the inter-layer isolation layer 15 is an oxygen-containing dielectric layer. In one example, the inter-layer isolation layer 15 is a silicon dioxide layer. FIG. 1(e) illustrates the detail construction of the memory transistor 20 formed in the memory structure 10a of FIG. 1(c) in some embodiments. The memory transistors 20 in FIG. 1(c) is constructed in a similar manner to the memory transistors 20 in FIG. 1(d) except for the inter-layer isolation layer 15 which is formed as a dielectric layer or a dielectric-filled layer.

Furthermore, in the embodiment shown in FIG. 1(c), the memory structure 10a includes the slit trench 19 that is filled with a dielectric layer 39 to provide isolation between adjacent memory stacks 17. In alternate embodiments, the memory structure 10a can be formed with dielectric-filled inter-layer isolation layers 15 and using air gap isolation for the slit trenches 19. More specifically, the memory structure of the present invention can be realized using a selection of isolation elements or materials between the active layers and between the active stacks to achieve the desired isolation of the memory transistors formed therein.

In the embodiments shown in FIGS. 1(d) and 1(e), the inter-layer isolation layer 15 is shown extending to the ferroelectric gate dielectric layer 27. As described above, in the regions of the inter-layer isolation layer 15, the exposed layer of the local word line structure can be the interfacial layer 25, if used. In other embodiments, the exposed layer of the local word line structure in the inter-layer isolation layer 15 can be the ferroelectric gate dielectric layer. The interfacial layer 25, if used, can be completely or partially removed in the inter-layer isolation region.

In the present embodiments, the memory transistors in the NOR memory strings are ferroelectric field effect transistors including a ferroelectric thin film as the gate dielectric layer, also referred to as the ferroelectric polarization layer or the ferroelectric gate dielectric layer or the ferroelectric dielectric layer. In a ferroelectric field effect transistor (FeFET), the polarization direction in the ferroelectric gate dielectric layer is controlled by an electric field applied between the transistor drain terminal (bit line 22) and the transistor gate electrode (gate conductor 28), where changes in the polarization direction alters the threshold voltage of the FeFET. In some embodiments, the electric field is applied to both the transistor drain and source terminals, relative to the transistor gate electrode. For example, the FeFET may be programmed to have either one of two threshold voltages, where each threshold voltage of the FeFET can be used to encode a given logical state. For example, the two threshold voltages of the FeFET can be used to encode a “programmed” state and an “erased” state, each representing a designated logical value. In one example, the programmed state is associated with a higher threshold voltage and the erased state is associated with a lower threshold voltage. In some embodiments, more than two threshold voltages may be established to represent more than two memory states at each FeFET.

Referring again to FIGS. 1(a) and 1(b), in embodiments of the present invention, each memory stack 17 includes local word line structures 13 arranged as a two-dimensional array in the X-Y plane. In particular, the local word line structures 13 are arranged in two lines extending and staggered in the Y-direction. A memory transistor 20 is formed at each intersection of the bit line 22/source line 24 and a local word line structure 13. As thus configured, in each active layer 16 of a memory stack 17, the bit line 22/source line 24 intersect multiple local word line structures 13 in the memory stack to form a NOR memory string of ferroelectric memory transistors 20. The local word line structures 13 intersect with the active layers 16 in the multiple planes to form NOR memory strings in the multiple planes of the memory structures. As thus configured, a three-dimensional array of NOR memory strings is formed to realize a high density and high capacity memory structure. In each memory stack 17, each local word line structure 13 is connected to a respective global word lines 30, extending in the X-direction. Accordingly, each memory transistor 20 in a NOR memory string is coupled to a different global word line 30. In operation, one global word line 30 is activated to select one local word line structure 13 in a memory string and one bit line 22 is selected to access one memory transistor from the multiple active layers 16 in the memory stack.

In the example shown in FIGS. 1(a) and 1(b), the memory structure 10 is illustrated by two memory stacks: memory stack 0 and memory stack 1, separated by a slit trench 19. Referring to FIG. 1(b), the memory stacks are illustrated as including two active layers: active layer 0 including bit line BL0 and SL0 and active layer 1 including bit line BL1 and SL1. The active layer 0 and active layer 1 are separated by the inter-layer isolation layer 15. In the example shown in FIG. 1(b), each memory stack is shown with four local word line structures 13. For memory stack 0, four local word line structures LWL0-0, LWL1-0, LWL2-0 and LWL3-0 are provided. For memory stack 1, four local word line structures LWL0-1, LWL1-1, LWL2-1 and LWL3-1 are provided. In each memory stack, each local word line structure 13 is connected to a respective global word line 30. That is, the local word line structures LWL0-x, LWL1-x, LWL2-x and LWL3-x are connected to different global word lines so that only one local word line structure in a memory stack is selected at a time by activation of the respective global word line. In the present example, four global word lines 30 are provided and extend in the X-direction: GWL0, GWL1, GWL2 and GWL3. The global word line GWL0 connects to the local word line LWL0-0 and LWL0-1. The global word line GWL1 connects to the local word line LWL1-0 and LWL1-1. The global word line GWL2 connects to the local word line LWL2-0 and LWL2-1. The global word line GWL3 connects to the local word line LWL3-0 and LWL3-1. As thus configured, each activated global word line selects one local word line structure in each memory stack. In the present embodiment, to facilitate connection of each local word line structure to the respective global word line, the array of pillar-shaped local word line structures in each memory stack are formed in a staggered arrangement in the Y-direction to enable each global word line to connect to only one local word line structure in a memory stack.

In the illustration shown in FIG. 1(b), a via 29 is used to illustrate the connection of the local word line structure to the respective global word line, with a darken cap portion illustrating a connection being made between the local word line structure and the global word line. The via 29 is illustrative only and not intended to represent actual physical element of the memory structure. In some embodiments, the global word lines 30 are formed using a damascene process and the global word line material makes contact with the exposed gate conductor layer in the top portion of the local word line structure.

In embodiments of the present invention, the memory transistors 20 in the memory structure 10 are junctionless ferroelectric memory transistors. Accordingly, each memory transistor 20 includes only conductive layers as the source and drain regions, without any semiconductor layers. The bit line and source line conductive layers are formed using a low resistivity metallic conductive material. In some embodiments, the bit line and source line conductive layers are metal layers, such as a titanium nitride (TiN) lined tungsten (W) layer, a tungsten nitride (WN) lined tungsten (W) layer, a molybdenum nitride (MoN) lined molybdenum (Mo) layer, or a liner-less tungsten or molybdenum or cobalt layer, or other metal layers. The channel spacer isolation layer 23 between the first and second conductive layers may be a dielectric layer, such as silicon dioxide (SiO₂), and is sometimes referred herein as the “channel spacer dielectric layer.” The channel layer 26 is an oxide semiconductor layer. In some examples, the channel layer 26 is formed using an amorphous oxide semiconductor material, such as indium gallium zinc oxide (InGaZnO or IGZO), indium zinc oxide (IZO), indium tungsten oxide (IWO), or indium tin oxide (ITO), or other such oxide semiconductor materials. An oxide semiconductor channel region has the advantage of a high mobility for greater switching performance and without concern for electron or hole tunneling. For example, an IGZO film has an electron mobility of 10.0-100.0 cm²/V, depending on the relative compositions of indium, gallium, zinc and oxygen.

To form the ferroelectric memory transistor, the memory transistor 20 includes a ferroelectric polarization layer in contact with the channel layer. The ferroelectric polarization layer (or “ferroelectric dielectric layer”) serves as the storage layer of the memory transistor. In some embodiments, the interfacial layer 25 may be provided between the oxide semiconductor channel layer and the ferroelectric polarization layer. The interfacial layer is a thin layer and may be 0.5 nm to 3.0 nm thick. In some embodiments, the interfacial layer is formed using a material with a high dielectric constant (K) (also referred to as “high-K” material). In some embodiments, the interfacial layer 25 may be a silicon nitride (Si₃N₄) layer, or a silicon oxynitride layer, or an aluminum oxide (Al₂O₃) layer. In one example, the interfacial layer, if present, may have a thickness of 1.5 nm when the ferroelectric polarization layer has a thickness of 4-5 nm. The inclusion of the interfacial layer 25 in FIGS. 1(a) to 1(e) is illustrative only and not intended to be limiting. The interfacial layer 25 is optional and may be omitted in other embodiments of the present invention. In other embodiments, the interfacial layer 25, when included, may be formed as a multi-layer of different dielectric materials. In the present description, a material with a high dielectric constant or a “high-K material” refers to a material with a dielectric constant larger than the dielectric constant of silicon dioxide or larger than a dielectric constant of 3.9.

In some embodiments, the ferroelectric polarization layer is formed of a doped hafnium oxide material, such as zirconium-doped hafnium oxide (HfZrO or “HZO”). In other embodiments, the hafnium oxide can be doped with silicon (Si), iridium (Ir) or lanthanum (La). In some embodiments, the ferroelectric polarization layer is a material selected from: zirconium-doped hafnium oxide (HZO), silicon-doped hafnium oxide (HSO), aluminum zirconium-doped hafnium oxide (HfZrAlO), aluminum-doped hafnium oxide (HfO₂:Al), lanthanum-doped hafnium oxide (HfO₂:La), hafnium zirconium oxynitride (HfZrON), hafnium zirconium aluminum oxide (HfZrAlO), and any hafnium oxide that includes zirconium impurities.

The ferroelectric polarization layer is an annular layer and contacts the channel layer on the outer circumference and contact the gate conductor layer on the inner circumference. In some embodiments, the gate conductor layer includes a conductive liner and a low resistivity conductor. The conductive liner may be provided as an adhesion layer for the gate conductor layer. In some examples, the conductive liner is a titanium nitride (TiN) layer, a tungsten nitride (WN) layer, or a molybdenum nitride (MoN), and the conductor is formed using tungsten or molybdenum, or other metals. In some cases, the conductive liner is not needed and the gate conductor layer includes only the low resistivity conductor, such as a liner-less tungsten or molybdenum layer. In other examples, the gate conductor layer can be a heavily doped n-type or p-type polysilicon layer, which can be used with or without the conductive liner. The gate conductor layer forms the control gate electrode of the memory transistor and functions as the local word line in the memory structure. In some embodiments, the gate conductor layer is a heavily doped N+ or heavily doped P+ polysilicon layer, where the heavily doped polysilicon layer influences the work function of the global word line and thus also shift the threshold voltage of the ferroelectric memory transistor.

As thus constructed, the oxide semiconductor channel layer 26 forms an N-type, unipolarity channel region where the bit line/source line conductive layers 22, 24, forming the drain and source terminals, directly contact the channel region. The ferroelectric memory transistor thus formed is a depletion mode device where the transistor is normally on (i.e., conducting) and can be turned off (i.e., non-conducting) by depleting the N-type carriers in the channel region. The threshold voltage of the ferroelectric memory transistor is a function of the thickness of the annular oxide semiconductor channel layer 26 in the X-Y plane. That is, the threshold voltage of the ferroelectric memory transistor is the amount of voltage necessary to deplete the carriers within the thickness of the oxide semiconductor channel region to shut off the ferroelectric memory transistor. In embodiments of the present invention, the ferroelectric memory transistor has a channel length in the Z-direction between the bit line 22 and the source line 24 and defined by the channel spacer isolation layer 23. Furthermore, in embodiments of the present invention, the ferroelectric memory transistor has a channel width defined by the circumference of the annular channel layer 26.

In embodiments of the present invention, the three-dimensional array of NOR memory strings of ferroelectric memory transistors can be applied to implement a non-volatile memory device or a quasi-volatile memory device. For example, a quasi-volatile memory has an average retention time of greater than 100 ms, such as about 10 minutes or a few hours, whereas a non-volatile memory device may have a minimum data retention time exceeding 5 years. As a quasi-volatile memory, the ferroelectric memory transistor 20 may require refresh from time to time to restore the intended programmed and erased polarization states. For example, the ferroelectric memory transistors 20 in memory structure 10 may be refreshed every few minutes or hours. In particular, the ferroelectric memory transistors in the present disclosure can form a quasi-volatile memory device where the refresh intervals can be on the order of hours, significantly longer than the refresh intervals of DRAMs which require much more frequent refreshes, such as in tens of milli-seconds.

A salient feature of the ferroelectric memory transistor 20 is that the memory transistor can have a very short channel length, which is operative to increase the voltage separation between the different threshold voltages and therefore realizing a large memory window, while the memory structure 10 can be manufactured without requiring costly lithography techniques to realize the short channel length. In particular, the channel length of the ferroelectric memory transistor 20 is determined by the thickness L1 of the channel spacer dielectric layer 23 (FIGS. 1(b), 1(d) and 1(c)). The thickness L1 can be accurately controlled during the deposition of the sublayers forming the initial film stack. The ability to control the thickness L1 of the dielectric layer 23 by deposition process, together with the very low channel leakage of oxide semiconductor channel layer, make it possible to provide a ferroelectric memory transistor 20 with very short channel length, such as a channel length of 5 nm, without needing to employ costly lithography such as extreme ultraviolet scanners (EUV) that are necessary to pattern short channels in planar transistors. In some embodiments, the channel length L1 of the memory transistor 20 can be between 5 nm and 20 nm, or between 5-7 nm.

Another benefit of a very short channel achieved in the memory transistor of the present invention is that during the memory program or erase operations, the fringing electric field at the source-channel intersection and the drain-channel intersection may overlap each other, which results in a fast program or erase of the entire length of the channel, corresponding to a polarized or depolarized ferroelectric dielectric layer, which has the effect of forming a wide memory window of operation. More specifically, with the short channel length, the ferroelectric memory transistor is operated so that the applied voltage and the fringing field result in polarization of the ferroelectric gate dielectric layer across the entire channel. Alternately, the wide memory window of operation can be exploited by operating the program and erase operations at only partial polarization or partial depolarization to reduce the stress on the oxide semiconductor layer of the ferroelectric memory transistor. In the present description, partial polarization refers to biasing the ferroelectric memory transistor to realize a polarization level in the ferroelectric dielectric layer that is between the positive and negative polarization states associated with the respective erased state and programmed state of the ferroelectric memory transistor. In the present description, the term “polarization state” is used herein to refer to the polarization direction of the ferroelectric dielectric layer, which can be a positive polarization state or a negative polarization state, such as being associated with the erased state or the programmed state of the ferroelectric memory transistor. Furthermore, in the present description, the term “polarization level” refers to different amounts of polarization achieved in the ferroelectric dielectric layer, which is related to different threshold voltage values induced by the polarization. In embodiments of the present invention, the ferroelectric memory transistor can be operated with bias voltages that induces only partial polarization to result in threshold voltage values that are within the full memory window capability of the ferroelectric memory transistor. In other embodiments, the wide memory window of the memory transistors enable the use of lower voltage operations for program and erase operations, thereby reducing the stress and increasing the endurance on the ferroelectric memory transistor.

Another salient feature of the ferroelectric memory transistor 20 is that the memory transistor has a large channel width to increase the transistor “on” current without having to increase the die size of the memory structure. The channel layer of the memory transistor is formed as an annular layer on the outer circumference of the pillar-shaped local word line structure. For a memory transistor formed with a sidewall channel layer of the similar planar dimension, the annular channel layer provides a channel width that is nearly 4 times larger than the sidewall channel of the same dimension. The larger “on” current of the memory transistor is beneficial for compensating for the larger bit line capacitance that may result from the increased channel width.

In embodiments of the present invention, the memory structure includes a memory array portion constructed as described above to form the three-dimensional array of NOR memory strings. To complete the memory device, the memory structure includes staircase portions provided at the ends of the memory strings (in the Y-directions). The thin-film memory transistors of the NOR memory strings are formed in the memory array portion while the staircase portions, on opposite sides of the array portion, include staircase structures to provide connections through conductive vias to the common bit lines and, optionally, the common source lines, of the NOR memory strings. In some embodiments, the common source lines are pre-charged to serve as virtual voltage reference source during programming, reading and erase operations, thereby obviating the need for a continuous electrical connection with the support circuitry during such operations. In the present description, the common source lines are described as being electrically floating to refer to the absence of a continuous electrical connection to the common source lines. In embodiments of the present invention, various processing steps for forming staircase structures in the memory structure can be used. The processing steps for forming the staircase structures can be before, after, or interleaved with the processing steps for forming the memory array portion.

The memory structures 10 and 10a of FIGS. 1(a)-1(c) illustrate the construction of a memory array including a three-dimensional array of NOR memory strings. In FIGS. 1(a) and 1(c), the memory structure 10 is shown with two memory stacks, eight active layers and five local word line structures. In FIG. 1(b), the memory structure 10 is shown with two memory stacks, two active layers and four local word line structures for simplicity of illustration. FIGS. 1(a) to 1(c) are illustrative only and are not intended to be limiting. In actual implementation, the memory structure may include 8, 16, 20 or more active layers, 1000 to 2000 memory stacks and 2000 to 4000 local word line structures. For example, the memory structure 10/10a may be provided with the suitable number of active layers, memory stacks and local word line structures to form a modular memory unit of 64 million memory transistors, representing 64 Mb of data. The memory structure 10 can be used as a building block for forming a high capacity, high density memory device. In embodiments of the present invention, the memory structure 10/10a represents a modular memory unit, referred to as a “tile,” and a memory device is formed using an array of the modular memory units. In one exemplary embodiment, a memory device is organized as a two-dimensional array of tiles, arrayed along the X- and Y-directions, where each tile includes a three-dimensional array of ferroelectric memory transistors with support circuitry for each tile formed under the respective tile. More specifically, a memory device includes multiple memory arrays of thin-film ferroelectric memory transistors organized as a 2-dimensional array of “tiles” (i.e., the tiles are arranged in rows and columns) formed above a planar semiconductor substrate. Each tile can be configured to be individually and independently addressed or larger memory segments (e.g., a row of tiles or a 2-dimensional block of tiles) may be created and configured to be addressed together. In some examples, each row of tiles (a “tile row”) may be configured to form an operating unit, which is referred to as a “bank.” A group of banks, in turn, form a “bank group.” In that configuration, the banks within a bank group may share data input and output buses in a multiplexed manner. Alternately, a memory device may include a large array of tiles that are individually accessed to maximize tile access frequencies and minimize tile access conflicts, thereby increasing the memory access bandwidth. As thus configured, the tile is a modular unit that allows flexibility in configuring the memory module to adapt to application requirements.

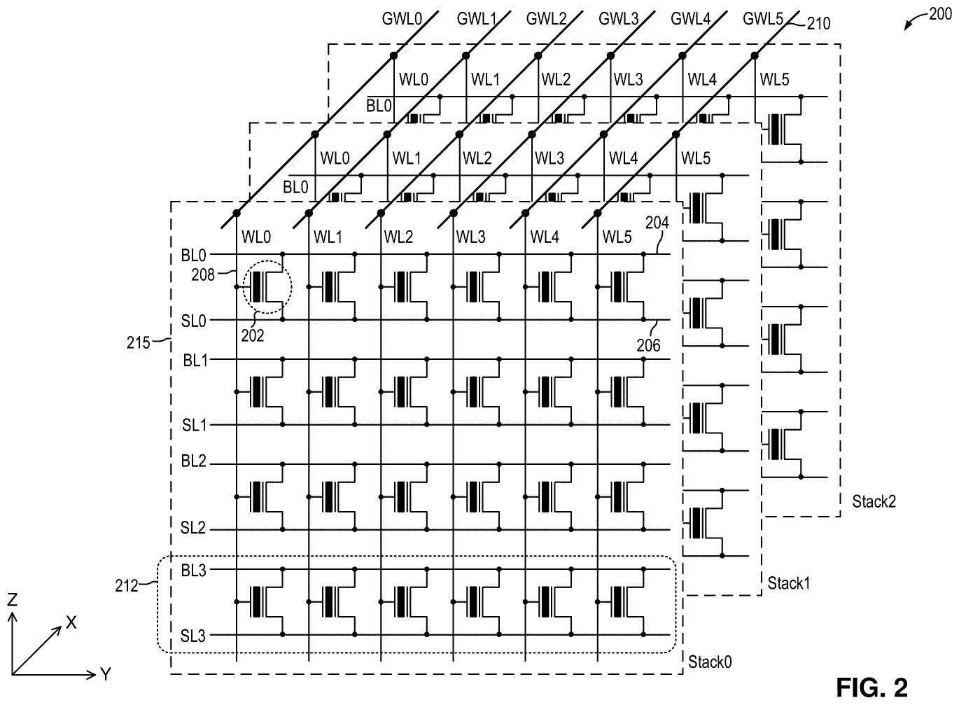

FIG. 2 is a transistor-level schematic diagram of a memory device including a three-dimensional array of NOR memory strings in embodiments of the present invention. In some embodiments, the memory device of FIG. 2 is constructed using one of the memory structures of FIGS. 1(a) to 1(c). That is, the memory device of FIG. 2 is constructed using the channel-all-around ferroelectric memory transistors described in FIGS. 1(a)-1(e). Referring to FIG. 2, a memory device 200 includes multiple NOR memory strings organized in a three-dimensional array to form a high density memory structure. The three-dimensional array of NOR memory strings is organized as stacks 215 of NOR memory strings 212, with NOR memory strings 212 formed one on top of another in each stack 215 in a third direction (e.g. the Z-direction). In FIG. 2, three memory stacks 215—Stack0, Stack 1, Stack2—are shown. The three-dimensional array of NOR memory strings is also organized as rows of NOR memory strings arranged in a first direction (e.g. the X-direction) forming a plane, with the rows of NOR memory strings arranged in one or more parallel planes that extend in the third direction. Each memory string 212 includes a series of memory transistors 202 organized in a NOR configuration with the memory transistors connected in parallel with each other between a common bit line 204 and a common source line 206. The memory transistors form a horizontal NOR memory string (also referred to as “HNOR memory string”) that extends in a second direction (e.g. the Y-direction). In the present embodiment, the memory transistors 202 are thin-film ferroelectric field-effect transistors (referred herein as “ferroelectric memory transistors”). Furthermore, in some embodiments, the memory transistors 202 are junctionless ferroelectric memory transistors formed with an oxide semiconductor channel.

Each ferroelectric memory transistor 202 in a respective memory string includes a drain terminal coupled to a respective bit line BLx (e.g. BL0, BL1, BL2, . . . ) and a source terminal coupled to a respective source line SLx (e.g. SL0, SL1, SL2, . . . ). The ferroelectric memory transistors 202 in a memory string 212 are therefore connected in parallel to a common bit line 204 and a common source line 206, forming the NOR memory string. Each ferroelectric memory transistor 202 in a respective memory string further includes a gate terminal coupled to a respective word line WLx (e.g. WL0, WL1, WL2, . . . ). The ferroelectric memory transistors 202 that are vertically aligned in a memory stack 215 across the several memory strings in the stack are connected to a common word line 208, referred herein as a local word line 208. The local word lines 208 across horizontally aligned memory transistors in the first direction (X-direction) are connected to a common global word line GWLx (e.g. GWL0, GWL1, GWL2, . . . ).

In some embodiments, the common source line 206 is electrically floating (that is, not provided with a continuous electrical connection) and the source voltage is applied from the common bit line using pre-charge transistors (not shown). For example, one or more pre-charge transistors are provided across a common bit line and a common source line. A voltage is applied to the common bit line and the pre-charge transistors are turned on to electrically short the common bit line to the common source line, thereby charging the common source line to the voltage on the common bit line. The pre-charge transistors are then turned off and the voltage is maintained on the common source line by the charge in an associated capacitor (“virtual ground”), such as the parasitic capacitance of the common source line. In other embodiments, the common bit line 204 and the common source line 206 are both electrically biased or driven, through a hardwire connection, by control circuits associated with the memory device 200. Implementing an electrically floating source line has the advantage of eliminating hardwire connections to mitigate the congestion of connector wires that may be needed at the staircase structures (not shown) of the three-dimensional array.

The ferroelectric memory transistors, as described herein, provide high endurance, long data retention, and relatively low voltage operations for both erase (e.g., under 3.0 volts gate-to-source voltage) and program (e.g., under −3.0 volts gate-to-source) operations. By combining the ferroelectric or polarization characteristics with the three-dimensional organization (e.g., as the thin-film NOR memory strings described herein), the memory device of ferroelectric memory transistors of the present invention achieves the additional benefits of high-density, low-cost memory arrays with the advantages of high-speed, randomly accessed memory circuits with low read latency.

In embodiments of the present invention, the three-dimensional array of NOR memory strings in memory device 200 is formed on a semiconductor layer, also referred to as a semiconductor substrate. To complete the memory circuit, various types of circuitry can be formed in or at the surface of the semiconductor substrate to support the operations of the NOR memory strings formed on the semiconductor substrate. Such memory control circuits are referred to as “circuits under array” (“CuA”) and may include digital and analog circuitry such as decoders, drivers, sense amplifiers, sequencers, state machines, logic gates, memory caches, multiplexers, voltage level shifters, voltage sources, latches and registers, and connectors, that execute repetitive local operations such as processing random address and executing activate, erase, program, read, and refresh commands with the memory arrays formed above the semiconductor substrate. In some embodiments, the transistors in the CuA are built using a process optimized for the memory control circuits, such as an advanced manufacturing process that is optimized for forming low-voltage and faster logic circuits. In some embodiments, the CuA is built using fin field-effect transistors (FinFET) or gate-all-around field-effect transistors (GAAFET) to realize a compact circuit layer and enhanced transistor performance.

In some embodiments, the memory device 200 is formed on a semiconductor substrate without circuitry built therein and the memory device 200 is bonded to a separate semiconductor substrate containing the memory control circuitry, such as using hybrid bonding. In one embodiments, hybrid bonds are formed on the top side of the memory array, opposite the semiconductor layer on which the memory array is built, to connect to mating hybrid bonds formed on a separate semiconductor layer which contains the control circuits for operating the memory array. The semiconductor layer or semiconductor substrate on which the memory device 200 is formed can be configured in different manner depending on the degree of integration with the memory control circuitry.

In some embodiments, the CuA provides the data path to and from the memory array and further to a memory controller that may be built on the same semiconductor substrate as the CuA. Alternatively, the memory controller may reside on a separate semiconductor substrate, in which case the CuA and the associated data path are electrically connected to the memory controller using various integration techniques, including, for example, hybrid bonding, through-silicon vias (TSVs), exposed contacts and other suitable interconnect techniques. In one example, the memory controller may be connected to the CuA using an electro-photonic based interconnection system.

In some examples, the memory controller includes control circuits for accessing and operating the memory transistors in the memory array connected thereto, performing other memory control functions, such as data routing and error correction, and providing interface functions with systems interacting with the memory array. In one example, the memory controller provides commands, such as erase, program and read commands, to the circuit under array (CuA), usually with accompanying information, such as the memory cell address and write data for the write operation. The memory array, using the circuit under array, performs the memory operation autonomously in response to the received command.

In the memory device 200, each memory transistor of a NOR memory string is read, programmed or erased by suitably biasing its associated word line 208 (WLx) and the common bit line 204 (BLy) it shares with other memory transistors in the NOR memory string 212. The memory transistor's associated word line is shared with memory transistors of NOR memory strings on other planes that are aligned with the memory transistor along the third direction (the Z-direction or “vertical direction”). In some embodiments, the common source line is normally electrically floating, that is, not hard-wire connected to any electrical potential. During read, program or erase operation, the common source line of the NOR memory string is typically provided a relatively constant voltage that is maintained either by a voltage source or by the charge in an associated capacitor (“virtual ground”), such as the parasitic capacitance of the common source line. For example, the common source line of the NOR memory string can be biased to a given voltage by a precharge operation where the desired voltage is provided on the common bit line and the common source line is charged to the voltage on the common bit line through one or more precharge transistors. To program or erase a selected memory transistor, for example, a sufficient voltage difference (e.g., 1.5V to 3V for ferroelectric memory transistor) is imposed across the word line and at least the common bit line. To mitigate disturb to a non-selected memory transistor, a predetermine voltage difference that is significantly less than the required voltage to program or erase may be imposed across the non-selected memory transistor's associated word line and its common bit line, so as to inhibit undesired erasing or programming of the non-selected memory transistor. To read a selected memory transistor, a read voltage (e.g. 1V for ferroelectric memory transistor) is applied to the word line and the bit line is biased to a positive voltage (e.g. ˜ 0.05V to ˜0.9V) to induce a current flow, if any, between the drain and source terminals of the selected memory transistor. The bit line current is sensed by a sense amplifier through a bit line selector to determine the logical state, or the stored data, of the selected memory transistor.

In some embodiments, to erase a selected memory transistor, the selected word line is biased to 2-3V and the selected bit line is biased to 0V with the source line set to 0V (such as by a precharge operation). An inhibit voltage of 1.1-1.5V is applied to the unselected word lines, bit lines and source lines. In some embodiments, to program a selected memory transistor, the selected word line is biased to 0V and the selected bit line is biased to 1.8-2V with the source line set to 0.5-0.8V (such as by a precharge operation). An inhibit voltage of 0.5-0.8V is applied to the unselected word lines, bit lines and source lines. In some embodiments, to read a selected memory transistor, the selected word line is biased to 0.7-1V and the selected bit line is biased to 0.5V with the source line set to 0V (such as by a precharge operation). An inhibit voltage of 0V is applied to the unselected word lines, bit lines and source lines.

In some embodiments, the channel-all-around ferroelectric memory transistor, with an annular channel layer, enables the use of different voltage magnitudes for the program and erase operation. In particular, the program voltage imposed across the word line and the common bit line to program the memory transistor to a first logical set has a first voltage magnitude. Meanwhile, the erase voltage imposed across the word line and the common bit line to erase the memory transistor to a second logical set has a voltage polarity opposite to the program voltage and has a second voltage magnitude. The annular channel layer enables the use of different voltage magnitudes for the program and erase voltages.

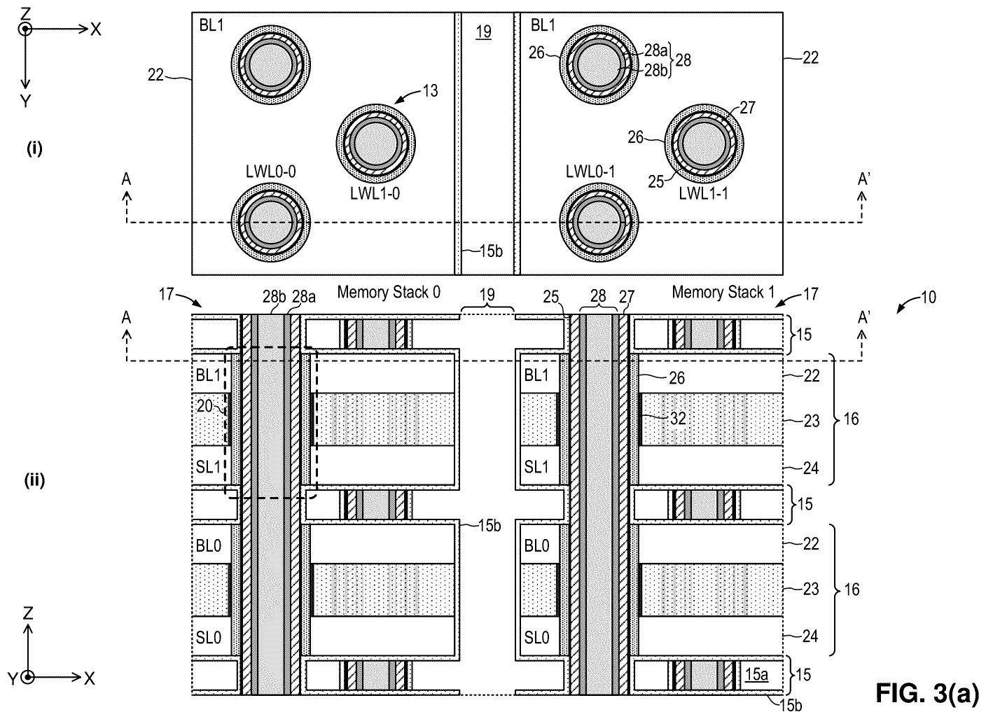

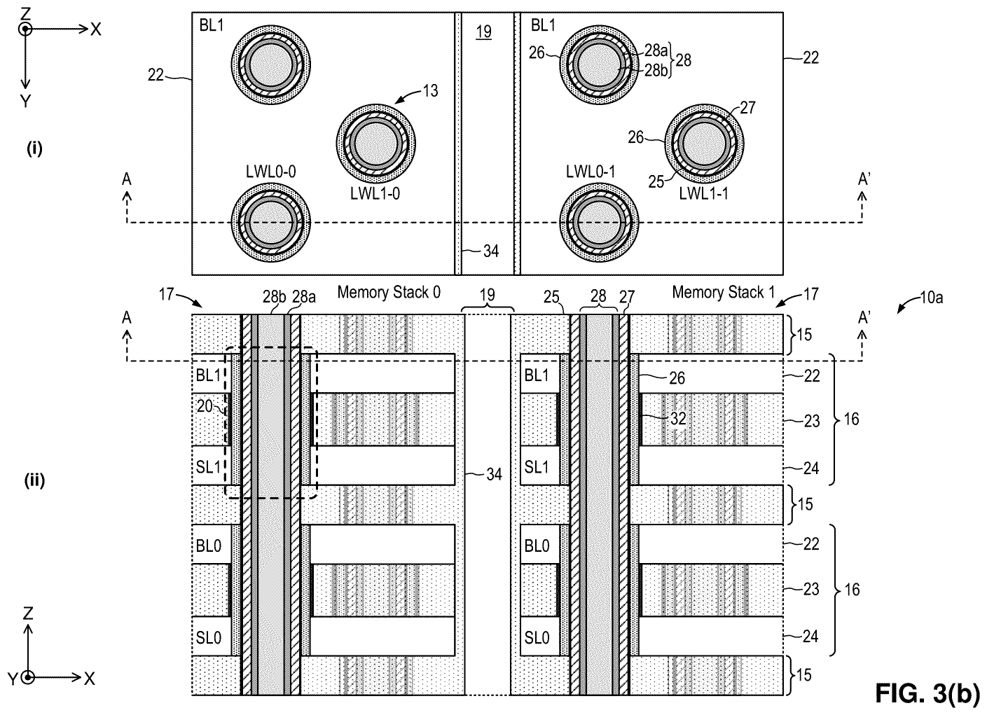

FIGS. 3(a) and 3(b) include cross-sectional views of the memory structures of FIGS. 1(a) and (c) in two different planes in embodiments of the present invention. Each of FIGS. 3(a) and 3(b) includes two views: view (i) is a horizontal cross-sectional view (i.e., in an X-Y plane) along line A-A′ in view (ii), and view (ii) is a vertical cross-sectional view (i.e., in an X-Z plane) along line A-A′ in view (i). Furthermore, the memory structures are shown in FIGS. 3(a) and 3(b) in expanded cross-sectional views to illustrate the detailed construction of the memory structures. In particular, FIG. 3(a) illustrates the cross-sectional views of two memory stacks in the memory structure 10 of FIG. 1(a) and FIG. 3(b) illustrates the cross-sectional views of two memory stacks in the memory structure 10a of FIG. 1(c).

Referring to FIG. 3(a), the memory structure 10 includes a pair of adjacent memory stacks 17—referred herein as memory stack 0 and memory stack 1—separated by a slit trench 19. View (i) of FIG. 3(a) illustrates the cross-sectional view in the X-Y plane at the bit line layer BL1. In the present embodiment, each memory stack 17 includes local word line structures 13 arranged in two lines that extend in the Y-direction. In each memory stack, the local word line structures 13 in the two lines are staggered in the Y-direction so that no two local word line structures are aligned in the X-direction. The staggering of the local word line structures enables the global word line connection to be made to just one local word line structure in each memory stack across several memory stacks.

In embodiments of the present invention, each local word line structure 13 is formed in holes formed in the memory stack during the fabrication process. The holes are circular holes in the present embodiment but can have other shapes in other embodiments. The concentric layers of the channel layer, the ferroelectric layer and the gate conductor layer are deposited into the holes, such as by using a damascene process and atomic layer deposition (ALD). For instance, each local word line structure 13 includes a channel layer 26 formed as an annular layer at the outer circumference of the holes, a ferroelectric dielectric layer 27 formed as an annular layer on the channel layer and a gate conductor layer 28 filling the remaining cavity of the hole. In some embodiments, an interfacial layer 25 may be provided between the channel layer 26 and the ferroelectric dielectric layer 27. As shown in view (i) of FIG. 3(a), each local word line structure 13 is encircled by the conductive layers forming the bit line 22 (common drain line) and the source line 24 (common source line). Referring to view (ii) of FIG. 3(a), in each memory stack 17, the bit line and source line conductive layers 22, 24 in each active layer encircle and are in contact with the annular channel layer 26 of each local word line structure 13 in the memory stack 17. In particular, a portion of the annular channel layer 26 is provided between or overlap the bit line 22 and the annular ferroelectric gate dielectric layer 27 in the X-Y plane; and a portion of the annular channel layer 26 is provided between or overlap the source line 24 and the annular ferroelectric gate dielectric layer 27 in the X-Y plane.

View (ii) of FIG. 3(a) illustrates the cross-sectional view in the X-Z plane at the local word line structures across the two memory stacks 17. In the present illustration, two active layers 16 of the memory structure 10 are shown, with the active layers being separated or isolated from each other by the inter-layer isolation layer 15, which is an air gap isolation in the present example. Each active layer 16 includes a first conductive layer 22 as the common drain line or bit line 22 and a second conductive layer 24 as the common source line or source line 24. Within an active layer 16, the first and second conductive layers are separated by the channel spacer dielectric layer 23, which defines the channel length of the memory transistor 20. As thus constructure, the first and second conductive layers 22, 24 (BL and SL) are formed in contact with and encircle the channel layer 26 to form the channel-all-around ferroelectric memory transistor 20.

The cross-sectional view in view (ii) of FIG. 3(a) is taken across the local word line structure LWL0-0 of memory stack 0 and LWL0-1 of memory stack 1. The local word line structures LWL1-0 and LWL1-1 are staggered in the Y-direction and can be observed through the air gap isolation 15. In the present illustration, the channel spacer dielectric layer 23 is shown with transparency to reveal the local word line structures LWL1-0 and LWL1-1 that are formed behind or staggered in the Y-direction. In practice, in the case the channel spacer dielectric layer 23 is a silicon dioxide (SiO₂) layer, the channel spacer dielectric layer 23 would be transparent to visible light.

In memory structure 10, each memory transistor 20 is isolated from adjacent memory transistors along a memory stack (in the Z-direction) by the inter-layer isolation layer 15. In the embodiment shown in FIG. 3(a), the inter-layer isolation layer 15 is an air gap isolation formed by an air gap cavity 15a and an optional air gap liner 15b. The air gap liner 15b is a dielectric layer used to cover or passivate the exposed surface of the air gap cavity 15a. In some embodiments, the air gap liner 15b is a silicon nitride layer or an aluminum oxide (Al₂O₃) layer. The air gap liner 15b may be 1 nm-3 nm thick. In FIG. 3(a), elements are sometimes exaggerated in size for illustrative purposes only. It is understood that the depictions in this and other figures are not necessarily to scale. The air gap cavities 15a forming the inter-layer isolation layer 15 provides effective isolation between adjacent memory transistors 20 along a memory stack 17. In embodiments of the present invention, the inter-layer isolation layer 15 is also used to provide physical separation between the channel layer 26 of one memory transistor and the channel layer of the memory transistors above or below it in the same memory stack, thereby providing isolation of each memory transistor in a memory stack. In particular, the channel layer 26 is removed in the inter-layer isolation region between two adjacent active layers so that the channel layer 26 is only formed within an active layer between and in contact with the first and second conductive layers forming the bit line 22 and the source line 24.

In alternate embodiments, the inter-layer isolation layer 15 is formed as a dielectric layer, as shown in FIG. 3(b). In some examples, after the channel layer is separated in the inter-layer isolation region between two adjacent active layers, a dielectric layer, such as a silicon dioxide (SiO₂) layer, is deposited, such as by atomic layer deposition (ALD), to fill the cavities of the inter-layer isolation region. The deposition process will also deposit the dielectric layer on the sidewall of the slit trench 19, as indicated by the sidewall portion 34. The remaining cavity of the slit trench 19 can be left unfilled to use as an air gap isolation, as shown in FIG. 3(b), or be filled with a dielectric layer, as shown in FIG. 1(c).

During intermediate processing steps, a dielectric liner layer 32 may be provided on the sidewall of the hole openings to provide a smooth surface for the deposition of the subsequent channel layer and ferroelectric dielectric layer. The dielectric liner layer 32 is removed during the metal replacement process to allow the bit line conductive layer and source line conductive layer to be in contact with the channel layer 26. Furthermore, the dielectric liner layer 32 is also removed between the active layers 16 to facilitate separation of the channel layer 26 between adjacent active layers. Therefore, in the resulting memory structure 10/10a as shown in FIGS. 3(a) and 3(b), only remnants of the dielectric liner layer 32 remain. In particular, portions of the dielectric liner layer 32 remain on the local word line sidewalls adjacent the channel spacer isolation layer 23. In some embodiments, the dielectric liner layer 32 is a silicon dioxide layer (SiO₂) and may have a thickness in the X-direction of about 2-3 nm.

In embodiments of the present invention, the memory structure 10/10a is formed from a multi-layer film stack of sacrificial materials and dielectric layers. After the local word line structures are formed, slit trenches 19 are formed in the multi-layer film stack to divide the film stack into multiple memory stacks 17. Thereafter, the slit trench 19 is used in a metal replacement process to replace certain sacrificial layers with the first and second conductive layers to form the bit line 22 and source line 24. The slit trench 19 is also used in a channel separation process to remove the channel layer in the inter-layer isolation region between active layers. After completion of the memory structure, the slit trench 19 can be filled with a dielectric layer, such as silicon dioxide, or the trench area can be left unfilled to use as air gap isolation. The fabrication process for making memory structure 10/10a will be described in more details below.

In some embodiments, the active layers of the memory structure 10 can be formed with thin films having a thickness in the Z-direction of 15 nm to 25 nm. In one embodiment, the first and second conductive layers have a thickness in the Z-direction of 20 nm and the channel spacer dielectric layer has a thickness in the Z-direction of 25 nm. In one embodiment, each local word line structure has a diameter of 55 nm and is spaced apart from adjacent local word line structures by 55 nm in the Y-direction. In other embodiments, the local word structures have a diameter of 40-70 nm. The memory stack and the slit trench has a pitch of 224 nm in the X-direction where the slit trench may have a width of 50-75 nm in the X-direction. The annular oxide semiconductor channel layer 26 has a thickness in the X or Y direction in the range of 5-10 nm. The annular ferroelectric dielectric layer 27 has a thickness in the X or Y direction in the range of 3-7 nm. In one example, the annular oxide semiconductor channel layer 26 has a thickness of 7 nm and the annular ferroelectric dielectric layer 27 has a thickness of 5 nm. The gate conductor layer fills the remaining volume of the local word line structure. In some embodiment, the gate conductor layer includes a conductive liner layer, such as titanium nitride (TiN), having a thickness of 2-3 nm.

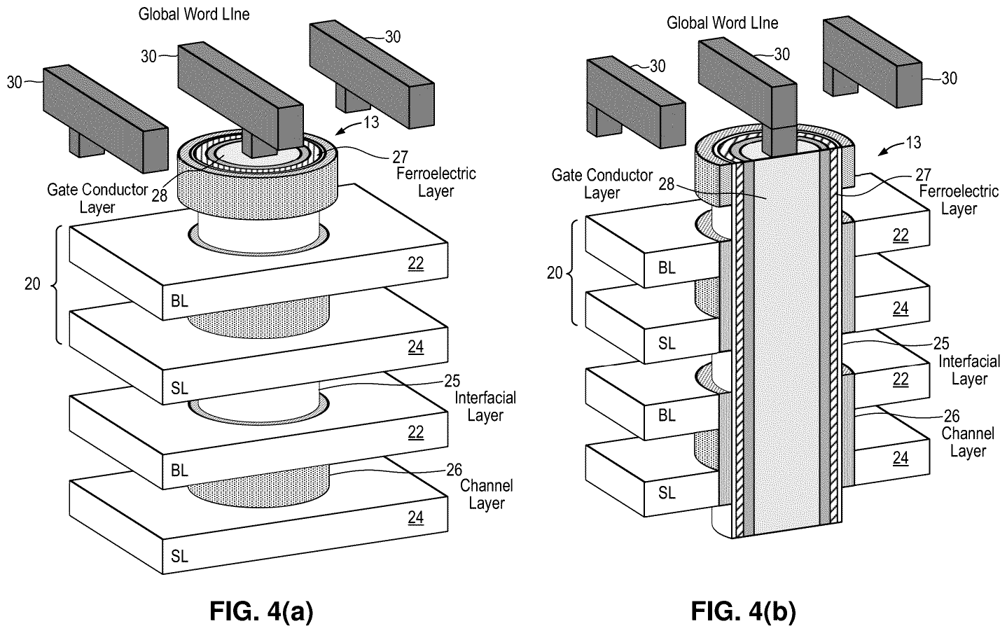

FIGS. 4(a) and 4(b) are expanded perspective views of the memory structure of FIGS. 1(a) to 1(c) in embodiments of the present invention. In particular, FIG. 4(a) illustrates an expanded view of a channel-all-around ferroelectric memory transistor 20 formed at a pillar-shaped local word line structure 13 with connection to the associated global word line 30. FIG. 4(b) is a cross-sectional view through the local word line structure 13. The perspective views in FIGS. 4(a) and 4(b) are shown with the dielectric layers omitted to better illustrate the memory transistor structure. Referring to FIGS. 4(a) and 4(b), the bit line conductive layer 22 and the source line conductive layer 24 encircle the pillar-shaped local word line structure 13 and the oxide semiconductor channel layer 26 has an annular shape formed around the ferroelectric gate dielectric layer 27 and the gate conductor layer 28. In the vertical direction, the oxide semiconductor channel layer 26 is formed between and in contact with the bit line conductive layer 22 and the source line conductive layer 24. The channel layer 26 is removed or separated in the inter-layer region between two adjacent active layers, i.e. between the source line 24 and the next bit line 22. In the present example, the local word line structure 13 includes an interfacial layer and the interfacial layer 25 is exposed in the inter-layer region. Alternately, the interfacial layer 25 may be completely or partially removed. As explained in FIGS. 3(a) and 3(b), the cavities in the inter-layer region and the slit trench cavities may be filled with a dielectric layer, such as silicon dioxide (SiO₂). Alternately, an air gap dielectric liner layer may be formed to passivate the exposed surfaces with the remaining cavities left to form an air gap isolation.

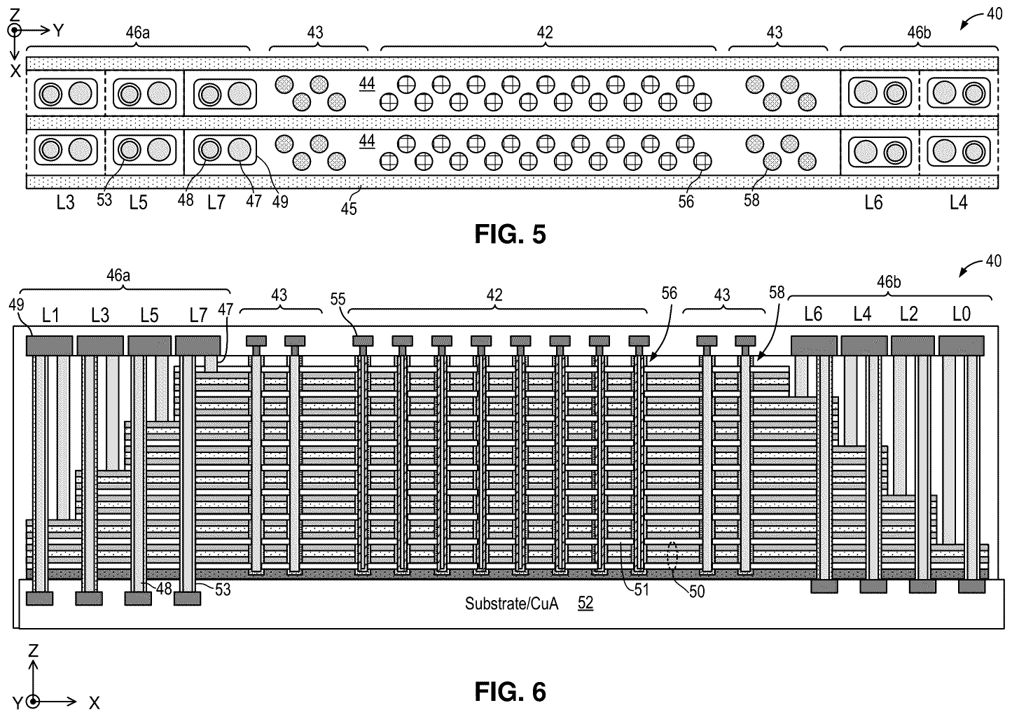

FIG. 5 is a top view of a memory structure including precharge transistors and staircase structures in embodiments of the present invention. FIG. 6 is a cross-sectional view of the memory structure of FIG. 5 including precharge transistors and staircase structures in embodiments of the present invention. Referring to FIGS. 5 and 6, a memory structure 40 includes a three dimensional array of NOR memory strings of channel-all-around ferroelectric memory transistors formed in multi-layer memory stacks. The memory structure 40 includes multiple memory stacks 44 arranged in the X-direction and separated from each other by slit trenches 45. Each memory stack 44 includes multiple active layers 50 separated by inter-layer isolation layer 51. In the present example, the memory stacks 44 include 8 active layers, L0 to L7. Each active layer 50 includes a first conductive layer as the common drain line or bit line, a second conductive layer as the common source line or source line, and a channel spacer dielectric layer in between.

Each memory stack 44 includes a memory array portion 42 including pillar-shaped local word line structures 56 for forming channel-all-around ferroelectric memory transistors at each intersection with an active layer 50. Each memory stack 44 further includes a precharge array portion 43 including pillar-shaped precharge local word line structures 58 for forming channel-all-around non-memory transistors at each intersection with an active layer 50. As explained above with reference to FIG. 2, non-memory precharge transistors are used to set the common source line voltage in case the common source line is left electrically floating in the memory structure. In some embodiments, the precharge transistors are formed using the same channel layer and the same gate conductor layer as the memory transistors. The precharge transistors are formed using a non-polarizable gate dielectric layer to form non-memory transistors.

Each memory stack 44 further includes staircase structures formed at two ends of the memory stack in the Y-direction. More specifically, each memory stack 44 includes odd staircase portion 46a and even staircase portion 46b. In each staircase portion, conductive vias 47 are provided to contact the common drain line (bit line) of the active layers and conductive vias 48 are provided to connect to circuitry formed in the semiconductor substrate 52. A metal line 49 connects a conductive via 47 to a conductive via 48 in each staircase step, thereby connecting a common drain line from one active layer to the circuitry formed in the semiconductor substrate. In the present embodiment, the conductive vias 48 are formed aligned with the respective conductive vias 47 in the Y-direction and are formed through the multi-layer memory stack. Accordingly, each conductive via 48 is encircled by a dielectric spacer layer 53 to prevent the conductive via from electrically shorting to the conductive layers in the active layers.

As thus configured, the memory structure 40 includes the odd staircase portion 46a that connects to the bit lines of the odd number of active layers (e.g., active layers L1, L3, L5 and L7) and the even staircase portion 46b that connects to the bit lines of the even number of active layers (e.g., active layers L0, L2, L4, L6). By using staircase portions 46a, 46b that connect to every other active layer, the fabrication process for forming the staircase portions is greatly simplified.

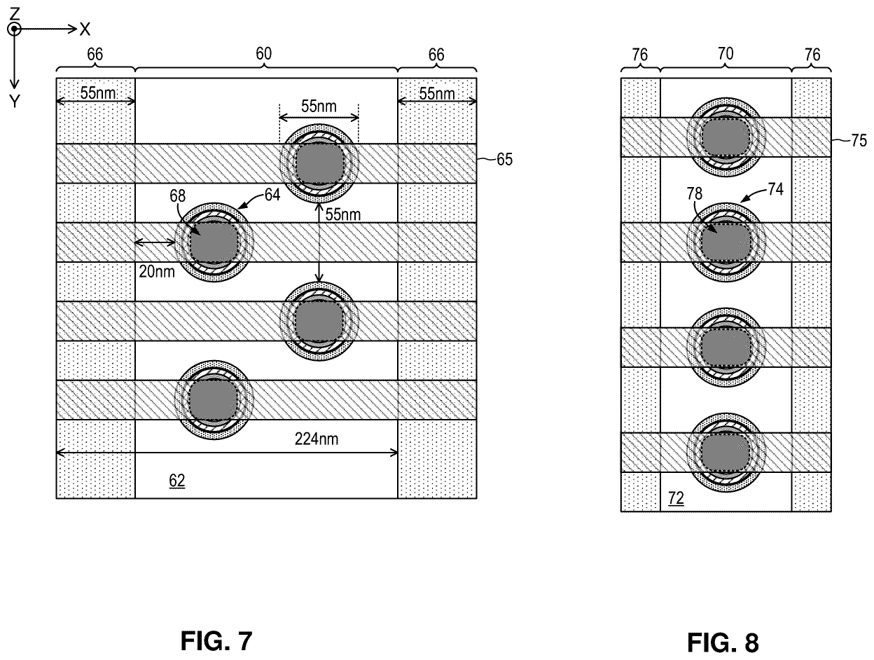

FIG. 7 is an expanded cross-sectional view of a memory stack including local word line structures in embodiments of the present invention. Referring to FIG. 7, a portion of a memory stack 60 with local word line structures 64 in the X-Y plane is shown. The cross-sectional view of FIG. 7 is taken across a bit line layer 62 in the memory stack. The memory stack 60 is bordered by slit trenches 66, both the memory stack and the slit trenches extending in the Y-direction. Global word lines 65 for connecting to respective local word line structures run in the X-direction.

In the embodiments shown in FIG. 7, the memory stack 60 includes two lines of local word line structures 64 arranged in the X-direction and extending in the Y-direction. In other words, the local word line structures 64 are arranged in a two-dimensional array in the X-Y plane. The local word line structures 64 are staggered in the Y-direction so that each global word line 65 that runs in the X-direction connects to a single local word line structure in each memory stack. In FIG. 7, a dotted circle 68 indicates the connection of the gate conductor layer in a local word line structure 64 to the respective global word line 65.

In the example shown in FIG. 7, each pillar-shaped local word line structure 64 has a diameter of 55 nm and is spaced apart from a neighboring local word line structure by 55 nm. The slit trench 66 is 55 nm and the pitch of the memory stack with slit trench is 224 nm. The local word line structures 64 have a margin of around 20 nm from the edge of the memory stack. In this configuration, the global word lines 65 have a pitch of 55 nm and each global word line 65 has a width of 27.5 nm in the Y-direction. In one embodiment, the global word lines 65 are formed using double patterning lithography, or self-aligned double patterning lithography. In other embodiments, the global word lines 65 can be formed using single patterning lithography.

FIG. 8 is an expanded cross-sectional view of a memory stack including local word line structures in an alternate embodiment of the present invention. Referring to FIG. 8, a portion of a memory stack 70 with local word line structures 74 in the X-Y plane is shown. The cross-sectional view of FIG. 8 is taken across a bit line layer 72 in the memory stack. The memory stack 70 is bordered by slit trenches 76, both the memory stack and the slit trenches extending in the Y-direction. Global word lines 75 for connecting to respective local word line structures run in the X-direction.

In the embodiments shown in FIG. 8, the memory stack 70 includes a single line of local word line structures 74 that extends in the Y-direction. Each global word line 75 that runs in the X-direction connects to a single local word line structure in each memory stack. In FIG. 8, a dotted circle 78 indicates the connection of the gate conductor layer in a local word line structure 74 to the respective global word line 75. When using a single line of local word line structures 74, the pitch of the global word lines 75 can be relaxed. The memory stack 70 is narrowed in the X-direction which can reduce the parasitic capacitance of the active layers. The length of the memory stack 70 in the Y-direction may be elongated to accommodate the desired number of local word line structures to form the desired number of memory transistors.

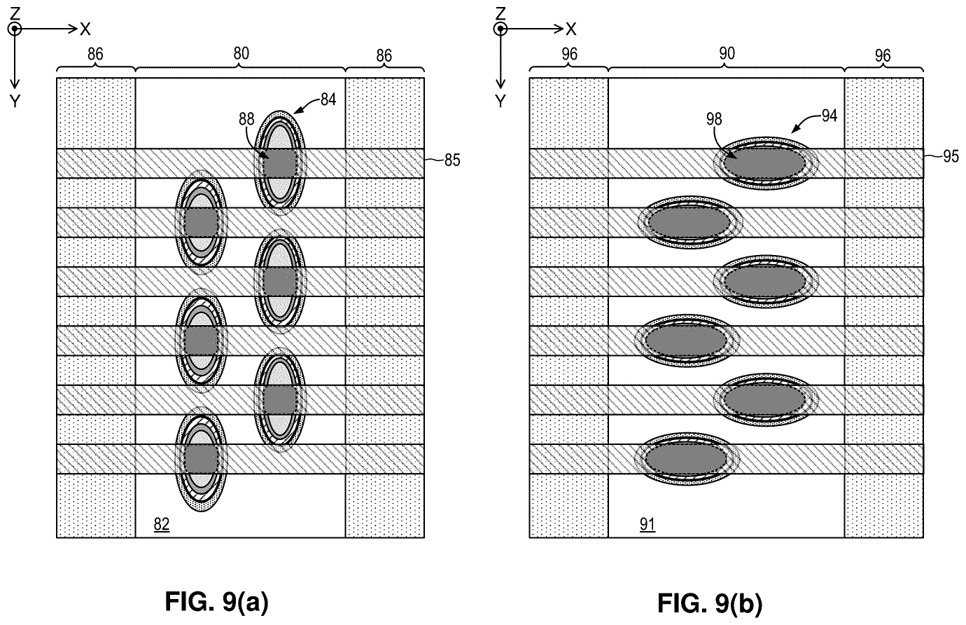

FIGS. 9(a) and 9(b) are expanded cross-sectional views of memory stacks including local word line structures in an alternate embodiments of the present invention. In the above described embodiments, the pillar-shaped local word line structures are formed using a circular openings in the X-Y plane. In other embodiments, the pillar-shaped local word line structures can be formed using an oval shape or having an oblong shape, as shown in FIGS. 9(a) and 9(b).

Referring first to FIG. 9(a), a portion of a memory stack 80 with local word line structures 84 in the X-Y plane is shown. The cross-sectional view of FIG. 9(a) is taken across a bit line layer 82 in the memory stack. The memory stack 80 is bordered by slit trenches 86, both the memory stack and the slit trench extending in the Y-direction. Global word lines 85 for connecting to respective local word line structures run in the X-direction.

In the embodiments shown in FIG. 9(a), the memory stack 80 includes two lines of local word line structures 84 arranged in the X-direction and extending in the Y-direction. Each local word line structure 84 has an oblong shape with the longer dimension in parallel with the Y-direction and the shorter dimension in parallel with the X-direction. The local word line structures 84 are staggered in the Y-direction so that each global word line 85 that runs in the X-direction connects to a single local word line structure 84 in each memory stack. In FIG. 9(a), a dotted circle 88 indicates the connection of the gate conductor layer in a local word line structure 84 to the respective global word line 85.

Referring now to FIG. 9(b), a portion of a memory stack 90 with local word line structures 94 in the X-Y plane is shown. The cross-sectional view of FIG. 9(b) is taken across a bit line layer 92 in the memory stack. The memory stack 90 is bordered by slit trenches 96, both the memory stack and the slit trench extending in the Y-direction. Global word lines 95 for connecting to respective local word line structures run in the X-direction.

In the embodiments shown in FIG. 9(b), the memory stack 90 includes two lines of local word line structures 94 arranged in the X-direction and extending in the Y-direction. Each local word line structure 94 has an oblong shape with the longer dimension in parallel with the X-direction and the shorter dimension in parallel with the Y-direction. The local word line structures 94 are staggered in the Y-direction so that each global word line 95 that runs in the X-direction connects to a single local word line structure 94 in each memory stack. In FIG. 9(b), a dotted circuit 98 indicates the connection of the gate conductor layer in a local word line structure 84 to the respective global word line 85.

In embodiments of the present invention, the pillar-shaped local word line structure can be formed using a circular shape, an oval shape or an oblong shape. The channel layer and the ferroelectric dielectric layer are formed as annular concentric layers in the pillars regardless of the shape of the pillars. The specific shape of the pillar for the local word line structure can be selected to optimize the placement or the density of the local word line structures that can be formed in the memory stack, taking into account the dimensions of the global word lines that are to be formed above the memory stack to connect to the local word line structures.

In the embodiments described above in FIGS. 5 and 6, the memory structure is formed with hardwire connection to the bit lines only while the source line is left electrically floating, i.e. without a hard wire or continuous electrical connection. Precharge transistors are used to set the source line to the desired voltage for each given memory operation. In alternate embodiments, the memory structure of the present invention can be configured with physical or hard wire connection to both the bit lines (common drain lines) and the source lines (common source lines) through the staircase structures.

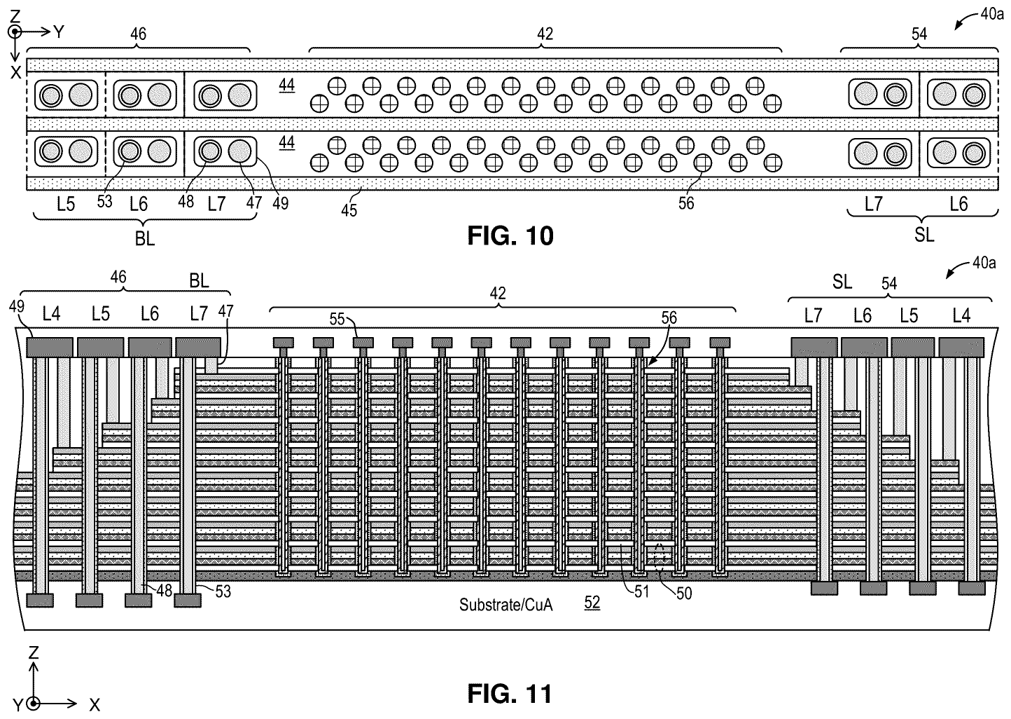

FIG. 10 is a top view of a memory structure including staircase structures connecting to common bit lines and common source lines in embodiments of the present invention. FIG. 11 is a cross-sectional view of the memory structure of FIG. 10 including staircase structures connecting to common bit lines and common source lines in embodiments of the present invention. Referring to FIGS. 10 and 11, a memory structure 40a includes a three dimensional array of NOR memory strings of channel-all-around ferroelectric memory transistors formed in multi-layer memory stacks. The memory structure 40a includes multiple memory stacks 44 arranged in the X-direction and separated from each other by slit trenches 45. Each memory stack 44 includes multiple active layers 50 separated by inter-layer isolation layer 51. In the present example, the memory stacks 44 include 8 active layers, L0 to L7. Each active layer 50 includes a first conductive layer as the common drain line or bit line, a second conductive layer as the common source line or source line, and a channel spacer dielectric layer in between. In the cross-sectional view of FIG. 11, the common source lines of the active layers 50 are given a cross-hatch pattern to distinguish the source lines from the bit lines in the active layers. The use of different patterns in the cross-sectional view in FIG. 11 does not necessarily suggest that the common source lines and the common drain lines are formed of different conductive materials. In most cases, the common source lines and the common drain lines are formed of the same conductive material. Similarly, in FIGS. 6 and 11 (and FIG. 16 to be described below) the channel spacer dielectric layer in the active layers 50 and the inter-layer isolation layer 51 are shown using different pattern to distinguish the two layers. The use of different patterns in the cross-sectional view in FIGS. 6, 11 and 16 does not suggest that the channel spacer dielectric layer and the inter-layer isolation layer 51 are necessarily formed of different materials. In some embodiments, the channel spacer dielectric layer and the inter-layer isolation layer 51 are both formed of the same dielectric material, such as a silicon dioxide layer. In other embodiments, the channel spacer dielectric layer is a silicon dioxide layer and the inter-layer isolation layer 51 may be implemented as an air-gap isolation.

Each memory stack 44 includes a memory array portion 42 including pillar-shaped local word line structures 56 for forming channel-all-around ferroelectric memory transistors at each intersection with an active layer 50. In memory structure 40a, no non-memory precharge transistors are needed as the source line is hard wired. Each memory stack 44 includes staircase structures formed at two ends of the memory stack in the Y-direction. In the present embodiment, each memory stack 44 includes a bit line staircase portion 46 and a source line staircase portion 54. In the bit line staircase portion 46, conductive vias 47 are provided to contact the common drain line (bit line) of each active layers 50 and conductive vias 48 are provided to connect to circuitry formed in the semiconductor substrate 52. A metal line 49 connects a conductive via 47 to a conductive via 48 at each staircase step, thereby connecting the common drain line of each active layer to the circuitry formed in the semiconductor substrate. In the source line staircase portion 54, conductive vias 47 are provided to contact the common source line (source line) of each active layers 50 and conductive vias 48 are provided to connect to circuitry formed in the semiconductor substrate 52. A metal line 49 connects a conductive via 47 to a conductive via 48 at each staircase step, thereby connecting the common source line of each active layer to the circuitry formed in the semiconductor substrate.

In the present embodiment, the conductive vias 48 of both staircase portions 46, 54 are formed aligned with the respective conductive vias 47 in the Y-direction and are formed through the multi-layer memory stack. Accordingly, each conductive via 48 is encircled by a dielectric spacer layer 53 to prevent the conductive via from electrically shorting to the conductive layers in the active layers.

As thus configured, the memory structure 40a includes the bit line staircase portion 46 that connects to the bit lines of all of the active layers (i.e., active layers L0 to L7) and the source line staircase portion 54 that connects to the source lines of all of the active layers (i.e., active layers L0 to L7). By using staircase portions 46 and 54, the memory transistors in the memory structure 40a have both the bit lines and the source lines hard wire connected to circuitry in the semiconductor substrate. Accordingly, the source line can be provided with a bias voltage directly to effectuate memory operations.

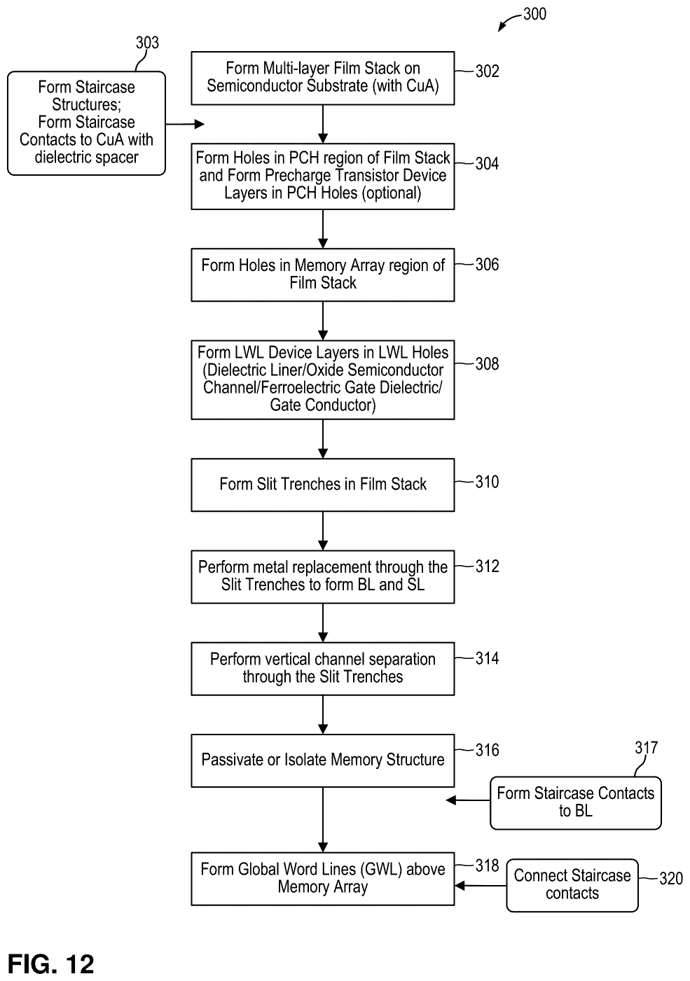

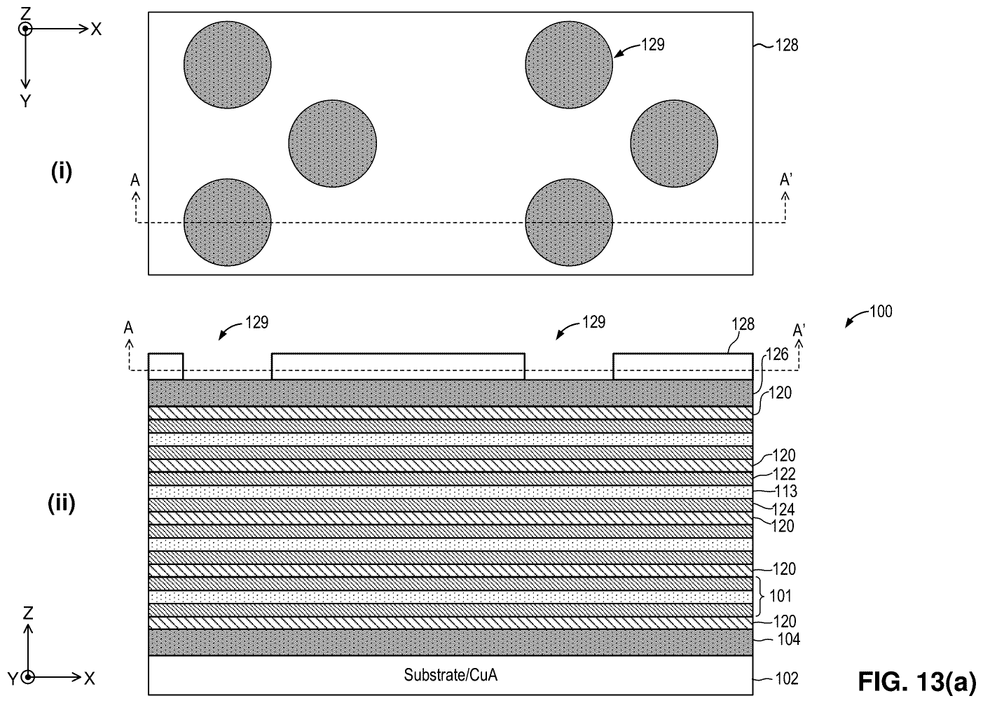

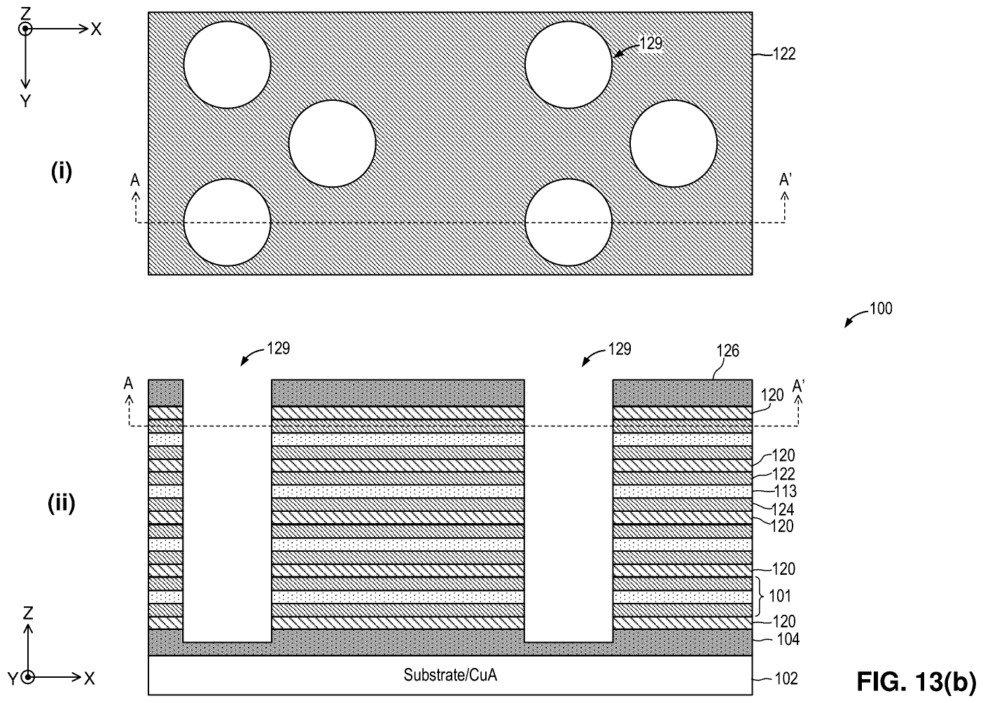

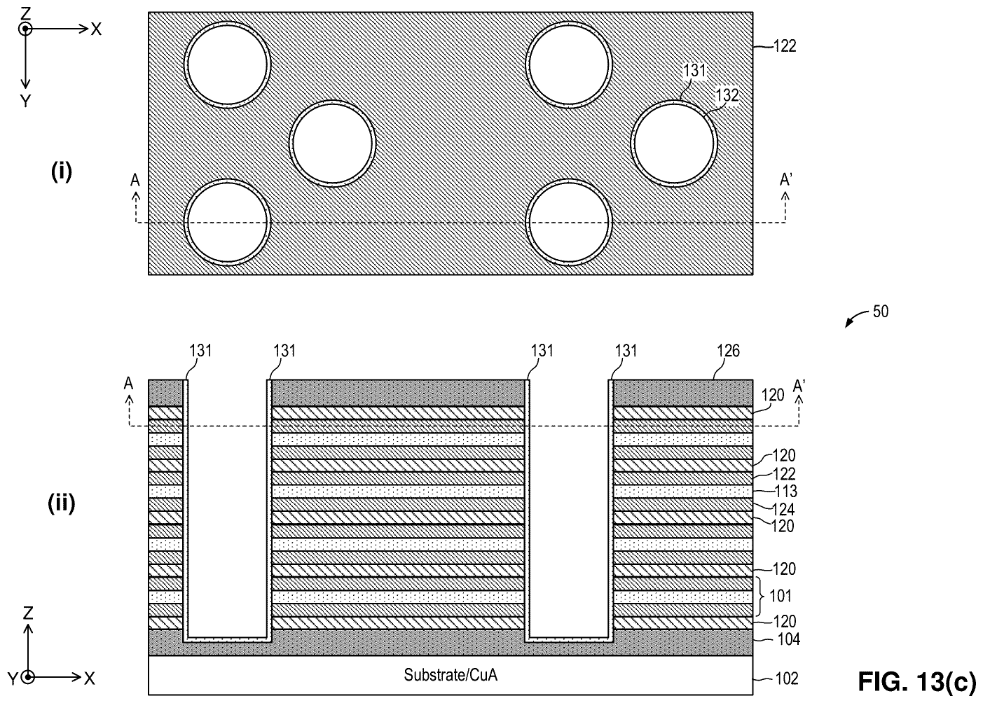

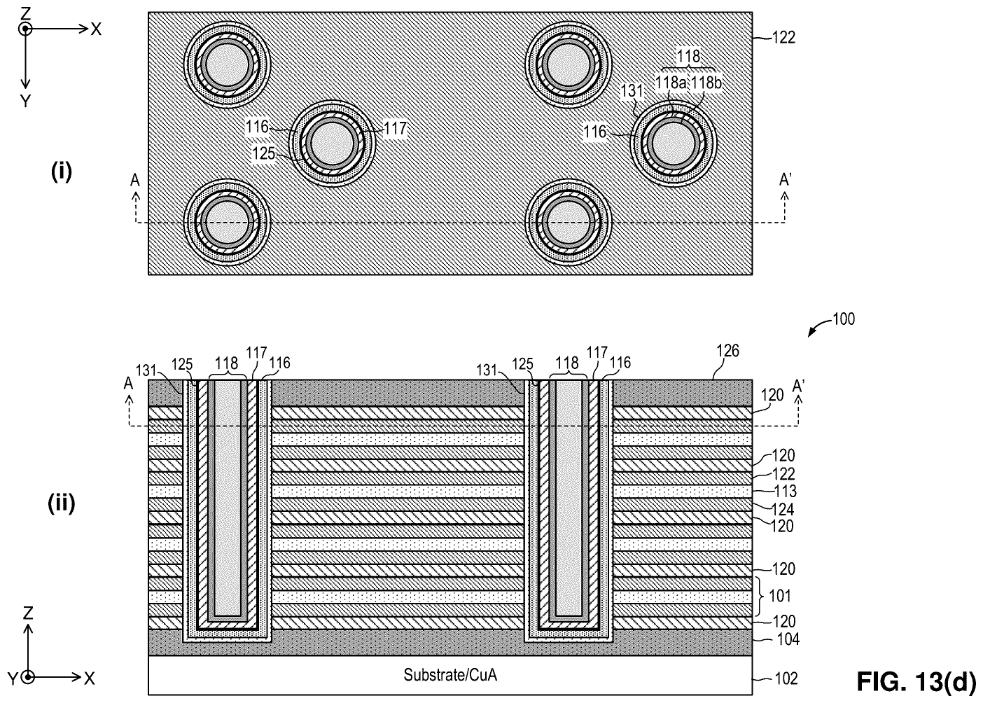

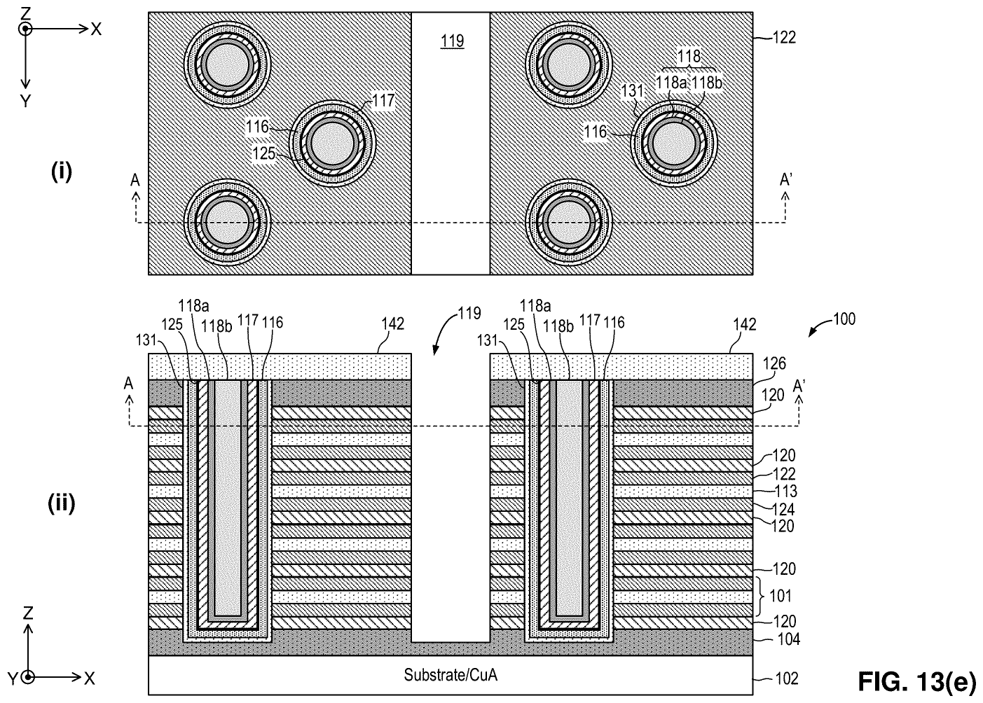

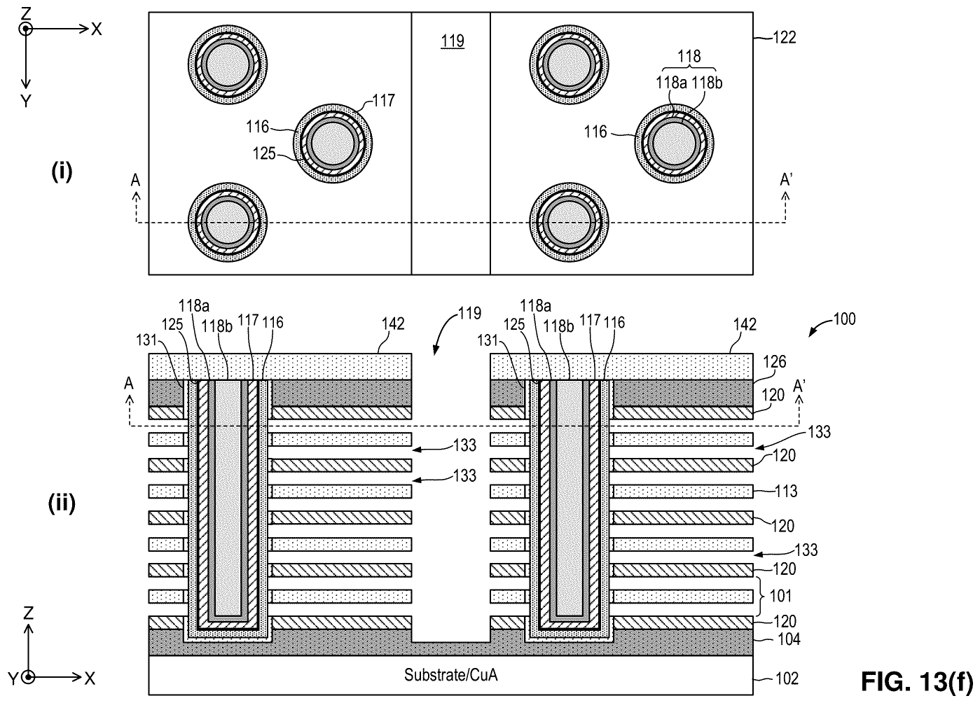

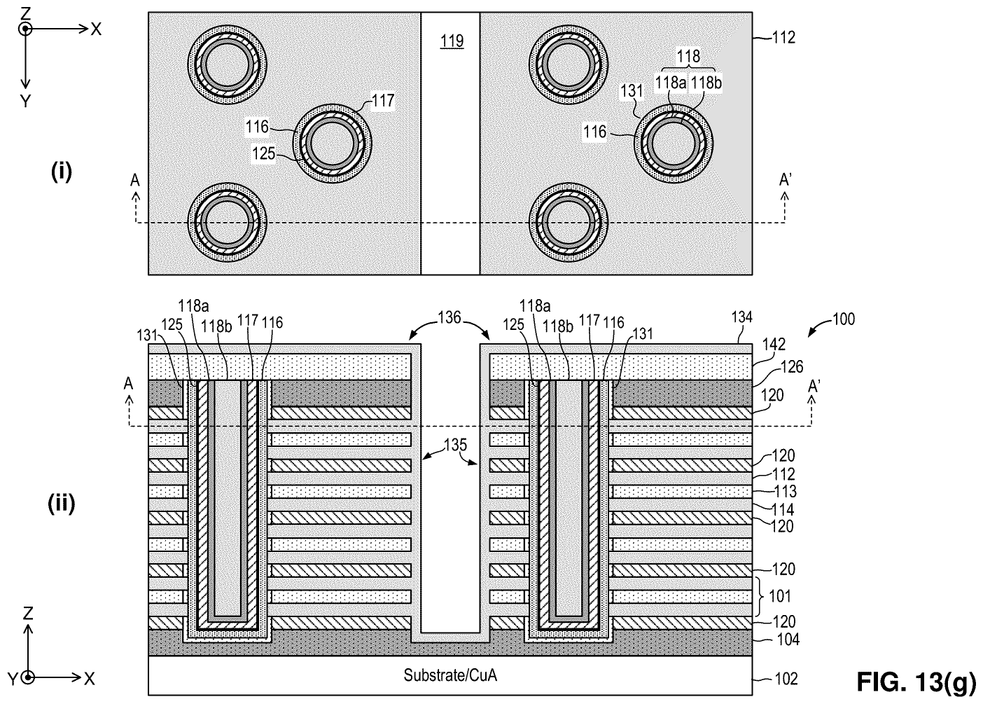

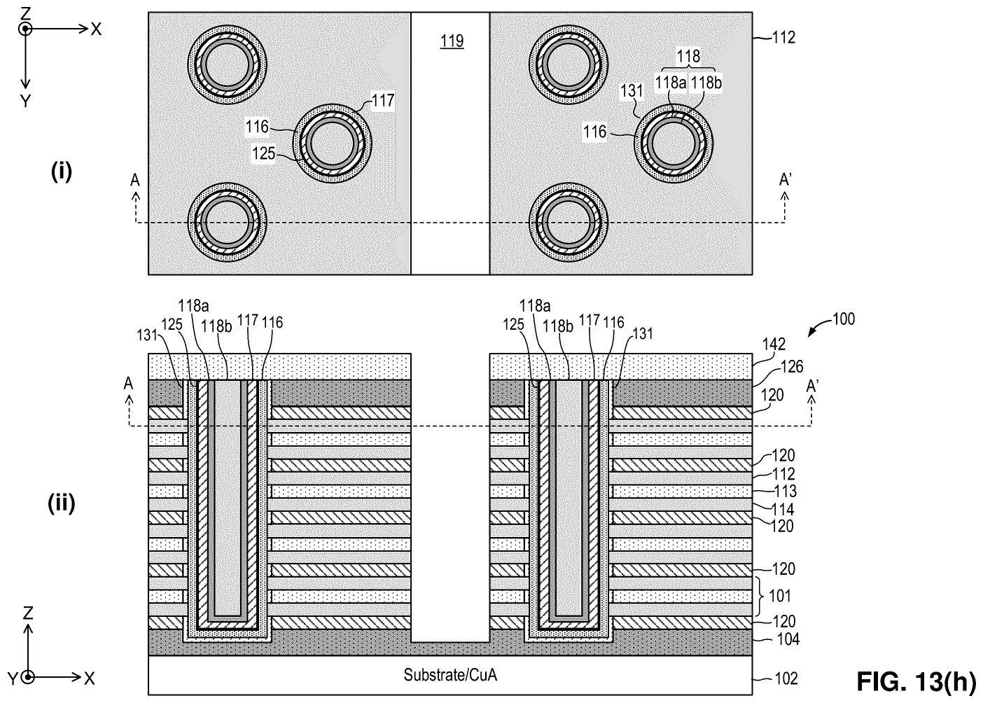

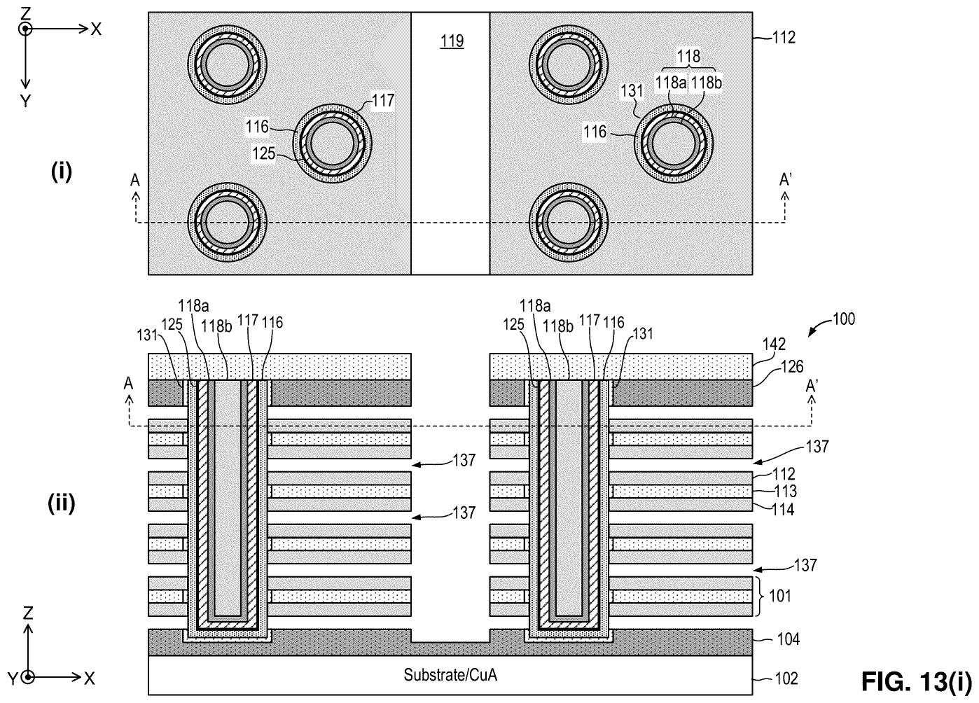

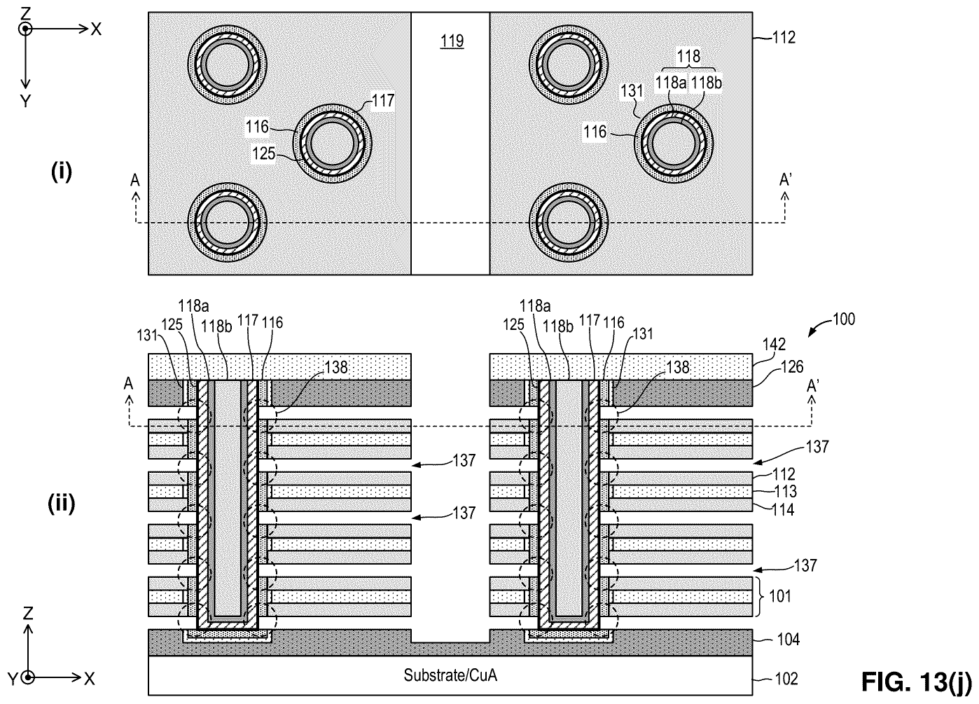

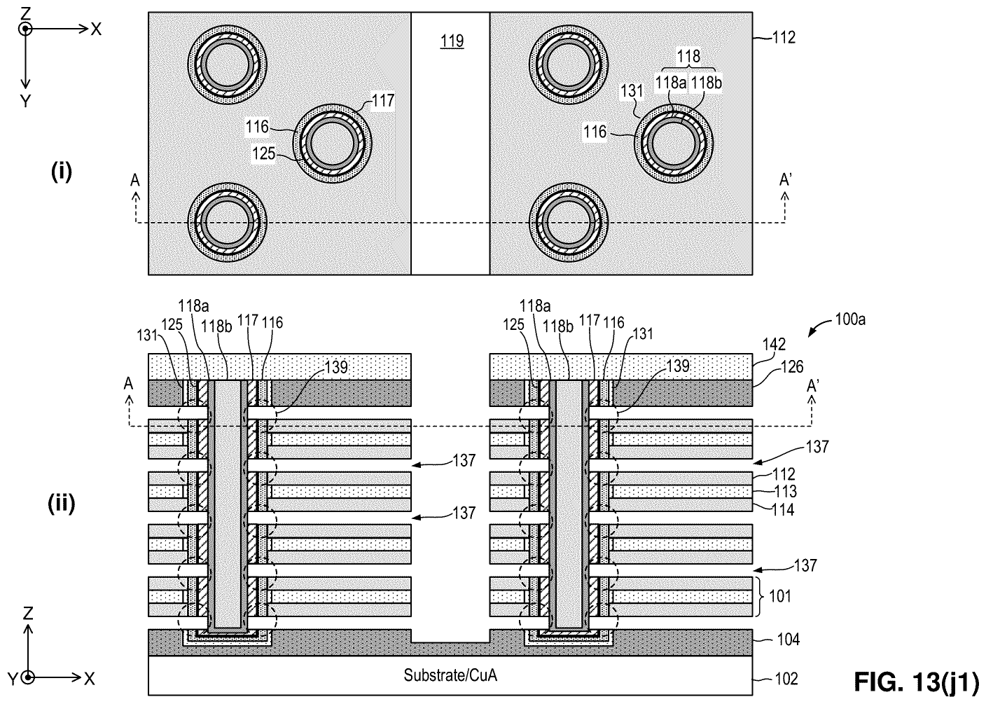

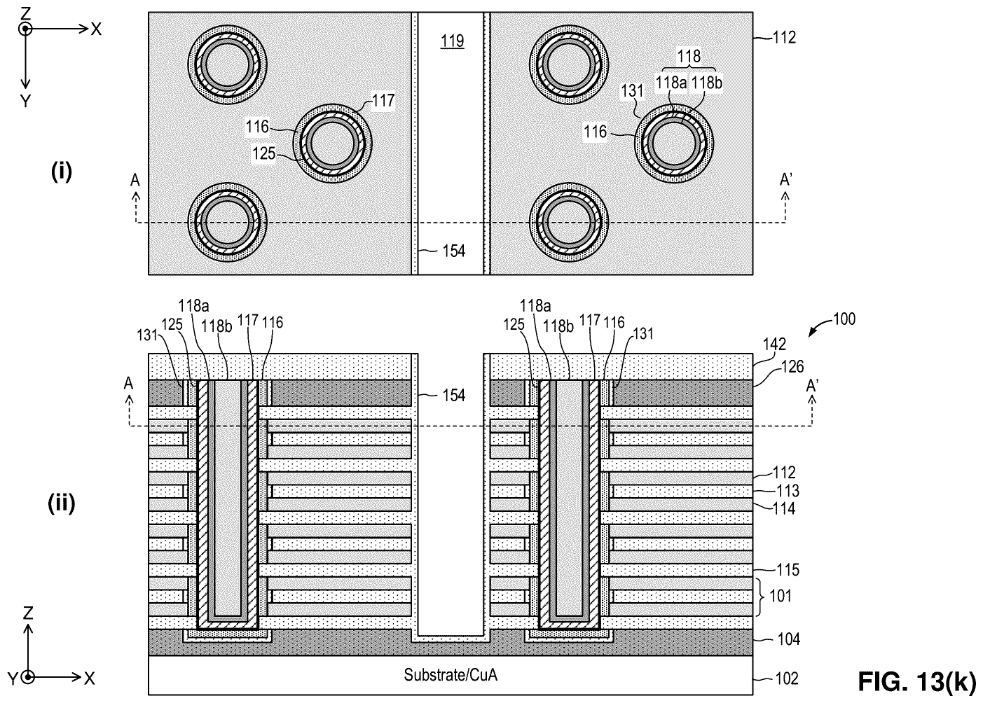

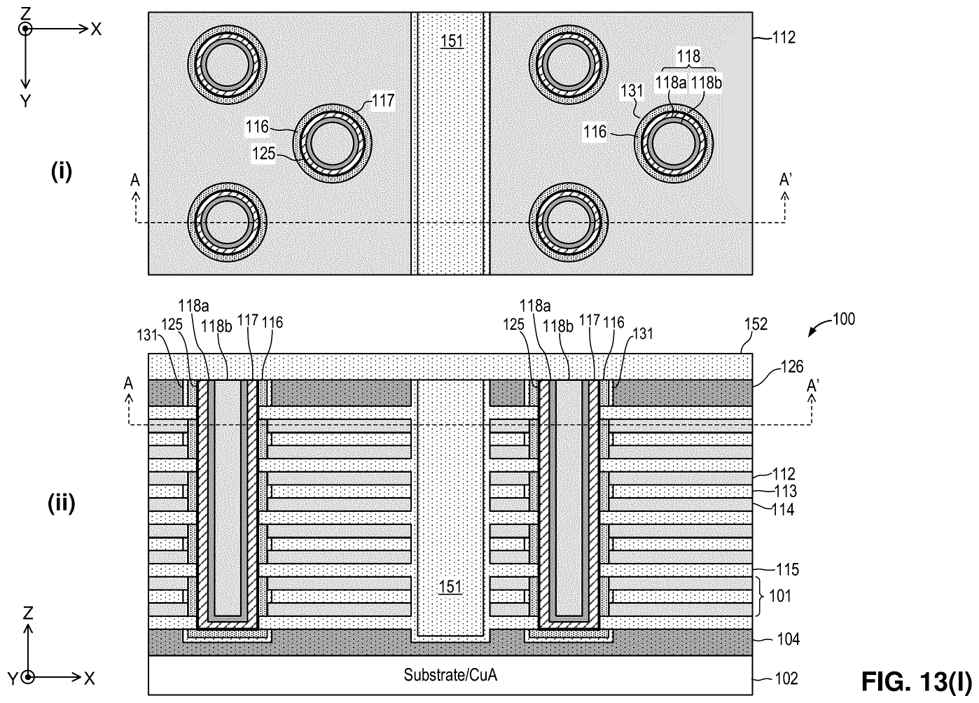

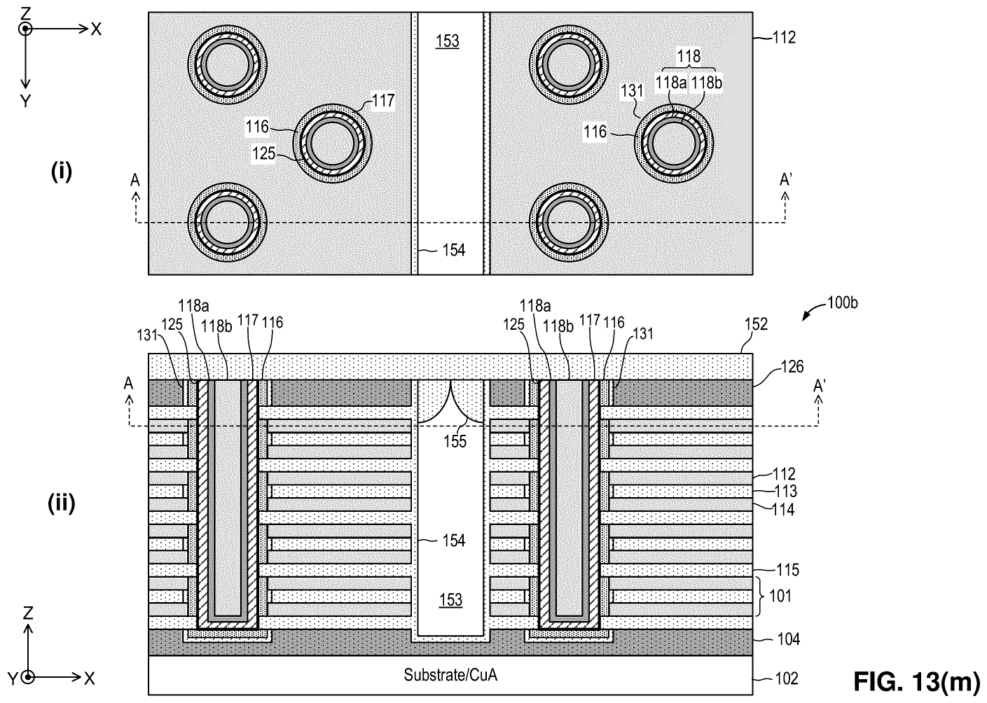

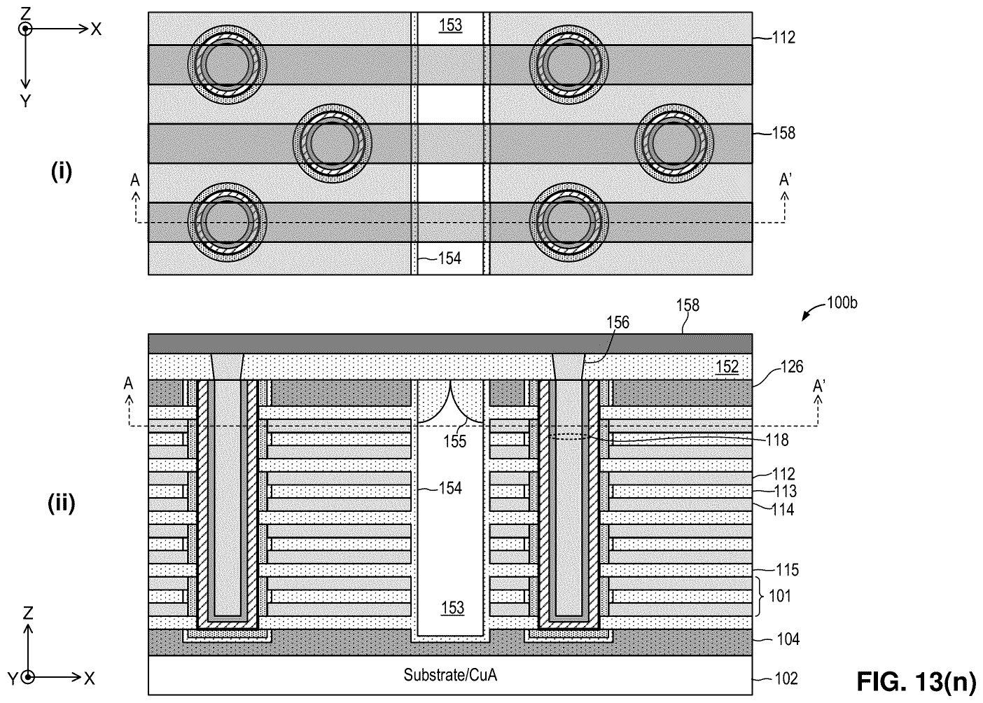

FIG. 12 is flowchart of a fabrication process for forming a memory structure including channel-all-around ferroelectric memory transistors in embodiments of the present invention. FIGS. 13(a) to 13(n), including FIG. 13 (j1), illustrate the memory structure during intermediate process steps in the fabrication process of FIG. 12 in some embodiments. The following description refers to FIG. 12 and FIGS. 13(a) to 13(n) and 13 (j1). Each figure in FIGS. 13(a) to 13(n) and 13 (j1) includes two views: view (i) is a horizontal cross-sectional view (i.e., in an X-Y plane) along line A-A′ in view (ii), and view (ii) is a vertical cross-sectional view (i.e., in an X-Z plane) along line A-A′ in view (i).

Referring to FIG. 12, a fabrication process 300 for forming channel-all-around ferroelectric memory transistors in a memory structure starts at 302 with forming a multi-layer film stack on a semiconductor substrate. As shown in FIG. 13(a), initially, a semiconductor substrate 102 is provided and any circuitry to be formed in the substrate 102, such as the CuA and the interconnect conductors, are fabricated in or on the substrate 102. An insulating layer 104 is provided on top of the semiconductor substrate to cover and protect the circuitry formed on and in the semiconductor substrate 102. In some embodiments, the insulating layer 104 is a dielectric layer which may also serve as an etch stop layer for the subsequent processing steps. In some embodiments, the insulating layer 104 is a silicon oxycarbide (SiOC) layer or an aluminum oxide (Al₂O₃) layer. The insulating layer 104 can be formed using any material with suitable selectivity for the subsequent etch processes to be performed.

Subsequently, a multi-layer film stack is formed by successive depositions of (i) a multilayer 101 and (ii) an inter-layer sacrificial layer 120 on the planar surface of the semiconductor substrate 102, or in particular on the insulating layer 104 formed on the substrate 102. In the present example, an inter-layer sacrificial layer 120 is deposited on the insulating layer 104 before the first multilayer 101 is deposited. The multilayer 101 includes three sublayers: (a) a first sacrificial layer 122, (b) a channel spacer dielectric layer 113, and (c) a second sacrificial layer 124, in this order in the Z-direction. FIG. 13(a) shows the memory structure 100 after the depositions of the initial layers of thin films. Multilayer 101 is also referred to in this detailed description as an “active layer.” View (i) in FIG. 13(a) illustrates the horizontal cross-section along a line A-A′ in the first sacrificial layer 122 in view (ii). View (ii) in FIG. 13(a) illustrates the vertical cross-section of the memory structure 100 along the line A-A′ shown in view (i). The first and second sacrificial layers 122 and 124 are to be replaced by respective conductive layers in subsequent processing. The inter-layer sacrificial layer 120 (also referred herein as the third sacrificial layer) is to be replaced by an isolation material in subsequent processing to form an inter-layer isolation layer for providing separation between the active layers, as will be described in more details below. In one embodiment, each sublayer in the multilayer 101 and the inter-layer sacrificial layer 120 has a thickness of typically 30 nm or less. In another embodiment, the sublayers in the multilayer 101 and the inter-layer sacrificial layer 120 do not have the same thickness. In the present description, the dimensions are provided merely for illustrative purposes and are not intended to be limiting. In actual implementation, any suitable thicknesses or dimensions may be used.

In some embodiments, the memory structure 100 may include lowermost and uppermost sublayers that are designated as dummy layers that do not necessarily form part of an active layer or part of the memory transistors. Furthermore, in the present embodiment, the memory structure 100 includes a topmost inter-layer sacrificial layer 120 and an etch stop layer 126 formed on the topmost inter-layer sacrificial layer 120. The topmost inter-layer sacrificial layer 120 will be subsequently replaced by an inter-layer isolation layer. The etch stop layer 126 is used as a stop layer for subsequent chemical mechanical polishing (CMP) process. In some embodiments, the etch stop layer 126 is a silicon oxycarbide (SiOC) layer or a silicon nitride (Si₃N₄) layer. In the example shown in FIG. 13(a), the multi-layer film stack includes four active layers. In other examples, the multi-layer film stack can be formed using any suitable number of one or more active layers.

In some embodiments, the first and second sacrificial layers 122 and 124 are each a silicon nitride (Si₃N₄) layer. The channel spacer dielectric layer 113 is an insulating dielectric material, such as silicon dioxide (SiO₂). The inter-layer (or third) sacrificial layer 120 is a sacrificial material selected from carbon, amorphous silicon (aSi), or silicon germanium (SiGe). In one embodiment, the inter-layer sacrificial layer 120 is an amorphous silicon (a-Si) layer.

After the multi-layer film stack is formed with the desired number of active layers 101, the fabrication process 300 may proceed to form the staircase structures on opposite sides of the memory structure (FIG. 12, 303). Various methods for forming the staircase structures are known in the art and can be applied to form the staircase structures for contacting at least the common drain line in the memory structure to be formed. For example, the staircase structures can be formed by successively masking and etching each multilayer of the film stack. The detail staircase process will not be described herein and the staircase structures are not shown in FIG. 13(a). After the staircase structures are formed, the memory structure is filled with a dielectric layer and staircase contact openings to the circuitry formed in the substrate 102 are formed, with one contact opening provided for each staircase step. In embodiments of the present disclosure, the fabrication process 300 may form contact openings in the staircase structures, such as by means of a dry etch process. The contact openings are made through the multi-layer film stack to the semiconductor substrate for connection to circuitry formed therein. A dielectric spacer layer is formed in the contact openings. For example, the dielectric spacer layer may be a silicon dioxide layer (SiO₂). The bottom portion of the dielectric spacer layer is punched through and a conductive layer is deposited to fill the contact openings. In this manner, contacts to circuitry formed in the semiconductor substrate is formed. In some embodiment, the conductive layer is a titanium-nitride lined tungsten layer (TiN/W). After the deposition step, excess material may be removed from the top of memory structure 100 using, for example, chemical-mechanical polishing (CMP), with the CMP process stopping on the etch stop layer 126. In the present description, the staircase contacts to circuitry in the semiconductor substrate are sometimes referred to as “CC contacts”.

In the case where the memory structure uses precharge transistors for setting the common source line voltage, the fabrication process 300 may proceed to form the precharge transistors in a precharge transistor (PCH) portion of the memory structure (FIG. 12, 304). Precharge transistors are optional and may be omitted in other embodiments of the present invention. For instance, the memory structure may be provided with a hardwire connection to the common source lines and therefore precharge transistors are not needed to set the source line voltage. In one embodiment, to form the precharge transistors, hole openings are made in the PCH portion of the multi-layer film stack. Device layers for the precharge transistors are then deposited into the hole openings, such as by using an atomic layer deposition (ALD) process. In some embodiments, the device layers for the precharge transistors include a dielectric liner layer, a channel layer, a non-memory gate dielectric layer, and a gate conductor layer. In one embodiment, the dielectric liner layer is a silicon dioxide layer with a thickness of 2 nm, the channel layer is an oxide semiconductor layer (e.g. IGZO) with a thickness of 5 nm, the non-memory gate dielectric layer is an aluminum oxide (Al₂O₃) layer with a thickness of 5 nm and the remaining volume is filled with a titanium-nitride lined tungsten layer.

In embodiments of the present invention, the processing steps for forming the staircase structures and/or the precharge transistors (if any) can be before, after, or interleaved with the processing steps for forming the memory transistors. The order of the fabrication process steps described herein is illustrative only and not intended to be limiting.

The fabrication process 300 proceeds to forming the memory transistors in the memory array portion of the memory structure. Referring FIG. 13(a), a masking layer 128 is applied on the memory structure (on the etch stop layer 126) and is patterned with hole openings 129. In some embodiments, the masking layer 128 is an amorphous hard mask, such as an amorphous carbon hard mask. The masking layer 128 is patterned, for example, using a photolithography patterning step (through the use of a mask and a patterning layer) followed by a mask open process, to form the openings 129 where holes are to be formed in the multi-layer film stack. It is instructive to note that the masking layer 128 is not drawn to scale in FIG. 13(a) and it is understood that an amorphous hard mask of sufficient thickness is used in the high-aspect-ratio etch process of the multi-layer film stack of the memory structure 100. Furthermore, it is understood that the photolithography and mask open processes may involve additional masking layers (not shown) to form the hole patterns in the masking layer 128, as understood by one skilled in the arts.

With the hole pattern thus defined in the masking layer 128, the fabrication process 300 proceeds to form holes in the multi-layer film stack using a high-aspect-ratio etch process (FIG. 12, 306). For example, a selective anisotropic dry etch process is applied to form the holes in the multi-layer film stack using the masking layer 128. After the hole etch process, remaining portions of the masking layer 128 is removed and the resulting structure is shown in FIG. 13(b). In the example shown in FIG. 13(b), two sets of hole openings 129 representing memory transistors to be formed in two memory stacks are made. In each set, the hole openings are arranged in two columns in the X-direction and the openings are staggered in the Y-direction. In some embodiments, the diameter of the hole openings is between 55-70 nm. In one embodiment, the hole openings have dimension, spacing and pitch as described above with reference to FIG. 7. As will be described in more detail below, a slit trench to be formed will divide the memory structure into separate mesas, each mesa housing one set of hole openings and the memory transistors to be formed in the hole openings. In the present description, the hole openings 129 are sometimes referred to as LWL holes.

In some embodiments, the fabrication process forms the LWL holes using a mask with a mask pattern of hole openings having a first diameter. After printing the hole openings onto the patterning layer (such as a photoresist layer) and transferring the mask pattern onto the masking layer, the size of the hole openings in the masking layer 128 is further adjusted or enlarged, such as by additional etching. In this manner, a larger hole size with a smaller pitch can be realized which exceeds the photolithography limitations. The enlarged masking layer is then used to etch the multi-layer film stack using a high-aspect-ratio etch process.

The fabrication process 300 then proceeds to form the device layers for the memory transistors in the LWL holes 129 (FIG. 12, 308). The memory transistor device layers are deposited into the LWL holes 129, such as by using an atomic layer deposition (ALD) process. In some embodiments, the device layers for the memory transistors include a dielectric liner layer, a channel layer, a ferroelectric gate dielectric layer, and a gate conductor layer. In some embodiments, an interfacial layer may be included between the channel layer and the ferroelectric gate dielectric layer. First, referring to FIG. 13(c), a dielectric liner layer 131 is deposited on the sidewalls of the LWL holes 129. For example, the dielectric liner layer 131 is deposited conformally on the sidewalls of the LWL holes 129. In one embodiment, the dielectric liner layer 131 is deposited by atomic layer deposition (ALD), chemical vapor deposition (CVD) or a combination thereof. In the present embodiment, the dielectric liner layer 131 is a silicon dioxide layer (SiO₂). In other embodiments, the dielectric liner layer 131 can be another dielectric material that has etch selectivity to the material used for the first and second sacrificial layers 122, 124 and to the channel layer to be formed. In one example, the dielectric liner layer 131 has a thickness of 1-5 nm in the X-direction. For example, the dielectric liner layer 131 may have a thickness of 2 nm in the X-direction in one embodiment. The dielectric liner layer 131 has the benefits of providing a uniform and even surface for the subsequent deposition of the memory transistor device layers.

The fabrication process 300 then proceeds to form local word line (LWL) structures in the LWL holes that are lined with the dielectric liner layer. One or more deposition steps are carried out to deposit the device layers of the ferroelectric memory transistors. In some embodiments, deposition of the device layers of the memory transistors includes depositing an oxide semiconductor channel layer 116 and then a ferroelectric gate dielectric layer 117, as conformal annular concentric layers, in the LWL holes. For example, the channel layer 116 and the gate dielectric layer 117 can be deposited using an atomic layer deposition (ALD) process, a chemical vapor deposition (CVD) process or a combination thereof. The remaining cavities of the LWL holes are then filled with a gate conductor layer 118, such as by use of an ALD technique. In some embodiments, an interfacial layer 125 is deposited between the channel layer and the ferroelectric gate dielectric layer, such as by use of an atomic layer deposition (ALD) technique. After the deposition steps, excess material may be removed from the top of memory structure using, for example, chemical-mechanical polishing (CMP). FIG. 13(d) illustrates the resulting memory structure.

In one embodiment, the oxide semiconductor channel layer 116 is an IGZO layer and the ferroelectric gate dielectric layer 117 is a zirconium-doped hafnium oxide (HZO) layer. In some embodiments, the oxide semiconductor channel layer 116 and the ferroelectric gate dielectric layer 117 are deposited in the same process chamber without breaking vacuum between the deposition processes. In some embodiments, the gate conductor layer 118 is a metal layer and can include a thin conductive liner 118a and a conductive filler material 118b. The thin conductive liner 118a may be a titanium nitride (TiN) liner or a tungsten nitride (WN) liner. The conductive filler material 118b may be a metal, such as tungsten (W) layer or molybdenum (Mo), or heavily doped n-type or p-type polysilicon. In one embodiment, the gate conductor layer 118 is a titanium-nitride lined tungsten layer (TiN/W). The interfacial layer 125, if present, is an aluminum oxide (Al₂O₃) layer. In one embodiment, the oxide semiconductor channel layer 116 has a thickness of 5-10 nm in the X-direction and may have a thickness of 7 nm in the X-direction in one example. In one embodiment, the ferroelectric gate dielectric layer 117 has a thickness of 3-6 nm in the X-direction and may have a thickness of 5 nm in the X-direction in one example. The gate conductor layer 118 fills the remaining volume of the LWL holes.

In some embodiments, the optional interfacial layer 125 has a thickness of 1.5 to 3 nm in the X-direction and may have a thickness of 2 nm in the X-direction in one example. In one embodiment, the interfacial layer 125 is an aluminum oxide (Al₂O₃) layer and is annealed to yield an amorphous film with the desired characteristics. In some embodiments, the aluminum oxide (Al₂O₃) layer can be annealed in oxygen (O₂), ozone (03), nitrous oxide (N₂O), forming gas (H2N₂), or argon (Ar). The interfacial layer 125 is optional and may be omitted in other embodiments of the present invention. In some embodiments, the interfacial layer 125 may be deposited in the same process chamber as the ferroelectric gate dielectric layer, without breaking vacuum between the deposition of the two layers.

In the present embodiment, the memory structure 100 is used to form ferroelectric memory transistors and the gate dielectric layer 117 is a ferroelectric material forming a ferroelectric gate dielectric layer. For example, the ferroelectric gate dielectric layer is deposited using an atomic layer deposition (ALD) technique. After deposition, a thermal anneal is performed to crystallize the as-deposited ferroelectric material into the ferroelectric phase. In some embodiments, the ferroelectric gate dielectric layer is a doped hafnium oxide material, such as zirconium-doped hafnium oxide (HfZrO or “HZO”). The ferroelectric phase of HZO is the orthorhombic phase of the material. In some embodiments, the HZO ferroelectric gate dielectric layer is annealed in the presence of a conductive capping layer to crystallize the as-deposited HZO film into the desired orthorhombic phase. In embodiments of the present invention, the fabrication process 300 performs the thermal annealing of the ferroelectric gate dielectric layer after deposition of a conductive capping layer on the ferroelectric gate dielectric layer. In one embodiment, the conductive capping layer is a titanium-nitride layer. In one embodiment, the conductive capping layer forms the conductive liner layer of the gate conductor layer. After the annealing process, the conductive filler material of the gate conductor layer is deposited onto the conductive liner layer. In another embodiment, the conductive capping layer is a sacrificial capping layer and is removed after the annealing process, such as by use of an etch process selective to the ferroelectric gate dielectric layer 117. The gate conductor layer, including a thin conductive liner (e.g. TiN) and a conductive filler material (e.g. W), is then deposited onto the annealed ferroelectric gate dielectric layer.

In one embodiment, the fabrication process 300 forms the LWL structures in the LWL holes by depositing the oxide semiconductor channel layer 116 on the dielectric liner layer 131 and depositing the ferroelectric gate dielectric layer 117 on the oxide semiconductor channel layer 116. The optional interfacial layer 125 may be deposited on the oxide semiconductor channel layer 116 before deposition of the ferroelectric gate dielectric layer 117, such as being deposited in the same process chamber without breaking vacuum. Then, the conductive capping layer, such as a titanium nitride (TiN) layer, is deposited on the ferroelectric gate dielectric layer 117. In some embodiments, the oxide semiconductor channel layer 116, the ferroelectric gate dielectric layer 117 and the conductive capping layer are deposited in the same process chamber without breaking vacuum between the deposition processes. In some embodiments, the conductive capping layer also serves as the thin conductive liner 118a of the gate conductor layer. In other embodiments, the conductive capping layer is a sacrificial capping layer that is removed after the annealing process. After deposition of the ferroelectric gate dielectric layer 117 and the conductive capping layer, the fabrication process then performs an anneal process to crystallize the ferroelectric gate dielectric layer 117. In one embodiment, a rapid thermal anneal (RTA) process is used where the annealing temperature is between 400 to 500° C. for a duration of 30 seconds to 15 minutes in a nitrogen (N₂) ambient. In one embodiment, with a 4 nm HZO layer as the ferroelectric gate dielectric layer and a 3 nm of TiN conductive capping layer, an RTA process with an annealing temperature of 475° C. for a duration of 8-10 minutes is used. In one embodiment, after the annealing process, the fabrication process deposits the conductive filler material 118b (e.g., W) of the gate conductor layer 118 on the conductive liner 118a (e.g., TiN). In another embodiment, after the annealing process, the fabrication process removes the sacrificial capping layer, such as by use of an etch process selective to the ferroelectric gate dielectric layer 117. The fabrication process then deposits the gate conductor layer 118 on the annealed ferroelectric gate dielectric layer 117. As described above, the gate conductor layer 118 can include a thin conductive liner 118a (e.g., TiN) and a conductive filler material 118b (e.g., W).

After the LWL structures are formed, the fabrication process 300 continues with forming slit trenches in the multi-layer film stack (FIG. 12, 310). Referring to FIG. 13(c), a cap oxide layer 142 is formed on the memory structure 10. The memory structure is then patterned by a masking layer (not shown) to define areas where slit trenches are to be formed to define the memory stacks. A selective anisotropic dry etch process is performed to etch through the multi-layer film stack (including the cap oxide layer 142) to form the slit trenches 119, dividing the memory structure into mesas corresponding to the memory stacks for forming the NOR strings of memory transistors. It is instructive to note that the slit trench etch process is made only through the multi-layer film stack and does not interact with any conductive or metal layers. For example, the slit trench etching process is performed between the staircase contacts at the staircase structures that may have been formed but does not intersect with the staircase contacts themselves. In one embodiment, the slit trench etch process is a high-aspect-ratio dry etch process.

With the slit trenches 119 thus formed to separate the memory stacks, the fabrication process 300 proceeds to perform metal replacement through the slit trenches to form the common drain line (bit line) and the common source line (source line) (FIG. 12, 312). Referring first to FIG. 13(f), the metal replacement process starts by removing the first and second sacrificial layers in each active layer. The first and second sacrificial layers 122 and 124 can be removed using, for example, a selective dry etch or a selective wet etch process, thereby creating cavities 133 between the channel spacer dielectric layer 113 and the inter-layer sacrificial layer 120. The first dielectric liner layer 131 functions as an etch stop for the removal of the first and second sacrificial layers 122 and 124. In this manner, the removal of the first and second sacrificial layers 122 and 124 stops on the first dielectric liner layer 131 and the channel layer 116 is protected during the etch process. Thereafter, the first dielectric liner layer 131 is removed through cavities 133 to expose the backside of the channel layer 116. In one example, the first and second sacrificial layers 122 and 124 are silicon nitride layers which are removed using a selective wet etch process using hot phosphoric acid. In one example, the first dielectric liner layer 131 is a silicon dioxide layer and may be removed using a wet etch process, such as using hydrofluoric acid (HF). It is instructive to note that in the case the etch stop layer 126 is also a silicon nitride layer, care should be taken to avoid etching or removing the silicon nitride etch stop layer 126. For example, processing steps can be incorporated to form a cap layer on the sidewalls of the silicon nitride etch stop layer 126 after the slit trench etch process. For example, the cap layer can be a silicon dioxide layer. In this manner, the removal of the first and second silicon nitride sacrificial layers will not remove the silicon nitride etch stop layer 126.

The remaining layers 113 and 120 are typically 30 nm or less in thickness and 30 nm to 60 nm long; they are held in place by being attached to the first dielectric liner layer 131, the channel layer 116, the ferroelectric layer 117 and the conductive liner 168. The layers 113 and 120 are supported by the rigid metallic vertical local word structures, which is repeated at a given pitch along the entire length of each metal stack in the Y-direction (as shown in FIG. 13(f) (i)). The feature of having strong mechanical support by metallic local word line structures spanning the entire depth of very tall and narrow memory stacks results in physical stability of the stacks, thereby enabling scaling up the height of the memory stacks even in case of very high aspect ratio memory structures.

Then, as shown in FIG. 13(g), a conductive layer 134 is deposited into the cavities 133 to replace the removed first and second sacrificial layers. For example, the conductive layer 134 can be deposited by using an atomic layer deposition technique or a chemical vapor deposition technique. Prior to the deposition process, the exposed backside of the channel layer 116 can be cleaned of any surface oxidation without damaging the channel layer. In the conductive layer deposition process, excess conductive materials are formed on the sidewalls (portions 135) of the slit trenches and on the top (portions 136) of the memory structure. The excess conductive materials are removed, such as by a dry etch process and CMP. In one example, the excess materials are removed by a selective dry etch process, and in some cases, followed by a selective wet etch process to remove remaining metal residues or stringers. FIG. 13(h) illustrates the resulting memory structure. More specifically, the metal replacement process forms conductive layers 112 and 114 in the cavities 133. In one embodiment, the conductive layers 112, 114 are each a titanium-nitride lined tungsten layer (TiN/W). As a result of the metal replacement process, first and second conductive layers 112, 114 are formed in each active layer in contact with the oxide semiconductor channel layer 116 and are spaced apart by the channel spacer dielectric layer 113. In each active layer 101, the first conductive layer 112 serves as the common drain layer (bit line) and the second conductive layer 114 serves as the common source line (source line) of the NOR memory string to be formed. In some embodiments, the first and second conductive layers 112, 114 are each a metal layer and may be a titanium nitride (TiN) lined tungsten (W) layer, a tungsten nitride (WN) lined tungsten (W) layer, a molybdenum layer or a cobalt layer, or other conductive materials described above.

After the metal replacement process, the fabrication process 300 proceeds to perform vertical channel separation through the slit trenches (FIG. 12, 314). Referring to FIG. 13(i), The inter-layer sacrificial layer 120 is removed, creating cavities 137. Various removal processes can be used depending on the material used for the inter-layer sacrificial layer 120. For example, in the case the inter-layer sacrificial layer 120 is a carbon layer, the carbon layer can be removed by ashing in an oxygen ambient. In the case the inter-layer sacrificial layer 120 is amorphous silicon or silicon germanium, a selective wet or dry etch process can be used. Then, the dielectric liner layer 131 is also removed through the cavities 137, such as by a wet etch process. As a result, portions of the oxide semiconductor channel layer 116 is exposed at the inter-layer region. The exposed portions of the oxide semiconductor channel layer 116 are removed, such as by a dry etch process or a wet etch process. In one example, the exposed portions of the oxide semiconductor channel layer 116 are removed using an atomic layer etch (ALE) process. FIG. 13(j) illustrates the resulting structure. The dotted circles 138 indicate areas where the channel layer 116 have been removed. By removing the channel layer 116 in the inter-layer region, the channel layer is isolated to each memory transistor formed in each active layer. In other words, the channel layer 116 is separated in the Z-direction to each active layer 101.

In some embodiments, the channel layer 116 is an oxide semiconductor material, such as IGZO, and the fabrication process uses, for example, sulfuric acid, citric acid, acetic acid, hydrochloric acid, or ammonium hydroxide (NH₄OH) in a wet etch process to selectively etch the exposed portions of the channel layer 166. In some embodiments, the memory structure 100 includes the interfacial layer 125 and the backside etch of the channel layer 116 is selective to the interfacial layer 125 so that the interfacial layer acts as an etch stop for the backside etch process. That is, the exposed portion of the channel layer 116 is etched through the slit trenches 119 and cavities 137 and the etch process will stop when the interfacial layer 125 is reached. In one embodiment, the interfacial layer 125 is an aluminum oxide (Al₂O₃) layer. In another embodiment, the backside etch process may be implemented as a multi-step etch process, including an atomic layer etch step used in the removal of the last 1-2 nm of the channel layer, in which the atomic layer etch step stops on the interfacial layer 125 or stop on the ferroelectric gate dielectric layer 117. In some embodiments, the interfacial layer 125 may be partially or fully removed during the etch process. In the inter-layer isolation region, the presence or absence of the interfacial layer 125 does not impact the performance of the memory transistor.

In alternate embodiments, the exposed portions of the channel layer 116 between two adjacent active layers 101 in the memory stack (in the Z-direction) can be partially removed, leaving a thin portion that does not function effectively as a parasitic channel conductor.

In the embodiment shown in FIG. 13(j), the channel separation process stops when the exposed portions of the channel layer 66 are removed and the channel region is physically separated (wholly or partially) and isolated to each active layer 101 in each memory stack. In alternate embodiments, the channel separation process can continue, by a change of etchant chemistry or process, to remove the now exposed portions of the ferroelectric gate dielectric layer 117. FIG. 13 (j1) illustrates the resulting memory structure after the removal of the exposed portions of the ferroelectric gate dielectric layer 117 through the cavities 137. The separation of the ferroelectric gate dielectric layer 117 is optional and may be omitted in other embodiments of the present invention. The dotted circles 139 indicate areas where the ferroelectric gate dielectric layer 117 and the interfacial layer 125 (if any) have been removed. Removing the ferroelectric gate dielectric layer 117 in the inter-layer region has the benefits of preventing sideway migration of the polarization areas or sideway migration of oxygen atoms between memory transistors in vertically adjacent planes.

The fabrication process 300 continues with passivating or isolating the memory structure thus formed (FIG. 12, 316). Referring to FIG. 13(k), in the present embodiment, the cavities 137 in the inter-layer region are filled with a dielectric layer to form an inter-layer isolation layer 115 between each pair of active layers 101. In some embodiments, the inter-layer isolation layer 115 is an oxygen-containing dielectric layer. In one embodiment, the inter-layer isolation layer 115 is a silicon dioxide layer. In some embodiment, the inter-layer isolation layer 115 is deposited using an atomic layer deposition technique. The deposition of the dielectric layer in the inter-layer cavities will also result in dielectric material 154 being deposited onto the sidewalls of the slit trenches 119. After the deposition of the inter-layer isolation layer 115, excess material may be removed from the top of memory structure using, for example, chemical-mechanical polishing (CMP). In some example, the CMP process removes the cap oxide layer 142 and stops on the etch stop layer 126 as the CMP stop layer. Accordingly, the memory stacks are passivated or isolated by the deposition of the inter-layer isolation layer 115.

Subsequently, as shown in FIG. 13(l), the fabrication process may continue with filling the slit trenches with a dielectric layer 151. In this case, the memory structure 100 is completely filled with a dielectric layer, such as a silicon dioxide layer. After deposition of the dielectric layer 151 into the slit trenches and subsequent CMP process to remove excess materials from the top of the memory structure, a cap oxide layer 152 is deposited on the memory structure to complete the isolation of the memory structure 100.

In other embodiments, the fabrication process may form air gap isolation in the slit trenches 119. Referring to FIG. 13 (m), after depositing the inter-layer isolation layer 115, including the sidewall portion 154 deposited on the sidewalls of the slit trenches 119. A non-conformal deposition process can be carried out to deposit a dielectric layer, such as a silicon dioxide layer, onto the memory structure. The non-conformal deposition will form a dielectric layer 155 which seals the top of each slit trench 119, leaving remaining cavity of the trench unfilled to use as an air gap isolation 153. Subsequent CMP process removes excess deposited materials from the top of the memory structure and a cap oxide layer 152 is deposited on the memory structure 100b. In embodiments of the present invention, the memory structure can be formed with dielectric filled trenches 151 (FIG. 3(l)) or with air gap isolation 152 (FIG. 3 (m)) for isolation between the memory stacks. In the following description, the memory structure 100b, including the air gap isolation between the memory stacks, is used to describe the remaining process steps.

After the vertical channel separation process, the fabrication process 300 may proceed to form the contacts for the staircase structures to the common drain layers (bit lines) (FIG. 12, 317). In the present description, the staircase contacts to the common drain layers is referred to as “CB contacts”. In particular, the fabrication process 300 may form contact openings in the staircase structures, such as by means of a dry etch process. The contact openings are made through the encapsulating oxide layer to each step of the staircase structure to make contact with the first conductive layer 112 in each active layer 101. The contact openings are then filled with a conductive layer. In some embodiment, the conductive layer is a titanium-nitride lined tungsten layer (TiN/W). The CB and CC staircase contact structure is shown in FIG. 6 above.

The fabrication process 300 then continues to form the global word lines (GWL) to make contact with the local word line structures in the memory structure (FIG. 12, 318). Various methods for forming the global word lines can be used. In the present embodiment, the global word lines are formed on the top of the memory structure 100b. In the example shown in FIG. 13(n), a via 156 is formed in the cap oxide layer 152 to contact the gate conductor layer in each LWL structure. Then a conductive layer 158 is provided on the cap oxide layer, contacting respective vias 156, to form the global word lines. The global word lines 158 extend in the X-direction and is electrically connected to one local word line structure in each memory stack. In one embodiment, the vias 156 are formed of tungsten and the global word lines 158 are formed of copper. In other embodiments, the global word lines can be formed using a damascene process, or using a single patterning process or a double patterning process, as will be described in more detail below. In some embodiments, the memory structure can be formed including some global word lines formed in the bottom of the memory structure (such as in the substrate) and some global word lines formed above the memory structure, as will be described in more detail below.

In the present embodiment, the fabrication process 300 may form the staircase contact connections at the same time as the global word lines (FIG. 320). That is, the masking step for forming the global word lines can also define regions where the connectors for each connection of the staircase contacts CC to staircase contacts CB are to be made. The conductive layer for the global word lines can also be deposited at the same time to connect the respective contact openings CC to CB. The staircase contact connection structure is shown in FIG. 6 above.

Using the fabrication process described above, a memory structure including a three-dimensional array of NOR memory strings of channel-all-around ferroelectric memory transistors is formed. In the above description, the fabrication process flow is described with respect to forming the staircase structure to connect to the common drain layer only. It is understood that the fabrication process can be adapted to form the staircase structure to connect to the common drain layer and the common source layer, as described in FIGS. 10 and 11.

In embodiments of the present invention, the memory structure includes ferroelectric memory transistor that are formed using an oxide semiconductor layer as the channel layer. In the above described embodiments, the oxide semiconductor channel layer is formed using a single oxide semiconductor material, deposited in the hole openings forming the pillar-shaped local word line structure. In some embodiments, the oxide semiconductor channel layer is formed as a bi-layer channel including a first oxide semiconductor layer formed on the sidewalls of the local word line pillars and a second oxide semiconductor layer formed between the first oxide semiconductor layer and the conductive layers forming the drain and source lines. The second oxide semiconductor layer is in electrical contact with the first oxide semiconductor layer to function as a bi-layer channel region for the ferroelectric memory transistor. Meanwhile, the second oxide semiconductor layer is in electrical contact with the conductive layers forming the drain and source lines to function as a low contact resistance contact layer between the drain and source conductive layers to the first oxide semiconductor layer. Meanwhile, the first oxide semiconductor layer functions as the main channel layer providing the desired high mobility and high on-current for the channel region of the ferroelectric memory transistors.

In some embodiments, the second oxide semiconductor is a metal oxide semiconductor material that provides a contact resistance to the bit line/source line (or source/drain) conductive layers that is lower than the contact resistance provided by the first oxide semiconductor layer. In one embodiment, the first oxide semiconductor layer is an IGZO layer of thickness around 6 nm and the second oxide semiconductor layer is, for example, an indium aluminum zinc oxide (InAlZnO or IAZO) layer or an indium oxide (InO) layer or an indium tin oxide (ITO) of thickness less than 3 nm. In some embodiments, the thickness of the second oxide semiconductor layer is around 1 nm to 2 nm. In other embodiments, other oxide semiconductor materials that provide a desirably low contact resistance to bit line/source line conductive layers can be used as the second oxide semiconductor layer. In some embodiments, a metal oxide semiconductor material that has high immunity to deoxidization of the channel layer by the source/drain conductive layer and suppresses oxidation of the source/drain conductive layers during thermal processing is desired for use as the second oxide semiconductor layer.

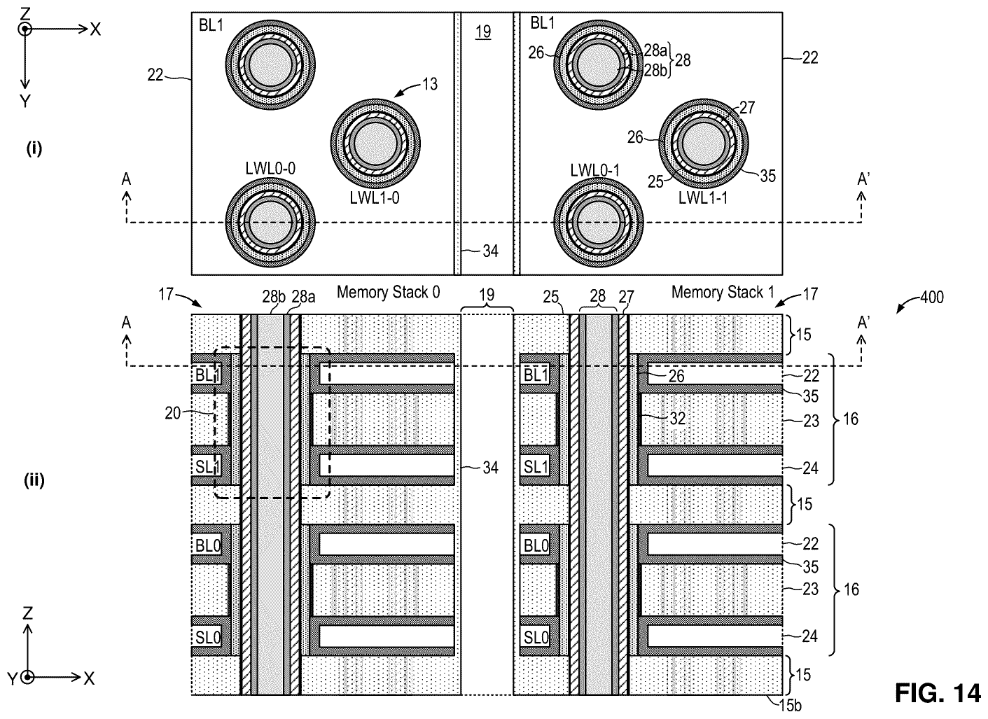

FIG. 14 includes cross-sectional views of a memory structure of channel-all-around ferroelectric memory transistors in alternate embodiments of the present invention. The memory structure in FIG. 14 is substantially similar to that of FIG. 3(b) except for the inclusion of the second oxide semiconductor layer as a contact layer for the source/drain conductive layers. Like elements in FIGS. 3(b) and 14 are given like reference numerals and will be not described in detail. Referring to FIG. 14, a memory structure 400 includes channel-all-around ferroelectric memory transistors 20 formed at the intersection between the bit line conductive layer 22, the source line conductive layer 24 and the pillar-shaped local word line structure 13. In the present embodiment, a second oxide semiconductor layer 35 is formed between the oxide semiconductor channel layer 26 and the bit line conductive layer 22 and the source line conductive layer 24. In particular, the second oxide semiconductor layer 35 is in contact with the oxide semiconductor channel layer 26 on one side and in contact with the bit line conductive layer 22 and the source line conductive layer 24 on the other side. As thus configured, the second oxide semiconductor layer 35 functions as a contact layer between the oxide semiconductor layer 26 and the bit line conductive layer 22 and the source line conductive layer 24. The second oxide semiconductor layer 35 is formed from an oxide semiconductor material that provides a lower contact resistance to conductive layers 22, 24 than the oxide semiconductor channel layer 26.

In embodiments of the present invention, the second oxide semiconductor layer 35 can be formed during the metal replacement process, such as step 312 in the fabrication process 300 (FIG. 12). More specifically, with the first and second sacrificial layers removed and the dielectric liner layer also removed, the second oxide semiconductor layer 35 is deposited on the memory structure into the cavities exposed by the removed first and second sacrificial layers. In particular, the second oxide semiconductor layer 35 is conformally deposited over all exposed surfaces of the memory structure 400. Prior to the deposition process, the exposed backside of the channel layer 26 can be cleaned of any surface oxidation without damaging the channel layer. In some embodiments, the second oxide semiconductor layer 35 is deposited using an atomic layer deposition (ALD) process. In some embodiments, the second oxide semiconductor layer 35 is formed using an oxide semiconductor material different from the first oxide semiconductor layer 26. In some embodiments, the second oxide semiconductor layer 35 is an amorphous oxide semiconductor material, such as indium aluminum zinc oxide (InAlZnO or IAZO), or indium oxide (InO), indium zinc oxide (IZO), or indium tin oxide (ITO), or other suitable oxide semiconductor materials. In other embodiments, the first oxide semiconductor layer 26 and the second oxide semiconductor layer 35 are both indium gallium zinc oxide (IGZO) layers but with different element ratios. That is, the first oxide semiconductor layer 26 is an indium gallium zinc oxide (IGZO) layer having a first element ratio of indium, gallium and zinc, and the second oxide semiconductor layer 35 is an indium gallium zinc oxide (IGZO) layer having a second element ratio of indium, gallium and zinc, where the first element ratio is different from the second element ratio. In some embodiments, the thickness of the second oxide semiconductor layer 35 is less than 3 nm, such as around 1 nm to 2 nm.

After the second oxide semiconductor layer 35 is deposited, a conductive layer is deposited on the memory structure 400 to form the bit line conductive layer 22 and the source line conductive layer 24. In some embodiments, the conductive layer is deposited using chemical vapor deposition or atomic layer deposition. Subsequent to the conductive layer deposition, the excess material formed on the sidewalls of the slit trench 19 and on the top surface of the memory structure is removed by a dry selective etch, and in some cases, followed by a selective wet etch process to remove remaining metal residues or stringers. Meanwhile, the excess material of the second oxide semiconductor layer 35 formed on the sidewall of the slit trenches 19 is also removed, either in the same process as the conductive material removal or in a separate removal process. Subsequent channel separation process, passivation process, and global word line formation can be carried out in the manner described above with reference to the fabrication process 300 of FIG. 12. The resulting structure is shown in FIG. 14. As thus formed, the bit line/source line conductive layers and the second oxide semiconductor layer are each separated and isolated to each individual layers. In particular, in the present embodiment, by virtue of being formed using an ALD process, each bit line/source line conductive layer is partially enveloped by a respective isolated or separated portion of the second oxide semiconductor layer.

In the memory structure 400, the bit line conductive layer 22 and the source line conductive layer 24 are formed and are spaced apart by the channel spacer dielectric layer 23. Each separated portion of the second oxide semiconductor layer 35 is in electric contact with the respective bit line or source line conductive layer 22, 24 but are isolated from other portions of the second oxide semiconductor layer. Each separated portion of the second oxide semiconductor layer 35 is in physical and electrical contact with a corresponding portion of the first oxide semiconductor layer 26 to from a bi-layer channel of the ferroelectric memory transistor. In each active layer 16, the bit line conductive layer 22 forms the common drain line and the source line conductive layer 24 forms the common source line of the NOR memory string to be formed. In some embodiments, the bit line and source line conductive layers 22, 24 are each a metal layer and may be a titanium nitride (TiN) liner and a tungsten (W) layer, a tungsten nitride (WN) liner and a tungsten (W) layer, a molybdenum layer or a cobalt layer, or other conductive materials described above.

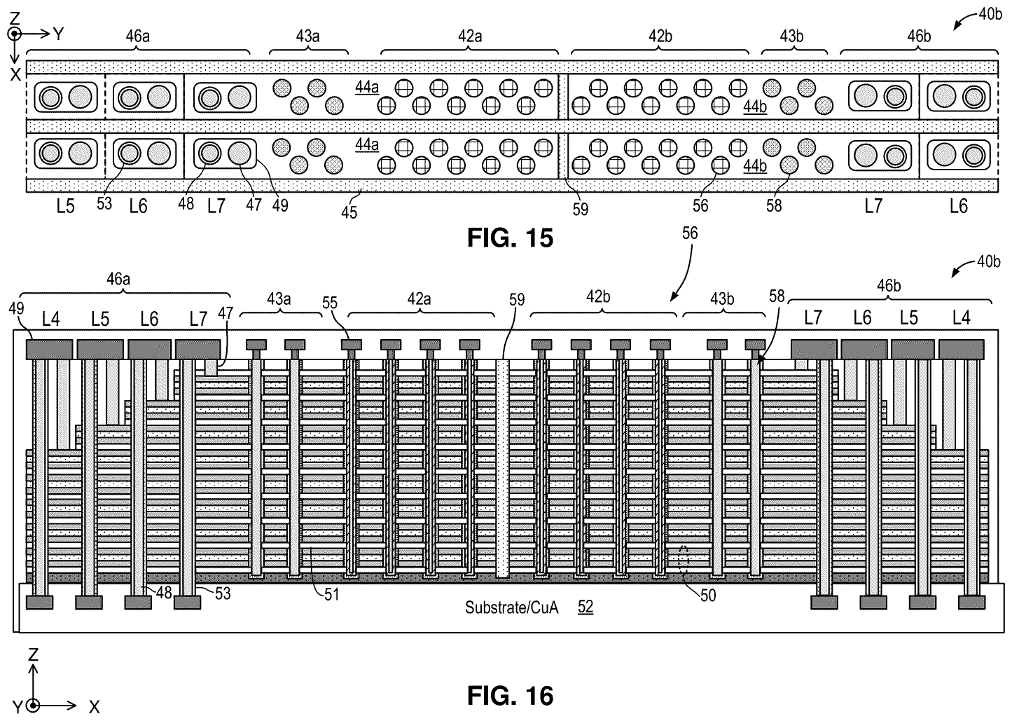

In the embodiments described above with reference to FIGS. 5 and 6, the memory structure is formed with the memory stack running the entire distance between the staircase portions 46a and 46b. In alternate embodiments, each memory stack can be divided into half to make shorter common drain lines and common source lines. FIG. 15 is a top view of a memory structure including staircase structures connecting to common bit lines and common source lines in alternate embodiments of the present invention. FIG. 16 is a cross-sectional view of the memory structure of FIG. 15 including staircase structures connecting to common bit lines and common source lines in embodiments of the present invention. Referring to FIGS. 15 and 16, a memory structure 40b includes a three dimensional array of NOR memory strings of channel-all-around ferroelectric memory transistors formed in multi-layer memory stacks. The memory structure 40b includes multiple memory stacks arranged in the X-direction and separated from each other by slit trenches 45. Each memory stack includes multiple active layers 50 separated by inter-layer isolation layer 51. Each active layer 50 includes a first conductive layer as the common drain line or bit line, a second conductive layer as the common source line or source line, and a channel spacer dielectric layer in between. In the present embodiment, the memory stacks are divided into a first memory stack portion 44a and a second memory stack portion 44b. The first and second memory stack portions 44a, 44b are separated by a slit trench 59. Accordingly, a common drain line in the first memory portion 44a is separated and isolated from the common drain line in the second memory portion 44b. As thus configured, each memory stack portion 44a or 44b includes a memory array portion 42a or 42b including pillar-shaped local word line structures 56 for forming channel-all-around ferroelectric memory transistors at each intersection with an active layer 50. Each memory stack portion 44a or 44b further includes a precharge array portion 43a or 43b including pillar-shaped precharge local word line structures 58 for forming channel-all-around non-memory transistors at each intersection with an active layer 50.

Separating the memory stacks into the first and second portions has the advantage of shortening the common drain line and the common source line for the memory strings in each active layer, thereby reducing the resistance and capacitance of the common drain line (the bit line of the memory transistors). As a result, the RC delay of the bit line is reduced which improves the access time for the memory transistors. In memory structure 40b, the memory strings in the first memory array portion 42a are accessed by the staircase structure 46a whereas the memory strings in the second memory array portion 42b are accessed by the staircase structure 46b. Each staircase structure 46a, 46b provides access to the common drain line of each active layer.

In embodiments of the present invention, the pillar-shaped local word line structures in the memory array are connected to global word lines for receiving bias voltages from circuitry in the CuA for performing memory operations. Several techniques can be used to provide the global word line in the memory structure of the present invention.

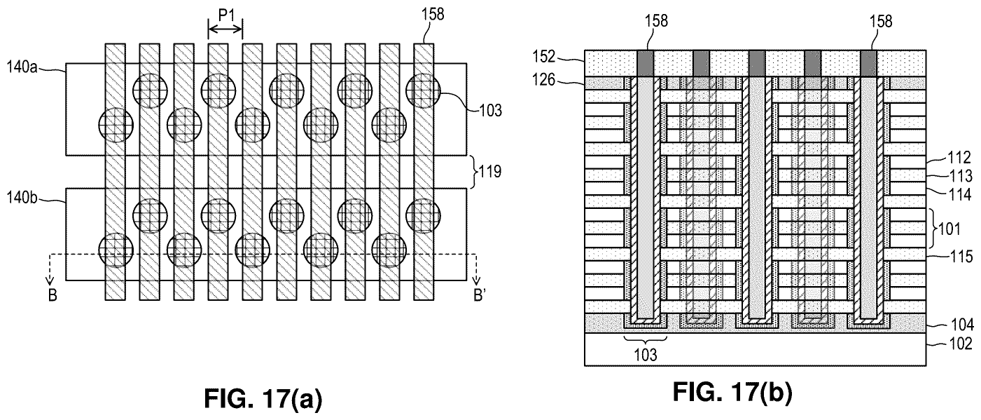

In the above described embodiments, the global word lines are provided on top of the memory structure after the fabrication process for forming the memory stacks of active layers and the local word line structures. In a first embodiment, the global word lines are formed in a single layer on the top of the memory structure. In one embodiment, when the pitch of the local word line structures are small or approaching the limits of photolithography, such as around 55 nm, the single-layer global word lines can be formed using a self-aligned double patterning technique. FIGS. 17(a) and 17(b) are top view and cross-sectional view, respectively, of a memory structure including a single layer of global word lines in some embodiments. Referring first to FIG. 17(a), a memory structure is shown with memory stacks 140a and 140b, separated by the slit trench 119. Each memory stack 140a, 140b includes a NOR string arranged in two staggered rows of local word line structures 103. The global word lines 158 are arranged traverse to the memory stacks 140a, 140b so that each global word line 158 contacts one local word line structure 103 in each memory stack. The global word lines 158, when formed in a single layer, has a pitch of P1, being the pitch of the local word line structures. In the case the pitch P1 is small, such as at the photolithography limit, a double patterning technique can be used to form the global word lines 158.

FIG. 17(b) illustrates the cross-sectional view of the memory stack along the line B-B′. Referring to FIG. 17(b), after the active layers 101 are formed, double patterning layers can be deposited and patterned to form mandrels which are then used to pattern an oxide layer 152, with openings for receiving a conductive layer in a damascene process. For example, the conductive layer is a copper layer in some embodiments. In this manner, the single-layer global word lines 158 are formed making contact to respective local word line structures 103 in the memory stacks.

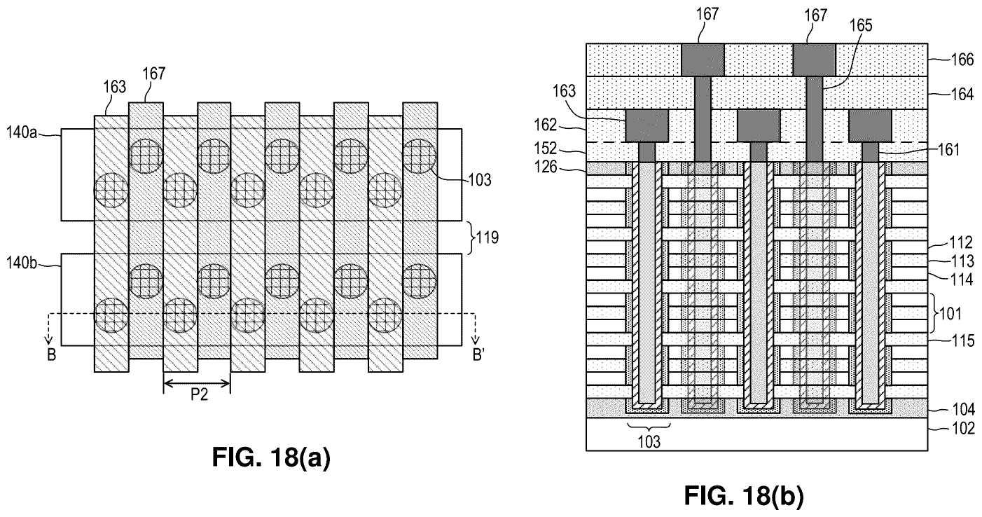

In a second embodiment, the global word lines are formed as two conductive layers on the top of the memory structure. FIGS. 18(a) and 18(b) are top view and cross-sectional view, respectively, of a memory structure including a double layer of global word lines in some embodiments. Referring first to FIG. 18(a), a memory structure is shown with memory stacks 140a and 140b, separated by the slit trench 119. Each memory stack 140a, 140b includes a NOR string arranged in two staggered rows of local word line structures 103. Lower-layer global word lines 163 are arranged traverse to the memory stacks 140a, 140b and contact alternate local word line structures 103 in each memory stack. Upper-layer global word lines 167 are arranged traverse to the memory stacks 140a, 140b and contact the other local word line structure 103 in each memory stack. In the two-layer global word line arrangement, the pitch P2 of the global word lines can be made larger than the pitch P1 of the global word lines in a single layer.

FIG. 18(b) illustrates the cross-sectional view of the memory stack along the line B-B′. Referring to FIG. 18(b), after the active layers 101 are formed, a dielectric layer 152 is formed on the top of the memory structure and shallow vias 161 are formed in the dielectric layer 152 to contact a first set of local word line structures 103. Then, additional patterning layer is formed on top of the memory structure to form the lower-layer global word lines 163. In one embodiment, the lower-layer global word lines 163 is formed by a damascene process. In another embodiment, the lower-layer global word lines 163 is formed with a dielectric spacer (not shown) before the filler dielectric layer 162 is formed. Then, an interlayer dielectric layer 164 is formed on the lower-layer global word lines 163. Vias 165 are then formed in the interlayer dielectric layer 164 to connect to a second set of local word line structures 103. Then, additional patterning layer is formed on top of the memory structure to form the upper-layer global word lines 167. In one embodiment, the upper-layer global word lines 167 is formed by a damascene process. In some embodiments, the shallow vias 161 and the vias 165 are both tungsten filled vias. The lower-layer global word lines 163 and the upper-layer global word lines 167 are conductive layers, such as copper. As thus configured, the lower-layer global word lines 163 contact the first set of local word line structures and the upper-layer global word lines 167 contact the second set of local word lines structures. The pitch of the lower and upper global word lines can be made larger to simplify the fabrication process and to improve the electrical characteristics of the electrical connection.

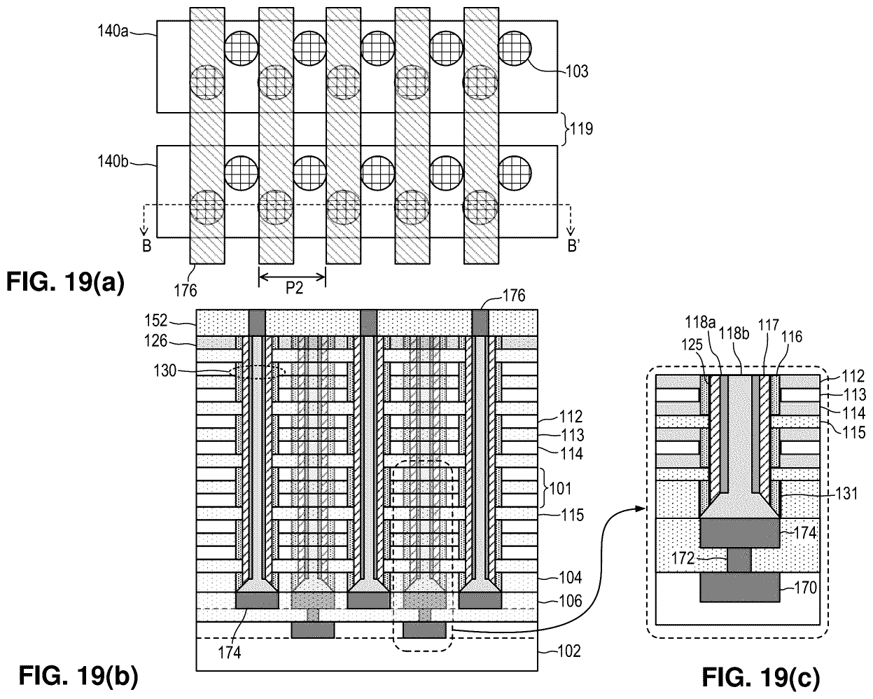

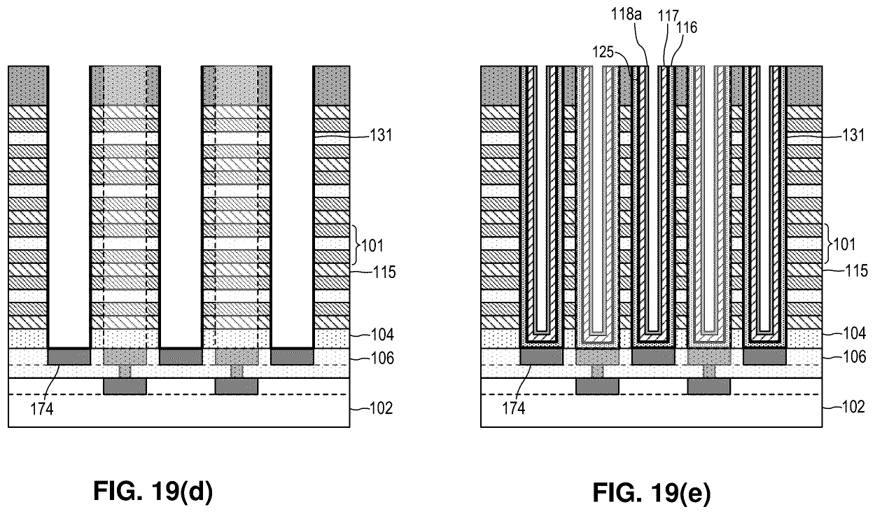

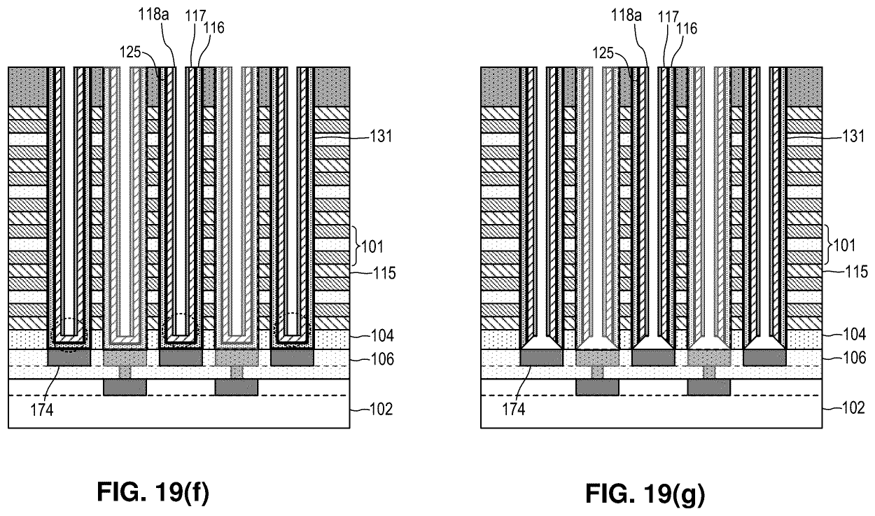

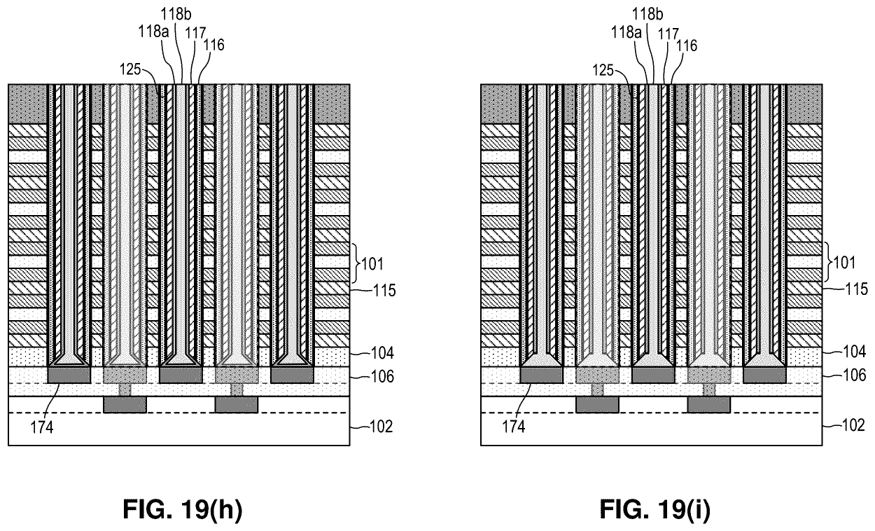

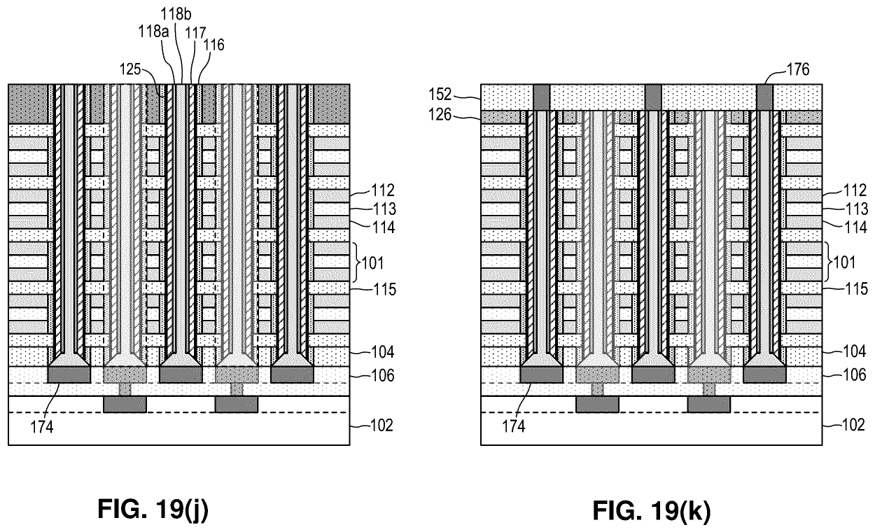

In a third embodiment, the global word lines are formed as top and bottom conductive layers-one layer under the memory array and the other layer above the memory array. FIGS. 19(a), 19(b) and 19(c) are top view, cross-sectional view and expanded cross-sectional view, respectively, of a memory structure including a top-bottom layer of global word lines in some embodiments. FIGS. 19(d)-19(k) are cross-sectional views of the memory structure of FIGS. 19(a)-19(c) illustrating the fabrication process for forming the top-bottom layer of global word lines in some embodiments. Referring first to FIG. 19(a), a memory structure is shown with memory stacks 140a and 140b, separated by the slit trench 119. Each memory stack 140a, 140b includes a NOR string arranged in two staggered rows of local word line structures 103. From the top view in FIG. 19(a), the top global word lines 176 are arranged traverse to the memory stacks 140a, 140b and contact alternate local word line structures 103 in each memory stack. The other local word line structures 103 are being contacted by bottom global word lines formed in the substrate. In this case, the pitch P2 of the global word lines can be made larger than the pitch P1 of the global word lines in a single layer.

FIG. 19(b) illustrates the cross-sectional view of the memory stack along the line B-B′. FIG. 19(c) illustrates the detailed view of a bottom global word line in some embodiments. Referring to FIGS. 19(b) and 19(c), the substrate 102 is initially provided with the bottom global word lines 170. That is, in fabricating the circuitry of the CuA in the substrate 102, the bottom global word lines 170 are formed with the desired routing of the global word line connection. Subsequently, such as at the start of the fabrication of the memory array on the substrate 102, one or more dielectric layers are formed on the substrate 102 and on the bottom global word lines 170. Vias 172 are formed to connect to the bottom global word lines 170. Then, conductive landing pads 174 are formed which are positioned corresponding to the local word line structures to be formed and also in alignment with the vias 172. In the present embodiment, the conductive landing pads 174 are provided for all the local word line structure, even though only a subset of the local word line structures are to be connected to the bottom global word lines. Accordingly, a subset of the conductive landing pads are positioned in alignment with the vias 172 for connection to the bottom global word lines 170. The conductive landing pads 174 having no connection to any bottom global word lines are dummy landing pads. However, the landing pads 174 are useful in serving as an etch stop layer for the local word line holes etch process.

The memory array is then fabricated in the manner described above. During the fabrication process of the local word line structures, openings in the multi-layer film stacks are made to the landing pads 174, which serves as the etch stop layer, as shown in FIG. 19(d). The memory transistor device layers are then deposited. In some embodiments, a dielectric liner layer (not shown in the present figure) is first deposited in the hole openings. The channel layer 116 and the ferroelectric gate dielectric layer 117 are then deposited in the hole openings, as shown in FIG. 19(c). In some embodiments, after the deposition of the channel layer 116 and the ferroelectric gate dielectric layer 117 (with or without the optional interfacial layer 125), a conductive capping layer is deposited on the ferroelectric gate dielectric layer 117, as shown in FIG. 19(e), and annealing of the ferroelectric gate dielectric layer 117 is performed. In some embodiments, the annealing process is a rapid thermal anneal process using an annealing temperature between 400 to 500° C. for a duration of 30 seconds to 15 minutes in a nitrogen (N₂) ambient. After the annealing, a punch-through etch process is performed to etch through the conductive capping layer at the bottom of the LWL holes, as shown by the dotted circles in FIG. 19(f). Then the local word line device layers, including the ferroelectric dielectric layer, the interfacial layer (if any), the oxide semiconductor channel layer and the dielectric liner layer, are removed from the bottom of the local word line holes, such as by an isotropic etching process, as shown in FIG. 19(g). In some embodiments, the conductive capping layer remains on the annealed ferroelectric gate dielectric layer 117 to act as a protective layer for the ferroelectric dielectric layer during the etch process. All of the local word line structures are processed the same way to form openings to the conductive landing pads 174. After the openings to the conductive landing pads 174 are formed, the conductive capping layer can be removed, such as by use of an etch process selective to the ferroelectric gate dielectric layer 117. Then, the gate conductor layer 118, including a gate conductor liner layer 118a and a gate conductor filler layer 118b, is deposited into the local word line structures, as shown in FIG. 19(h). The gate conductor layer 118 reaches all the way to the conductive landing pads 174. In other embodiments, the conductive capping layer can remain and serves as the gate conductor liner layer and the gate conductor layer 118 may includes only a conductive filler layer, as shown in FIG. 19(i). For example, the conductive capping layer maybe a titanium nitride layer (TiN) and may have a thickness of 2-3 nm and the gate conductor layer 118 may include a tungsten layer filling the remaining volume. In the case the conductive landing pads 174 are connected to the via 172, the local word line structures are thus connected to the bottom global word lines 170. Otherwise, the local word line structures are connected to dummy conductive landing pads.

The fabrication process of the memory structure continues with the slit opening, metal replacement and channel replacement processes described above. The resulting structure is shown in FIG. 19(j). After the active layers of the memory structure are formed, the top global word lines 176 are then formed on top of the memory structure to connect to the subset of local word line structures not connected to the bottom global word lines, as shown in FIG. 19(k). For example, an oxide layer 152 is patterned with openings for receiving a conductive layer in a damascene process. For example, the conductive layer is a copper layer in some embodiments. In this manner, the top global word lines 176 are formed making contact to the subset of local word line structures 103 in the memory stacks. In this manner, a first set of alternate local word line structures is being connected to the top global word lines 176 while a second set of alternate local word line structures is being connected to the bottom global word lines 170. The pitch of the top and bottom global word lines can be made larger to simplify the fabrication process and to improve the electrical characteristics of the electrical connection.

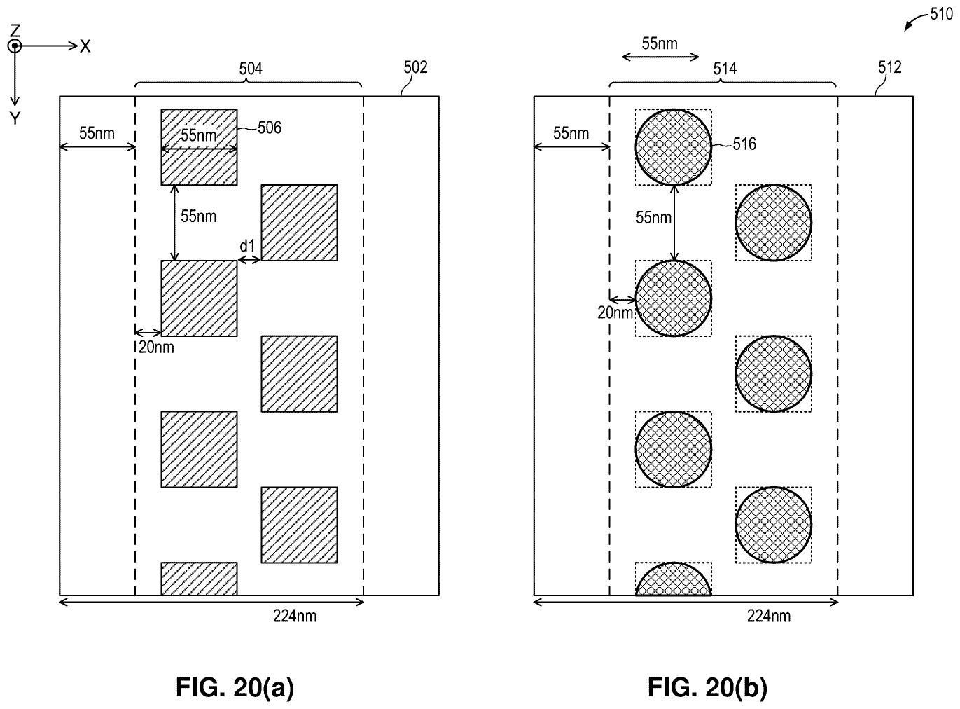

In embodiments of the present invention, the memory device is fabricated by forming closely spaced pillars in a multi-layer film stack, as described above with reference to FIG. 13(a). For example, a masking layer, such as an amorphous hard mask layer, is patterned using a photolithography technique and mask open process to define hole openings in the hard mask layer, where the hole openings correspond to the LWL holes to be formed in the memory structure. In some embodiments, a single exposure photolithography technique may be used to define the hole openings in the masking layer. FIGS. 20(a) and 20(b) illustrate the patterning of pillar hole openings in a hard mask layer using a single-mask, single-exposure photolithography technique in some embodiments. In particular, FIG. 20(a) illustrates a mask with a mask pattern that can be used to define hole openings in a masking layer using a single-mask, single-exposure photolithography technique in some embodiments. FIG. 20(b) illustrates the resulting hole openings formed on a masking layer using the mask in FIG. 20(a) in some embodiments. Referring first to FIG. 20(a), a mask 502 has hole opening pattern 506 defined thereon for patterning hole openings in a patterning layer, such as a photoresist layer. The hole opening pattern 506 are arranged in two staggered columns and the hole opening pattern 506 has a dimension of 55 nm and a spacing of 55 nm in the Y-direction. The hole opening pattern 506 are formed in a region 504 corresponding to areas of the memory structure where memory stacks are to be formed.

FIG. 20(b) illustrates a masking layer 512, such as an amorphous hard mask layer, formed on a memory structure 510 during an intermediate processing step. The masking layer 512 is to be patterned using the mask 502 to form hole openings corresponding to the hole opening pattern 506. Referring to both FIGS. 20(a) and 20(b), during the fabrication process, after the multi-layer film stack of the memory structure 510 is formed (such as the multi-layer film stack shown in FIG. 13(a)), a first masking layer 512, such as an amorphous hard mask layer, is formed on the multi-layer film stack. Additional masking layers may be formed on the first masking layer 512, such as an anti-reflective coating (e.g. SiON), an additional carbon-containing masking layer (e.g. SOC or spin-on carbon), and/or an additional silicon-containing masking layer (e.g. SOG or spin-on-glass). Finally, a patterning layer, such as a photoresist layer, is formed on the masking layers. The mask 502 is used in a photolithography process to print the mask pattern 506 onto the photoresist layer, such as by a light exposure of the photoresist layer using the mask 502 and development of the photoresist layer after exposure. In one example, an immersion lithography technique can be used. The developed or patterned photoresist layer is then used to transfer the mask pattern to the one or more masking layers, until the mask pattern 506 is transferred to the first masking layer 512 (the hard mask layer). The process is sometimes referred to as the mask open process.

As a result of the mask open process, hole openings 516 are formed in the first masking layer 512. It is instructive to note that while the hole opening pattern 506 as drawn on the mask 502 is a square, the pattern that is printed onto the patterning layer using the photolithography process will be a circle. Accordingly, the mask pattern being transferred to the masking layers, down to the first masking layer 512, will be circular hole openings 516 corresponding to the square hole opening pattern 506 in mask 502. Using the photolithography process and the mask open process, the first masking layer 512 is patterned with circular hole openings 516. The patterned hard mask layer 512 can then be used in a high-aspect-ratio etch process to form the LWL holes in the multi-layer film stack, in the manner as described above with reference to FIG. 13(b).

In the example shown in FIG. 20(a), the hole openings have a dimension of 55 nm and a spacing of 55 nm in the Y-direction. The memory stack and the slit trench to be formed have a pitch of 224 nm in the X-direction. The positioning of the hole openings can present a challenge to the photolithography process because the spacing “d1” between adjacent staggered hole opening pattern can be as small as 17 nm. The small spacing can make it difficult for the hole pattern to be printed correctly by common photolithography techniques.

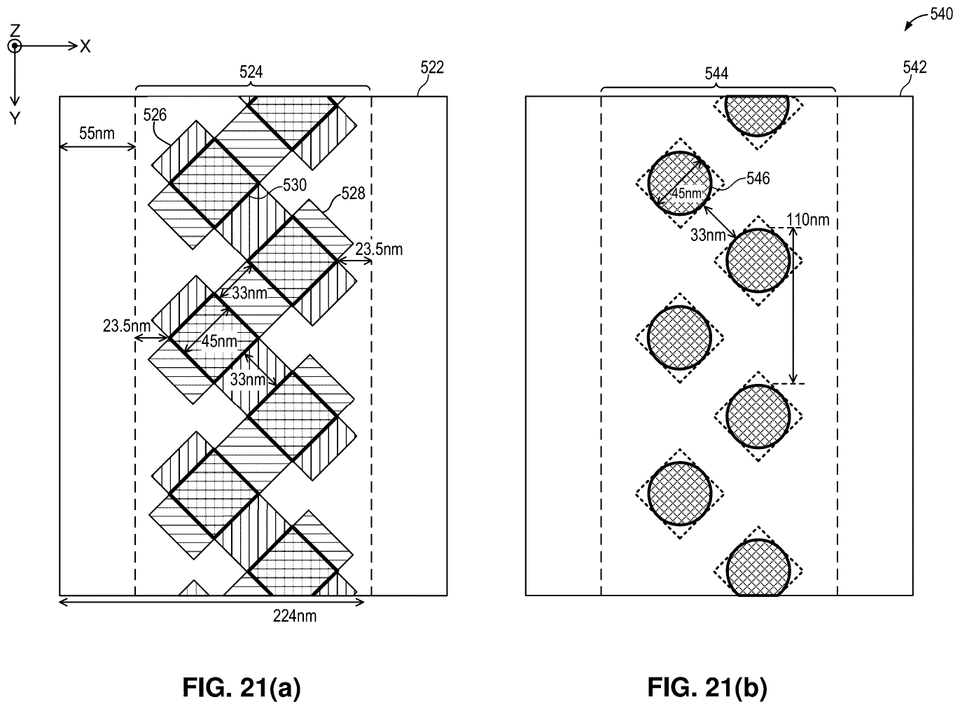

In other embodiments of the present invention, a multi-patterning photolithography technique is used to define the hole openings in the memory structure. Multi-patterning photolithography technique enables higher density patterns to be formed (e.g. 35 nm pitch or below) with less process complexity. FIGS. 21(a) and 21(b) illustrate the patterning of pillar hole openings in a hard mask layer using a two-mask, two-exposure photolithography technique in some embodiments. In particular, FIG. 21(a) illustrates two masks with mask patterns that can be used to define hole openings in a masking layer using a two-mask, two-exposure photolithography technique in some embodiments. FIG. 21(b) illustrates the resulting hole openings formed on a masking layer using the mask in FIG. 21(a) in some embodiments. In one embodiment, the multi-patterning photolithography technique referred to as litho-freeze-litho-etch (LFLE) is used. Referring first to FIG. 21(a), a first mask 522 has line-space pattern 526 defined thereon and a second mask 523 has line-space pattern 528 defined thereon. The two masks are shown overlapped in FIG. 21(a). The line-space patterns of the first and second masks are oriented at respective 45° angle relative to a central axis along the Y-direction (“Y-axis”). More specifically, the first mask 522 includes a line-space pattern 526 that is oriented at 45° in the counter-clockwise direction relative to the Y-axis; and the second mask 523 includes a line-space pattern 528 that is oriented at 45° in the clockwise direction relative to the Y-axis (or 135° in the counter-clockwise direction relative to the Y-axis). The line-space patterns 526, 528 of masks 522 and 523 are therefore at a right angle or 90° orientation to each other where the line-space patterns of masks 522 and 523 intersect to define the desired hole openings 530.

With the use of the multi-patterning photolithography technique, tight spacings between hole patterns can be avoided. In the example shown in FIG. 21(a), the line-space pattern can have a line width of 45 nm and a spacing of 33 nm. Hole openings of 45 nm dimensions can be formed without concern for tight spacings between the hole patterns. In some embodiments, the multi-patterning photolithography technique can be applied to pattern the conductive landing pads in the semiconductor layer under the memory array for forming bottom global word lines. In the following description, the multi-patterning photolithography technique is described with reference to forming pillar holes in the multi-layer film stack for forming the LWL holes.

FIG. 21(b) illustrates a masking layer 542, such as an amorphous hard mask layer, formed on a memory structure 540 during an intermediate processing step. The masking layer 542 is to be patterned using the masks 522, 523 to form hole openings corresponding to the line-space patterns 526, 528. Referring to both FIGS. 21(a) and 21(b), during the fabrication process, after the multi-layer film stack of the memory structure 540 is formed (such as the multi-layer film stack shown in FIG. 13(a)), a first masking layer 542, such as an amorphous hard mask layer, is formed on the multi-layer film stack. Additional masking layers may be formed on the first masking layer 542, such as an anti-reflective coating (e.g. SiON), an additional carbon-containing masking layer (e.g. SOC or spin-on carbon), and/or an additional silicon-containing masking layer (e.g. SOG or spin-on-glass).

In some example, the mask patterns of masks 522 and 523 can be printed onto the masking layers as follows. A first patterning layer (such as a photoresist layer) is formed on the masking layers. The first mask 522 is used in a photolithography process to print the line-space mask pattern 526 onto the first patterning layer, such as by a light exposure of the photoresist layer using the mask 522 and development of the photoresist layer after exposure. In one example, an immersion lithography technique can be used. Then, a second patterning layer (such as a photoresist layer) is provided on the developed first photoresist layer. The second mask 523 is used in a photolithography process to print the line-space mask pattern 528 onto the second patterning layer, such as by a light exposure of the photoresist layer using the mask 523 and development of the photoresist layer after exposure. As a result of the photolithography process using the first mask and the second mask, a hole opening pattern is formed at the overlapped areas 530 of the line-space mask patterns 526, 528. That is, the resulting pattern from the two developed photoresist layers is a hole opening pattern at the overlapped areas 530. The developed photoresist layers are then used to transfer the hole opening pattern to the one or more masking layers, until the hole opening pattern is transferred to the first masking layer 542 (the hard mask layer), in a process referred to as the mask open process.

As a result of the mask open process, hole openings 546 are formed in the first masking layer 542. As described above, while the overlapped area 530 of the line-space patterns 526, 528 is a square, the pattern that is printed onto the patterning layers using the photolithography process will be a circle. Accordingly, the masking layer 542 has circular hole openings 546 corresponding to the square overlapped area 530. The patterned hard mask layer 542 can then be used in a high-aspect-ratio etch process to form the LWL holes in the multi-layer film stack, in the manner as described above with reference to FIG. 13(b).

In embodiments of the present invention, the memory structure can be incorporated as an embedded memory in a logic integrated circuit. For example, a memory structure including using one, two, four or eight active layers can be used to form an embedded memory circuit. Furthermore, the memory structure can be adapted as an embedded memory circuit by using smaller tile size, that is fewer numbers of memory transistors in the memory strings and few memory strings per tile. In particular, the ferroelectric memory transistor in embodiments of the present invention can be operated at low bias voltages, such as using voltage levels less than 2V, making the memory structure suitable for use as embedded memory circuits.

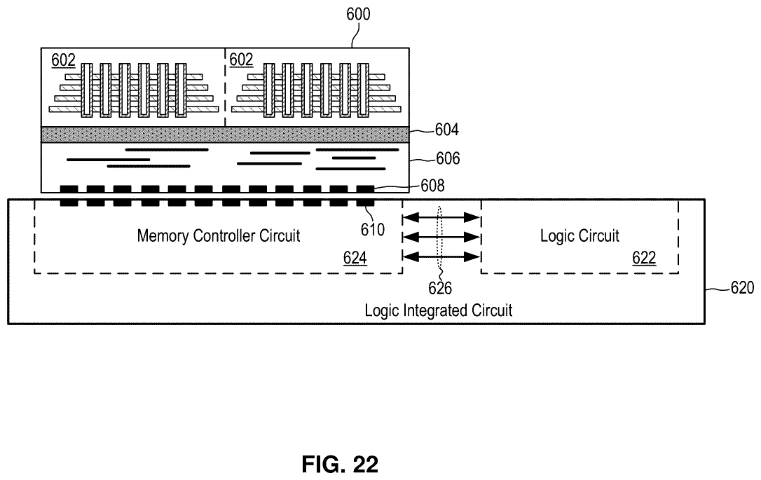

FIG. 22 illustrates an application of a memory device of the present invention as an embedded memory device in some embodiments. Referring to FIG. 22, a memory device 600 is constructed in the manner described above with reference to FIGS. 1(a) to 1(c) and includes a two-dimensional array of tiles 602, where each tile includes a memory array being a three-dimensional array of junctionless ferroelectric memory transistors. The memory arrays in tiles 602 are formed above a semiconductor substrate 606. An insulating layer 604 may be provided between the semiconductor substrate 606 and the memory arrays (tiles 602) formed on the substrate. Support circuitry (CuA) for operating the memory transistors in the memory arrays can be formed in the semiconductor substrate 606. In some examples, the support circuitry for the ferroelectric memory transistors of each tile is provided for modularity in the portion of the semiconductor substrate underneath each tile.

In some embodiments, the memory device interacts with a memory controller to perform memory operations. As described above, the memory controller includes control circuits for accessing and operating the ferroelectric memory transistors in the memory device, and performing memory control functions, and managing interface functions for host access. In some embodiments, a memory module is formed with the memory device formed on one semiconductor die and the memory controller formed on a separate semiconductor die. The memory die and the memory controller die may be integrated using a variety of integration techniques, such as using TSVs, hybrid bonds, exposed contacts, interposers, printed circuit boards and other suitable interconnect techniques, especially techniques for high density interconnects.

In the present embodiment, the memory controller is embedded in the semiconductor substrate of a logic integrated circuit 620. In particular, the logic integrated circuit 620 may have formed thereon digital or analog logic circuits 622, such as a core processor. The memory controller circuit 624 is integrated into the logic integrated circuit 160 and formed in a portion of the semiconductor substrate of the logic integrated circuit 620. The memory device 600 is bonded to and electrically connected to the memory controller circuit 624 using various bonding techniques. In the present illustration, the memory device 600 includes an array of connectors 608 which are bonded to corresponding mating connectors 610 formed on the logic integrated circuit 620. In some embodiments, the connectors 608 and 610 are hybrid integration bonds, such as copper to copper bonds and may have a pitch of less than 2 micron or less than 1 micron.

As thus configured, the memory device 600, through embedded memory controller 624, operates as an embedded memory circuit in logic integrated circuit 620. The memory controller circuit 624 can be connected to the digital or analog circuits 622 on the logic integrated circuit 620 directly through interconnect lines 626 formed in the logic integrated circuit, without going through any interface circuits. Accordingly, the ferroelectric memory transistors in the memory device 600 become available to circuitry of the logic integrated circuit 620 with minimal delays. That is, the memory transistors can be accessed with low latency through the direct connectors 626 between the memory controller circuit 624 and the logic circuits 622. Such a configuration is sometimes referred to as “in memory compute.” In memory compute is particularly desirable in artificial intelligence and machine learning applications that are data intensive, and which require a great deal of memory in close proximity to the CPU and GPU core processors, which can be formed as the logic circuit 622 in the logic integrated circuit 620. In embodiments of the present invention, memory device 150, including arrays of three-dimensional NOR memory strings of ferroelectric memory transistors, can be used to form an embedded memory circuit to realize a low latency, high capacity in memory compute system for data intensive applications. It is instructive to note that because ferroelectric memory transistors have a higher operating temperature, the memory device 600 of ferroelectric memory transistors can be embedded with the logic integrated circuit 620 by being provided on the logic integrated circuit, as opposed to being provided on the side of the logic integrated circuit. The embedded memory circuit of the present invention realizes improved latency by eliminating the RC delay caused by routing signals through an interposer.

In some embodiments, the memory device 600 may be built directly on top of the logic integrated circuit 620 on the same semiconductor substrate. For example, the memory device 600 may be built on top of an insulating layer formed on the logic integrated circuit to protect the circuitry already manufactured. For example, the insulating layer may be a silicon oxide layer or a passivation layer, such as a polyimide layer. Electrical connections between the memory device 600 and the memory control circuit or directly to other application-specific logic circuits are provided through vias formed in the insulating layer. In this case, bonding of the memory device through connectors 608, 610 is obviated.

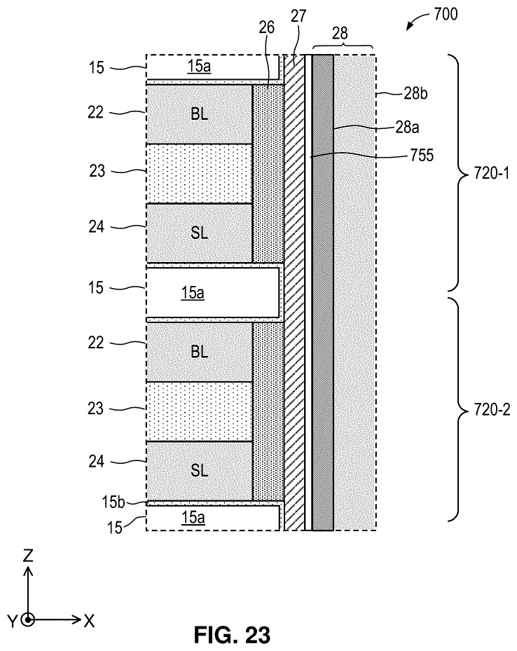

In the embodiments described above, such as with reference to FIGS. 1(d) and 1(c), the ferroelectric memory transistors 20 formed in the memory structure 10 may include an interfacial layer 25 provided between the oxide semiconductor channel layer 26 and the ferroelectric polarization layer 27. The optional interfacial layer 25 is a thin dielectric layer and may be provided to function as a barrier layer or as an adhesion layer. In some embodiments, the memory structure of the present invention includes ferroelectric memory transistors that are formed including an interfacial dielectric layer formed between the ferroelectric dielectric layer and the gate conductor layer. FIG. 23 illustrates the detail construction of a memory transistor formed in a memory structure in alternate embodiments of the present invention. In particular, FIG. 23 illustrates a memory structure 700 including a pair of memory transistors 720-1 and 720-2 in two adjacent planes of a memory stack. The memory structure 700 is constructed in the same manner as the memory structures described above except for the placement of the interfacial dielectric layer.

Referring to FIG. 23, the memory transistor 720 includes the first conductive layer 22 forming the drain region (the common drain line or the common bit line) and the second conductive layer 24 forming the source region (the common source line), the conductive layers being spaced apart by the channel spacer dielectric layer 23. The memory transistor 720 further includes the annular channel layer 26 formed vertically along the sidewall of the local word line pillar and in contact with both the first conductive layer 22 and the second conductive layer 24. The annular ferroelectric gate dielectric layer 27 and the gate conductor layer 28 are formed adjacent the annular channel layer 26. In particular, a portion of the annular channel layer 26 is provided between or overlap the bit line 22 and the gate conductor layer 28 in the X-Y plane; and a portion of the annular channel layer 26 is provided between or overlap the source line 24 and the gate conductor layer 28 in the X-Y plane. In the present embodiment, the channel layer 26 is an oxide semiconductor layer, such as an IGZO layer. In some embodiments, the gate conductor layer 28 may include a conductive liner 28a as an adhesion layer (e.g. TiN) and a low resistivity conductor 28b (e.g. W). The memory transistor 720 is isolated from adjacent memory transistors in the memory stack by an inter-layer isolation layer 15. As thus configured, in each memory stack, the memory transistors that share the common source line and the common bit line form a NOR memory string (referred herein as a “Horizontal NOR memory string” or “HNOR memory string”).

To form the ferroelectric memory transistor, the memory transistor 720 includes a ferroelectric dielectric layer or ferroelectric polarization layer as the gate dielectric layer 27, also referred to as ferroelectric gate dielectric layer 27. For example, the ferroelectric gate dielectric layer 27 may be formed using a doped hafnium oxide material, such as zirconium-doped hafnium oxide (HfZrO or “HZO”) layer. The ferroelectric polarization layer 27 serves as the storage layer of the memory transistor. In the present embodiment, the memory transistor 720 includes an interfacial dielectric layer 755 formed between the ferroelectric gate dielectric layer 27 and the gate conductive layer 28. For example, the interfacial dielectric layer 755 may be formed during the local word line formation process when the concentric layers of the channel layer, the ferroelectric layer, the interfacial dielectric layer and the gate conductor layer are deposited into the holes, such as by using a damascene process and atomic layer deposition (ALD). More specifically, after the deposition of the ferroelectric polarization layer 27, the interfacial dielectric layer 755 is deposited conformally onto the annular ferroelectric polarization layer 27 before the gate conductor layer 28 is deposited.

In some embodiments, the interfacial dielectric layer 755 is a thin layer and may be 0.5 nm to 3 nm thick. In some embodiments, the interfacial dielectric layer 755 is formed using a material with a high dielectric constant (K), that is, a high-K material with a dielectric constant greater than the dielectric constant of silicon dioxide (SiO₂). In some embodiments, the interfacial dielectric layer 755 may be a silicon nitride (Si₃N₄) layer, or a silicon oxynitride layer, an aluminum oxide (Al₂O₃) layer, or a zirconium oxide (ZrO₂) layer. In one example, the interfacial dielectric layer 755 may have a thickness of 2 nm when the ferroelectric dielectric layer 27 has a thickness of 4-5 nm. The interfacial dielectric layer 755 serves as a barrier layer for the gate dielectric layer of the ferroelectric memory transistor 720. The interfacial dielectric layer 755 is optional and may be omitted in other embodiments of the present invention. In other embodiments, the interfacial dielectric layer 755, when included, may be formed as a multi-layer of different dielectric materials.

According to another aspect of the present invention, a vertical ferroelectric field effect transistor is formed using the structures and processes described above. In embodiments of the present invention, an integrated circuit includes a vertical ferroelectric field effect transistor formed above a planar surface of a semiconductor substrate. For example, the vertical ferroelectric field effect transistor is formed in the same manner as the ferroelectric memory transistor described above, such as with reference to any of the above-described figures. In one embodiment, with reference to FIGS. 1(a) to 1(c) as an example, the vertical ferroelectric field effect transistor 20 includes a gate conductor layer 28 provided as a pillar extending in a first direction (e.g. the Z-direction), an annular ferroelectric dielectric layer 27 formed adjacent to the pillar of the gate conductor layer 28, and an annular oxide semiconductor layer 26 formed adjacent to the annular ferroelectric dielectric layer 27. The vertical ferroelectric field effect transistor 20 further includes a first conductive layer 22 and a second conductive layer 24, each provided as a plane parallel to the planar surface of the semiconductor substrate. The first and second conductive layers 22, 24 encircle an outer circumference of and are in contact with the annular oxide semiconductor layer 26.

In some embodiments, the first and second conductive layers 22, 24 are arranged one on top of another along the first direction (e.g. the Z-direction) and spaced apart by a first isolation layer 23.

As thus configured, the vertical ferroelectric field effect transistor is formed at an intersection of the first and second conductive layers 22, 24 and the annular oxide semiconductor layer 26. The first conductive layer 22 forms a drain region and the second conductive layer 24 forming a source region of the vertical ferroelectric field effect transistor. The oxide semiconductor layer 26 forms a junctionless channel region and the annular ferroelectric dielectric layer 27 forms the gate dielectric layer of the vertical ferroelectric field effect transistor. Finally, the gate conductor layer 28 forms the gate electrode of the vertical ferroelectric field effect transistor. For example, each vertical ferroelectric field effect transistor is formed in the memory structure, as shown in FIGS. 1(a)-1(c) and further illustrated in detail in FIGS. 1(d) and 1(c).

In another embodiment, an array of memory strings is formed including multiple vertical ferroelectric field effect transistors formed above a planar surface of a semiconductor substrate. For example, each vertical ferroelectric field effect transistor is formed in the same manner as the ferroelectric memory transistor described above, such as with reference to any of the above-described figures. In one embodiment, with reference to FIGS. 1(a) to 1(e) as an example, each ferroelectric field effect transistor 20 includes a gate conductor layer 28 provided as a pillar extending in a first direction (e.g. the Z-direction) substantially normal to the planar surface of the semiconductor substrate, an annular ferroelectric dielectric layer 27 formed adjacent to the pillar of the gate conductor layer 28, and an annular oxide semiconductor layer 26 formed adjacent to the annular ferroelectric dielectric layer 27. Each ferroelectric field effect transistor 20 further includes a first conductive layer 22 and a second conductive layer 24, each provided as a plane parallel to the planar surface of the semiconductor substrate. The first and second conductive layers 22, 24 are arranged one on top of another along the first direction (Z-direction) and spaced apart by a first isolation layer 23. The first and second conductive layers 22, 24 encircle an outer circumference of and are in contact with the annular oxide semiconductor layer 26.

Each vertical ferroelectric field effect transistor is formed at an intersection of the first and second conductive layers 22, 24 and the annular oxide semiconductor layer 25. The first conductive layer 22 forms a drain region and the second conductive layer 24 forms a source region of the vertical ferroelectric field effect transistor. The oxide semiconductor layer 26 forms a junctionless channel region and the annular ferroelectric dielectric layer forms the gate dielectric layer of the vertical ferroelectric field effect transistor. The gate conductor layer 28 forms the gate electrode of the vertical ferroelectric field effect transistor.

In some embodiments, the array of memory strings includes a stack of memory stings provided one on top of another in the first direction (e.g. Z-direction) where each memory sting in the stack is associated with multiple ferroelectric field effect transistors extending in a second direction (e.g. Y-direction). The array of memory strings further includes multiple pillars of the gate conductor layer arranged in the second direction and being associated with the ferroelectric field effect transistors along each memory sting. As thus configured, the vertical ferroelectric field effect transistors across the stack of memory strings are formed along each pillar of the gate conductor layer and are vertically aligned. The vertically aligned ferroelectric field effect transistors are electrically isolated from one or more neighboring ferroelectric field effect transistors by a second isolation layer 15.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present.

In this detailed description, process steps described for one embodiment may be used in a different embodiment, even if the process steps are not expressly described in the different embodiment. When reference is made herein to a method including two or more defined steps, the defined steps can be carried out in any order or simultaneously, except where the context dictates or specific instruction otherwise are provided herein. Further, unless the context dictates or express instructions otherwise are provided, the method can also include one or more other steps carried out before any of the defined steps, between two of the defined steps, or after all the defined steps.

In this detailed description, various embodiments or examples of the present invention may be implemented in numerous ways, including as a process; an apparatus; a system; and a composition of matter. A detailed description of one or more embodiments of the invention is provided above along with accompanying figures that illustrate the principles of the invention. The invention is described in connection with such embodiments, but the invention is not limited to any embodiment. Numerous modifications and variations within the scope of the present invention are possible. The scope of the invention is limited only by the claims and the invention encompasses numerous alternatives, modifications, and equivalents. Numerous specific details are set forth in the description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured. The present invention is defined by the appended claims.

1. A three-dimensional memory structure formed above a planar surface of a semiconductor substrate, the memory structure comprising:
a plurality of memory stacks arranged along a first direction, each memory stack being separated from each of its immediate neighboring memory stacks along the first direction by a trench, each memory stack and each trench extending in a second direction, the first and second directions being orthogonal to each other and both being substantially parallel to the planar surface of the semiconductor substrate, wherein each memory stack comprises a plurality of active layers arranged in a third direction substantially normal to the planar surface of the semiconductor substrate, each active layer comprising a first conductive layer and a second conductive layer arranged one on top of another in the third direction and spaced apart by a first isolation layer and each active layer is separated from its immediate neighboring active layers along the third direction by a second isolation layer; and
a plurality of local word line structures provided as pillars formed in each memory stack and extending in the third direction, each local word line structure being encircled by the first and second conductive layers, each local word line structure including concentric layers of an oxide semiconductor layer, a ferroelectric dielectric layer and a gate conductor layer, wherein the oxide semiconductor layer is provided around the outer circumference of each pillar and is provided between and in contact with the first and second conductive layers,
wherein each active layer in the memory stack forms a plurality of thin-film ferroelectric memory transistors organized as a NOR memory string, each memory transistor being formed at an intersection of an active layer and a local word line structure.

2. The three-dimensional memory structure of claim 1, wherein the memory transistors within each NOR memory string share the first conductive layer, which serves as a common drain line, and share the second conductive layer, which serves as a common source line, the oxide semiconductor layer in contact with and in between the first and second conductive layers serving as a junctionless channel region of each memory transistor in each NOR memory string.

3. The three-dimensional memory structure of claim 1, wherein each memory stack comprises a set of local word line structures arranged in a single line of local word line structures extending along the second direction, each active layer in the memory stack forming a NOR memory string of thin-film ferroelectric memory transistors.

4. The three-dimensional memory structure of claim 1, wherein each memory stack comprises a set of local word line structures formed in two or more lines of local word line structures arranged in the first direction, each line extending along the second direction, the local word line structures in each line being offset from the local word line structures in an adjacent line in the second direction, each active layer in the memory stack forming a NOR memory string of thin-film ferroelectric memory transistors.

5. The three-dimensional memory structure of claim 4, wherein, in each memory stack, the local word line structures in the two or more lines are connected to respective global word lines extending in the first direction, each local word line structure in the two or more lines of the memory stack being connected to a different global word line.

6. The three-dimensional memory structure of claim 5, wherein the global word lines are formed in a single layer on a top surface of the memory structure.

7. The three-dimensional memory structure of claim 5, wherein the global word lines are formed on a top surface of the memory structure and comprise lower global word lines and upper global word lines connecting to alternating local word line structures in the wo or more lines of the memory stack.

8. The three-dimensional memory structure of claim 5, wherein the global word lines comprises bottom global word lines formed in the semiconductor substrate and top global word lines formed on a top surface of the memory structure, the bottom global word lines and the top global word lines connecting to alternating local word line structures in the two or more lines of the memory stack, the bottom global word lines connecting to the gate conductor layer of the respective local word line structures in or at the surface of the semiconductor substrate.

9. The three-dimensional memory structure of claim 1, wherein, within a memory stack, the oxide semiconductor layer is absent from the local word line structures in a region between two adjacent active layers in the third direction.

10. The three-dimensional memory structure of claim 1, wherein, within a memory stack, the oxide semiconductor layer is partially removed from the local word line structures in a region between two adjacent active layers in the third direction.

11. The three-dimensional memory structure of claim 9, wherein, within a memory stack, the ferroelectric dielectric layer is absent from the local word line structures in a region between two adjacent active layers in the third direction.

12. The three-dimensional memory structure of claim 1, wherein the oxide semiconductor layer comprises one of an indium gallium zinc oxide (IGZO) layer, an indium zinc oxide (IZO) layer, an indium tungsten oxide (IWO) layer, or an indium tin oxide (ITO) layer.

13. The three-dimensional memory structure of claim 1, wherein the ferroelectric dielectric layer comprises a doped hafnium oxide layer.

14. The three-dimensional memory structure of claim 1, wherein each local word line structure further comprises an interfacial layer formed as a concentric layer between the oxide semiconductor layer and the ferroelectric dielectric layer.

15. The three-dimensional memory structure of claim 14, wherein the interfacial layer comprises one of a silicon nitride (Si₃N₄) layer or an aluminum oxide (Al₂O₃) layer.

16. The three-dimensional memory structure of claim 1, wherein the first isolation layer comprises a silicon dioxide layer (SiO₂).

17. The three-dimensional memory structure of claim 1, wherein the second isolation layer comprises an oxygen-containing dielectric layer or an air gap cavity lined with a dielectric liner.

18. The three-dimensional memory structure of claim 1, wherein the first conductive layer and the second conductive layer each comprises a metal layer.

19. The memory structure of claim 1, wherein the gate conductor layer comprises a conductive layer selected from titanium nitride or tungsten nitride.

20. The memory structure of claim 1, wherein the gate conductor layer comprises a first metal layer formed on the ferroelectric dielectric layer and a second metal layer formed on the first metal layer.

21. The memory structure of claim 20, wherein the first metal layer comprises a metal layer selected from titanium nitride or tungsten nitride and the second metal layer comprises a metal layer selected from tungsten, or molybdenum.

22. The memory structure of claim 1, wherein the gate conductor layer comprises a heavily doped N-type polysilicon layer or a heavily doped P-type polysilicon layer.

23. The three-dimensional memory structure of claim 1, wherein a channel length of each memory transistor is a function of a thickness of the first isolation layer in the third direction.

24. The three-dimensional memory structure of claim 23, wherein the thickness of the first isolation layer in the third direction is in the range of 10-30 nm.

25. The three-dimensional memory structure of claim 1, wherein a channel width of each memory transistor is a function of the circumference of the oxide semiconductor layer of the local word line structure.

26. The three-dimensional memory structure of claim 2, wherein the common source line is an electrically floating source.

27. The three-dimensional memory structure of claim 26, further comprising a plurality of non-memory transistors formed in each NOR memory string, the non-memory transistors being designated as precharge transistors, the precharge transistors being activated during a precharge operation to electrically connect the first and second conductive layers in each NOR memory string to set the voltage on the second conductive layer to equal to the voltage on the first conductive layer.

28. The three-dimensional memory structure of claim 27, further comprising:
a plurality of precharge local word line structures provided as pillars extending in the third direction formed in each memory stack and encircled by the first and second conductive layers, each precharge local word line structure including concentric layers of an oxide semiconductor layer, a non-polarizable gate dielectric layer and a gate conductor layer, wherein the oxide semiconductor layer is provided around the outer circumference of each pillar and is provided between and in contact with the first and second conductive layers,
wherein a precharge transistor is formed at the intersection of an active layer and a precharge local word line structure.

29. The three-dimensional memory structure of claim 1, further comprising:
a first staircase structure provide at a first end of the memory structure in the second direction and a second staircase structure provided at a second end of the memory structure in the second direction,
wherein the first staircase structure connects the first conductive layer in every other active layers in the plurality of memory stacks to circuitry formed in the semiconductor substrate; and the second staircase structure connects the first conductive layer in the other active layers in the plurality of memory stacks to circuitry formed in the semiconductor substrate.

30. The three-dimensional memory structure of claim 1, further comprising:
a first staircase structure provide at a first end of the memory structure in the second direction and a second staircase structure provided at a second end of the memory structure in the second direction,
wherein the first staircase structure connects the first conductive layer in every active layers in the plurality of memory stacks to circuitry formed in the semiconductor substrate; and the second staircase structure connects the second conductive layer in every active layers in the plurality of memory stacks to circuitry formed in the semiconductor substrate.

31. The three-dimensional memory structure of claim 1, wherein the plurality of memory stacks are divided into a first memory stack portion and a second memory stack portion by a second trench extending in the first direction, and the memory structure further comprises:
a first staircase structure provide at a first end of the memory structure in the second direction and a second staircase structure provided at a second end of the memory structure in the second direction,
wherein the first staircase structure connects the first conductive layer in every active layers in the first memory stack portion to circuitry formed in the semiconductor substrate; and the second staircase structure connects the first conductive layer in every active layers in the second memory stack portion to circuitry formed in the semiconductor substrate.

32. The three-dimensional memory structure of claim 1, wherein circuitry for supporting memory operations of the memory transistors is formed at the planar surface of the semiconductor substrate substantially underneath the plurality of memory stacks.

33. The three-dimensional memory structure of claim 2, wherein the gate conductor layer is biased to a first voltage value relative to the common drain line to program the ferroelectric memory transistor to a first logical state and the gate conductor layer is biased to a second voltage value relative to the common drain line to erase the ferroelectric memory transistor to a second logical state, the first voltage value and the second voltage value having opposite voltage polarities and having different voltage magnitude.

34. The three-dimensional memory structure of claim 2, wherein in each memory transistor in the NOR memory string, the common drain line and the common source line are biased to substantially the same voltage during a program or an erase operation of the memory transistor.

35. The three-dimensional memory structure of claim 2, wherein the gate conductor layer is biased to a third voltage value relative to the common drain line to partially polarize the ferroelectric memory transistor to represent a first logical state and the gate conductor layer is biased to a fourth voltage value relative to the common drain line to partially polarize the ferroelectric memory transistor to represent a second logical state.

36. The three-dimensional memory structure of claim 1, wherein the plurality of memory stacks and the local word line structures formed therein have dimensions that are scalable in the first direction and the second direction.

37. The three-dimensional memory structure of claim 1, wherein the pillars of the local word line structures are arranged in a two-dimensional array in a plane in the first and second directions, each line of local word line structures in the array along the second direction is offset from an adjacent line in the second direction.

38. The three-dimensional memory structure of claim 1, wherein each of the pillars of the local word line structures has a circular shape in a plane in the first and second directions.

39. The three-dimensional memory structure of claim 1, wherein each of the pillars of the local word line structures has an oblong shape in a plane in the first and second directions, each pillar having a length longer than a width in the plane in the first and second directions.

40. The three-dimensional memory structure of claim 39, wherein each oblong-shaped pillar of the local word line structures has a length that is parallel to the second direction or parallel to the first direction.

41. The three-dimensional memory structure of claim 1, wherein the concentric layer of the oxide semiconductor layer formed in the local word line structure comprises a first oxide semiconductor layer, and each active layer of in the plurality of memory stacks further comprises:
isolated portions of a second oxide semiconductor layer, wherein (i) a first isolated portion of the second oxide semiconductor layer partially envelops and in contact with the first conductive layer and a second isolated portion of the second oxide semiconductor layer partially envelops and in contact with the second conductive layer, the first and second conductive layers being spaced apart by the first isolation layer; and (ii) each isolated portion of the second oxide semiconductor layer is in contact with the first oxide semiconductor layer of the local word line structures and the second oxide semiconductor layer is formed of material different from the material of the first oxide semiconductor layer.

42. The three-dimensional memory structure of claim 41, wherein the first oxide semiconductor layer comprises indium gallium zinc oxide (IGZO) and the second oxide semiconductor layer comprises an oxide semiconductor material selected from indium aluminum oxide (IAO), indium oxide (InO), indium zinc oxide (IZO), and indium tin oxide (ITO).

43. The three-dimensional memory structure of claim 41, wherein the first oxide semiconductor layer has a first thickness and the second oxide semiconductor layer has a second thickness less than the first thickness.

44. The three-dimensional memory structure of claim 1, wherein each local word line structure further comprises an interfacial layer formed as a concentric layer between the ferroelectric dielectric layer and the gate conductor layer.

45. The three-dimensional memory structure of claim 44, wherein the interfacial layer comprises one of a silicon nitride (Si₃N₄) layer or an aluminum oxide (Al₂O₃) layer or a zirconium oxide (ZrO₂) layer.

46-105. (canceled)
